(19) United States
(12) Patent Application Publication
(10) Pub. No.: US 2026/0358541 A1
(43) Pub. Date: Nov. 12, 2026

(54) POLARIZING PLATE AND DISPLAY DEVICE

(71) Applicant: FUJIFILM Corporation, Tokyo (JP)

(72) Inventors: Nobuyuki AKUTAGAWA, Minamiashigara-shi (JP); Mitsuru KURASAWA, Minamiashigara-shi (JP)

(73) Assignee: FUJIFILM Corporation, Tokyo (JP)

(21) Appl. No.: 19/704,512

(22) Filed: Jun. 11, 2026

Related U.S. Application Data
(63) Continuation of application No. PCT/JP2025/001305, filed on Jan. 17, 2025.

(30) Foreign Application Priority Data
Jan. 19, 2024 (JP) 2024-006748

(51) Int. Cl. G02B 5/30

(52) U.S. Cl. CPC G02B 5/3016

(57) ABSTRACT

A polarizing plate includes, in order, a polarizer, a first optically anisotropic layer, and a second optically anisotropic layer. An isotropic layer is disposed between the polarizer and the first optically anisotropic layer and/or between the first optically anisotropic layer and the second optically anisotropic layer. At least one of the first optically anisotropic layer and the second optically anisotropic layer includes, at a surface facing the isotropic layer, a region in which in-plane birefringence gradually increases in a thickness direction from the surface. An absolute value of a difference between a refractive index in an in-plane slow-axis direction at the surface of the optically anisotropic layer facing the isotropic layer and an in-plane refractive index of the isotropic layer is 0.04 or less. The polarizing plate suppresses in-plane tint unevenness when incorporated into a display device and viewed from an oblique direction during black display.

### CROSS-REFERENCE TO RELATED APPLICATIONS

This application is a Continuation of PCT International Application No. PCT/JP2025/001305 filed on Jan. 17, 2025, which claims priority under 35 U.S.C. § 119(a) to Japanese Patent Application No. 2024-006748 filed on Jan. 19, 2024. The above applications are hereby expressly incorporated by reference, in their entirety, into the present application.

### BACKGROUND OF THE INVENTION

### 1. Field of the Invention

The present invention relates to a polarizing plate and a display device.

### 2. Description of the Related Art

An optically anisotropic layer having refractive index anisotropy is applied to various applications such as an anti-reflection film of various display devices such as an organic electroluminescence (EL) display device and an optical compensation film of a liquid crystal display device.

For example, WO2022/045188A discloses an optical film in which three types of optically anisotropic layers exhibiting predetermined optical properties are laminated.

### SUMMARY OF THE INVENTION

In recent years, in a display device, there is a demand for further reduction in in-plane tint unevenness in a case of being viewed from an oblique direction in a black display. The present inventors have studied a display device using the optical film described in WO2022/045188A, and have found that the display device may not satisfy a level required in recent years.

The in-plane tint unevenness means that there are regions having different tints in a plane.

In view of the above circumstances, an object of the present invention is to provide a polarizing plate which is applied to a display element to obtain a display device, and in which in-plane tint unevenness is less likely to occur in a case where the display device is viewed from an oblique direction in a black display. In addition, another object is to provide a display device including the polarizing plate.

As a result of conducting an extensive investigation to achieve the objects, the present inventors have found that the objects can be achieved by the following configuration.
[1] A polarizing plate comprising, in order: a polarizer; a first optically anisotropic layer; and a second optically anisotropic layer, in which an isotropic layer A exhibiting optical isotropy is disposed between the first optically anisotropic layer and the second optically anisotropic layer, and at least one of Requirement 1 or Requirement 2 described later is satisfied, or an isotropic layer B exhibiting optical isotropy is disposed between the polarizer and the first optically anisotropic layer, and Requirement 3 described later is satisfied.
[2] The polarizing plate according to [1], in which thicknesses of the region X, the region Y, and the region Z are 60 to 500 nm.
[3] The polarizing plate according to [1] or [2], in which in-plane thickness unevennesses of the isotropic layer A and the isotropic layer B are 5 to 35 nm.
[4] The polarizing plate according to any one of [1] to [3], in which the first optically anisotropic layer is an A-Plate.
[5] The polarizing plate according to any one of [1] to [4], in which an in-plane retardation of the first optically anisotropic layer at a wavelength of 550 nm is 150 to 240 nm.
[6] The polarizing plate according to any one of [1] to [5], in which the first optically anisotropic layer contains a disk-like liquid crystal compound.
[7] The polarizing plate according to any one of [1] to [6], in which the in-plane refractive indices of the isotropic layer A and the isotropic layer B are 1.51 to 1.59.
[8] The polarizing plate according to any one of [1] to [7], in which thicknesses of the isotropic layer A and the isotropic layer B are 0.5 to 20 μm.
[9] The polarizing plate according to any one of [1] to [8], in which the isotropic layer A and the isotropic layer B are each a pressure-sensitive adhesive layer or an ultraviolet curable adhesive layer.
[10] A display device comprising: a display element; and the polarizing plate according to any one of [1] to [9].

According to the present invention, it is possible to provide the polarizing plate which is applied to the display element to obtain the display device, and in which the in-plane tint unevenness is less likely to occur in a case where the display device is viewed from the oblique direction in the black display. In addition, it is also possible to provide the display device including the polarizing plate.

### BRIEF DESCRIPTION OF THE DRAWINGS

FIG. 1 is an example of a schematic cross-sectional view of an embodiment of the polarizing plate of the present invention.

FIG. 2 is an example of a schematic cross-sectional view of an embodiment showing a configuration of an optically anisotropic layer of the polarizing plate of the present invention.

FIG. 3 is a diagram showing a relationship between an absorption axis of a polarizer and an in-plane slow axis of an optically anisotropic layer in the embodiment of the polarizing plate according to the present invention shown in FIG. 2.

FIG. 4 is a schematic view showing a relationship of an angle between the absorption axis of the polarizer and the in-plane slow axis of the optically anisotropic layer, upon observation from a direction of a white arrow in FIG. 2.

FIG. 5 is an example of a schematic cross-sectional view of the embodiment showing the configuration of the optically anisotropic layer of the polarizing plate of the present invention.

FIG. 6 is a diagram showing a relationship between an absorption axis of a polarizer and an in-plane slow axis of an optically anisotropic layer in the embodiment of the polarizing plate according to the present invention shown in FIG. 5.

FIG. 7 is a schematic view showing a relationship of an angle between the absorption axis of the polarizer and the in-plane slow axis of the optically anisotropic layer, upon observation from a direction of a white arrow in FIG. 5.

### DESCRIPTION OF THE PREFERRED EMBODIMENTS

Hereinafter, the present invention will be described in detail.

The description of the configuration requirements described below may be made based on the representative embodiments of the present invention, but the present invention is not limited to those embodiments.

In the present specification, a numerical range expressed using “to” means a range that includes the preceding and succeeding numerical values of “to” as a lower limit value and an upper limit value, respectively.

In addition, in the present specification, in a case where there are two or more components corresponding to a certain component, “content” of such a component means the total content of the two or more components.

In the present specification, regarding numerical ranges that are described stepwise, an upper limit value or a lower limit value described in a numerical range may be replaced with an upper limit value or a lower limit value of another stepwise numerical range. In addition, in the numerical range described in the present specification, an upper limit value and a lower limit value described in a certain numerical range may be replaced with values shown in Examples.

In the present specification, a combination of two or more preferred aspects is a more preferred aspect.

A bonding direction of a divalent group (for example, —CO—O—) described in the present specification is not limited unless otherwise specified. For example, in a case where Y in a compound represented by a formula “X—Y—Z” is-CO—O—, the compound may be “X—O—CO—Z” or “X—CO—O—Z”.

In the present specification, the concept of “(meth)acryl” includes both acryl and methacryl, the concept “(meth)acryloyl” includes both acryloyl and methacryloyl, and the concept of “(meth)acrylate” includes both acrylate and methacrylate.

In the present specification, the solid content means components forming the optically anisotropic layer, and does not include a solvent. The component forming the optically anisotropic layer may be a component in which a chemical structure changes by a reaction (polymerization) in a case of forming the optically anisotropic layer. In addition, even in a case where the component is liquid, the component is included in the solid content as long as the component forms the optically anisotropic layer.

In the present specification, unless otherwise specified, the refractive index is a refractive index at a wavelength of 550 nm.

In the present specification, the slow axis is defined at 550 nm unless otherwise specified.

In the present specification, unless otherwise specified, Re (λ) and Rth(λ) represent an in-plane retardation and a thickness-direction retardation at a wavelength λ, respectively. Unless otherwise specified, it is assumed that the wavelength λ is 550 nm.

In the present specification, Re(λ) and Rth(λ) are values measured at the wavelength of λ in AxoScan (manufactured by Axometrics, Inc.). By inputting an average refractive index ((nx+ny+nz)/3) and a film thickness (d (μm)) in AxoScan,
in-plane slow axis direction (°)
Re(λ)=R0(λ), and
Rth(λ)=((nx+ny)/2−nz)×d
are calculated.

Although R0 (λ) is displayed as a numerical value calculated by AxoScan, it means Re (λ).

In the present specification, unless otherwise specified, the refractive indices nx, ny, and nz are measured using an Abbe refractometer (NAR-4T, manufactured by Atago Co., Ltd.) and using a sodium lamp (λ=589 nm) as a light source. In addition, the wavelength dependence can be measured using a combination of a multi-wavelength Abbe refractometer DR-M2 (manufactured by Atago Co., Ltd.) and a dichroic filter.

In addition, the values in Polymer Handbook (John Wiley & Sons, Inc.) and catalogs of various optical films can be used. The values of average refractive index of major optical films are as follows: cellulose acylate (1.48), cycloolefin polymer (1.52), polycarbonate (1.59), polymethyl methacrylate (1.49), and polystyrene (1.59).

In the present specification, unless otherwise specified, a weight-average molecular weight (Mw) is a value in terms of polystyrene, as measured by a gel permeation chromatography (GPC) method.

In addition, in the present specification, a relationship between angles (for example, “orthogonal”, “parallel”, and the like) is intended to include a range of errors acceptable in the art to which the present invention belongs. Specifically, it means that an angle is within an error range of less than ±10° with respect to the exact angle, and the error with respect to the exact angle is preferably within a range of ±5° or less and more preferably within a range of ±3° or less.

### [Polarizing Plate]

Hereinafter, the polarizing plate according to the embodiment of the present invention will be described in detail.

A polarizing plate according to the embodiment of the present invention is a polarizing plate comprising, in order: a polarizer; a first optically anisotropic layer; and a second optically anisotropic layer, in which an isotropic layer A exhibiting optical isotropy is disposed between the first optically anisotropic layer and the second optically anisotropic layer, and at least one of Requirement 1 or Requirement 2 is satisfied, or an isotropic layer B exhibiting optical isotropy is disposed between the polarizer and the first optically anisotropic layer, and Requirement 3 is satisfied.

Requirement 1: the first optically anisotropic layer has a region X in which an in-plane birefringence gradually increases along a thickness direction from a surface on a side of the isotropic layer A, and an absolute value of a difference between a refractive index in an in-plane slow axis direction on the surface of the first optically anisotropic layer on the side of the isotropic layer A and an in-plane refractive index of the isotropic layer A is 0.04 or less.

Requirement 2: the second optically anisotropic layer has a region Y in which an in-plane birefringence gradually increases along the thickness direction from a surface on the side of the isotropic layer A, and an absolute value of a difference between a refractive index in an in-plane slow axis direction on the surface of the second optically anisotropic layer on the side of the isotropic layer A and the in-plane refractive index of the isotropic layer A is 0.04 or less.

Requirement 3: the first optically anisotropic layer has a region Z in which an in-plane birefringence gradually increases along the thickness direction from a surface on a side of the isotropic layer B, and an absolute value of a difference between a refractive index in an in-plane slow axis direction on the surface of the first optically anisotropic layer on the side of the isotropic layer B and an in-plane refractive index of the isotropic layer B is 0.04 or less.

The reason why the polarizing plate having the above-described configuration can achieve the object of the present invention is not necessarily clear, but the present inventors speculate as follows.

The mechanism by which the effect is obtained is not limited by the following speculation. In other words, even in a case where the effect is obtained by a mechanism other than the one described below, it is still included within the scope of the present invention.

In a case where a difference in refractive index between members constituting the polarizing plate, for example, between the optically anisotropic layer and the isotropic layer is large, light may be reflected at an interface between the layers, and in-plane tint unevenness may occur due to interference of reflected light. In the polarizing plate according to the embodiment of the present invention, in which the optically anisotropic layer has at least one region in which in-plane birefringence gradually increases along the thickness direction from a surface on the side of the adjacent isotropic layer, and a difference between a refractive index in an in-plane slow axis direction on the surface of the optically anisotropic layer on the side of the isotropic layer and the in-plane refractive index of the isotropic layer is a predetermined value or less, a rapid change in refractive index between the optically anisotropic layer and the isotropic layer and in the optically anisotropic layer is suppressed, and occurrence of reflection is suppressed. As described above, it is presumed that the number of interfaces at which light is reflected is reduced, and as a result, the in-plane tint unevenness can be suppressed.

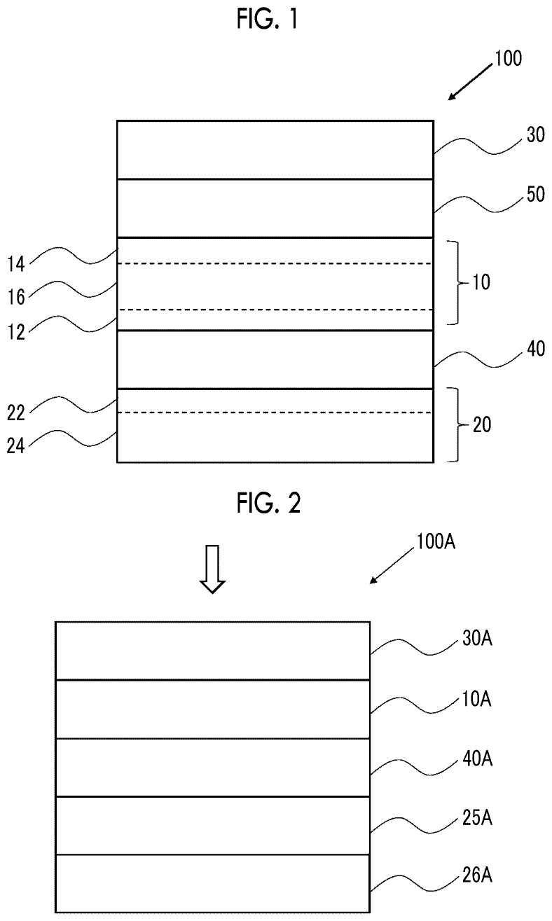

Hereinafter, a polarizing plate according to the embodiment of the present invention will be described with reference to FIG. 1. FIG. 1 is a schematic cross-sectional view of one embodiment of the polarizing plate according to the embodiment of the present invention.

A polarizing plate 100 shown in FIG. 1 includes a polarizer 30, an isotropic layer B50, a first optically anisotropic layer 10, an isotropic layer A40, and a second optically anisotropic layer 20 in this order.

The polarizing plate 100 shown in FIG. 1 is a polarizing plate in an aspect in which both the isotropic layer A40 and the isotropic layer B50 are included and all of the above-described Requirements 1 to 3 are satisfied.

As shown in FIG. 1, in the first optically anisotropic layer 10, a region X12 in which in-plane birefringence gradually increases along a thickness direction (a direction from the first optically anisotropic layer 10 to the polarizer 30) from a surface on the isotropic layer A40 side is present on a surface side on the isotropic layer A40 side. As shown in FIG. 1, in the first optically anisotropic layer 10, a region Z14 in which in-plane birefringence gradually increases along a thickness direction (a direction from the first optically anisotropic layer 10 to the second optically anisotropic layer 20) from a surface on the isotropic layer B50 side is present on a surface side on the isotropic layer B50 side. As shown in FIG. 1, it is preferable that the first optically anisotropic layer 10 has a region 16 (homogeneous region 1) in which in-plane birefringence does not gradually increase along the thickness direction, as a region different from the above-described region X12 and the above-described region Z14.

As shown in FIG. 1, in the second optically anisotropic layer 20, a region Y22 in which in-plane birefringence gradually increases along a thickness direction (a direction from the first optically anisotropic layer 10 to the second optically anisotropic layer 20) from a surface on the isotropic layer A40 side is present on a surface side on the isotropic layer A40 side. In addition, as shown in FIG. 1, it is preferable that the second optically anisotropic layer 20 has a region 24 (homogeneous region 2) in which in-plane birefringence does not gradually increase along the thickness direction, as a region different from the above-described region Y22.

In FIG. 1, an embodiment in which the isotropic layer A40 and the isotropic layer B50 are provided is disclosed, but the present invention is not limited to this embodiment, and the polarizing plate according to the embodiment of the present invention may be an aspect in which only the isotropic layer A is provided or an aspect in which only the isotropic layer B is provided. For example, in a case where the polarizing plate according to the embodiment of the present invention includes the isotropic layer A and does not include the isotropic layer B, at least one of the region X or the region Y may be provided, and in a case where the polarizing plate according to the embodiment of the present invention does not include the isotropic layer A and includes only the isotropic layer B, the region Z may be provided. In a case where the polarizing plate according to the embodiment of the present invention includes both the isotropic layer A and the isotropic layer B, at least one of the region X to the region Z may be provided.

The polarizing plate 100 shown in FIG. 1 may include an optional member (not shown), and for example, an optically anisotropic layer may be further provided on a side of the second optically anisotropic layer 20 opposite to the isotropic layer A40.

Hereinafter, the relationship among the region X, the region Y, and the region Z, and the characteristic interlayer relationship of the present invention will be described, and then the details of each layer will be described. Hereinafter, a concept including all of the region X, the region Y, and the region Z will also be referred to as a “specific region”.

### [Region X, Region Y, and Region Z]

The region X, the region Y, and the region Z (specific region) are regions in which in-plane birefringence Δn gradually increases along the thickness direction from a surface on a side of the adjacent isotropic layer. In the specific region, the in-plane birefringence may continuously increase or may increase stepwise.

As described above, the region X is a region that can be included in the first optically anisotropic layer.

The region X is a region disposed on the isotropic layer A side of the first optically anisotropic layer, and is a region in which the in-plane birefringence gradually increases along the thickness direction (direction from the first optically anisotropic layer to the polarizer) from the surface on the isotropic layer A side. The range of increase in the in-plane birefringence in the region X is more than 0.00, preferably 0.01 or more and more preferably 0.03 or more. The range of increase depends on the intrinsic birefringence of the liquid crystal molecules, but is 0.05 or less in many cases.

The range of increase in the in-plane birefringence in the region X is a difference between a minimum value and a maximum value of the in-plane birefringence at each position in the thickness direction of the region X, and corresponds to a difference between the in-plane birefringence on the surface of the region X on the isotropic layer A side and the in-plane birefringence at a position of the region X farthest from the isotropic layer A.

In the present specification, the in-plane birefringence is a difference between a refractive index ne in an in-plane slow axis direction and a refractive index no in an in-plane fast axis direction which is a direction perpendicular to the in-plane slow axis direction.

In a case where the optically anisotropic layer is a layer formed by twistedly aligning the liquid crystal compound in the thickness direction, for example, in a case where the optically anisotropic layer is a chiral nematic layer described below, the interface reflection with the isotropic layer is maximized in the alignment axis direction of the liquid crystal compound at the interface in contact with the isotropic layer. Therefore, in a case where the optically anisotropic layer is the chiral nematic layer, the alignment axis direction of the liquid crystal compound at the interface with the isotropic layer is read as the in-plane slow axis direction at the surface. In addition, a direction perpendicular to the above-described in-plane slow axis direction is read as the in-plane fast axis direction. That is, for example, the absolute value of the difference between the refractive index in the in-plane slow axis direction at the surface of the chiral nematic layer and the in-plane refractive index of the isotropic layer is the absolute value of the difference between the refractive index in the alignment axis direction of the liquid crystal compound at the interface at which the chiral nematic layer is in contact with the isotropic layer and the in-plane refractive index of the isotropic layer.

In addition, in a case where the optically anisotropic layer is the chiral nematic layer, the in-plane birefringence at each position in the thickness direction is a difference between the refractive index in the alignment axis direction of the liquid crystal compound at each position in the thickness direction and the refractive index in a direction perpendicular to the alignment axis direction. The range of increase in the in-plane birefringence in the specific region is a difference between the minimum value and the maximum value of the in-plane birefringence at each position in the thickness direction calculated by the above-described reading, and the alignment axis direction in a case of showing the minimum value and the alignment axis direction in a case of showing the maximum value may be the same as or different from each other.

In the present specification, the surface in a case of in-plane birefringence and in-plane refractive index on the surface of a certain layer is intended to be a region from the interface of the layer to a depth of 50 nm.

In a case where Requirement 1 is satisfied, an absolute value (|n_{e1A}−n_{A}|) of a difference between a refractive index n_{e1A} in an in-plane slow axis direction on a surface of the first optically anisotropic layer on the isotropic layer A side and an in-plane refractive index n_{A} of the isotropic layer A is 0.04 or less. The |n_{e1A}−n_{A}| is preferably 0.03 or less and more preferably 0.02 or less, from the viewpoint that the effect of the present invention is more excellent. The lower limit of |n_{e1A}−n_{A}| is 0.00.

In addition, in a case where Requirement 1 is satisfied, an absolute value (|n_{o1A}−n_{A}|) of a difference between a refractive index n_{o1A} in an in-plane fast axis direction on a surface of the first optically anisotropic layer on the isotropic layer A side and the in-plane refractive index n_{A} of the isotropic layer A is preferably 0.04 or less, preferably 0.03 or less, and more preferably 0.02 or less. The lower limit of |n_{o1A}−n_{A}| is 0.00.

The region X may correspond to a partial region of the first optically anisotropic layer in the thickness direction or may correspond to the entire first optically anisotropic layer.

In a case where the region X corresponds to a partial region of the first optically anisotropic layer in the thickness direction, the first optically anisotropic layer has a region different from the region X. For example, the first optically anisotropic layer may further have a region Z described below. In addition, the first optically anisotropic layer may have a region (hereinafter, also referred to as a “homogeneous region 1”) that is located adjacent to the region X and in which the in-plane birefringence is constant in the thickness direction. Further, the first optically anisotropic layer may have the region X, the homogeneous region 1 that is located adjacent to the region X, and the region Z that is located adjacent to the homogeneous region 1.

As described above, the region Y is a region that can be included in the second optically anisotropic layer.

The region Y is a region disposed on the isotropic layer A side of the second optically anisotropic layer, and is a region in which the in-plane birefringence gradually increases along the thickness direction (direction from the polarizer side to a surface on a side opposite to the polarizer) from the surface on the isotropic layer A side. The range of increase in the in-plane birefringence in the region Y is more than 0.00, and is preferably 0.01 or more and more preferably 0.03 or more. In addition, the range of increase depends on the intrinsic birefringence of the liquid crystal molecules, but is 0.05 or less in many cases.

The range of increase in the in-plane birefringence in the region Y is a difference between a minimum value and a maximum value of the in-plane birefringence at each position in the thickness direction of the region Y, and corresponds to a difference between the in-plane birefringence on the surface of the region Y on the isotropic layer side and the in-plane birefringence at a position of the region Y farthest from the isotropic layer A.

In a case where Requirement 2 is satisfied, an absolute value (|n_{e2A}−n_{A}|) of a difference between a refractive index n_{e2A} in an in-plane slow axis direction on a surface of the second optically anisotropic layer on the isotropic layer A side and the in-plane refractive index n_{A} of the isotropic layer A is 0.04 or less. The |n_{e2A}−n_{A}| is preferably 0.03 or less and more preferably 0.02 or less, from the viewpoint that the effect of the present invention is more excellent. The lower limit of |n_{e2A}−n_{A}| is 0.00.

In addition, in a case where Requirement 2 is satisfied, an absolute value (|n_{o2A}−n_{A}|) of a difference between a refractive index n_{o2A} in an in-plane fast axis direction on a surface of the second optically anisotropic layer on the isotropic layer A side and the in-plane refractive index n_{A} of the isotropic layer A is preferably 0.04 or less, preferably 0.03 or less, and more preferably 0.02 or less. The lower limit of |n_{o2A}−n_{A}| is 0.00.

The region Y may correspond to a partial region of the second optically anisotropic layer in the thickness direction or may correspond to the entire second optically anisotropic layer.

In a case where the region Y corresponds to a partial region of the second optically anisotropic layer in the thickness direction, the second optically anisotropic layer has a region different from the region Y. For example, the second optically anisotropic layer may have a region (hereinafter, also referred to as a “homogeneous region 2”) that is located adjacent to the region Y and in which the in-plane birefringence is constant in the thickness direction.

As described above, the region Z is a region that can be included in the first optically anisotropic layer.

The region Z is a region disposed on the isotropic layer B side of the first optically anisotropic layer, and is a region in which the in-plane birefringence gradually increases along the thickness direction (direction from the polarizer to the first optically anisotropic layer) from the surface on the isotropic layer B side. The range of increase in the in-plane birefringence in the region Z is more than 0.00, preferably 0.01 or more and more preferably 0.03 or more. In addition, the range of increase depends on the intrinsic birefringence of the liquid crystal molecules, but is 0.05 or less in many cases.

The range of increase in the in-plane birefringence in the region Z is a difference between a minimum value and a maximum value of the in-plane birefringence at each position in the thickness direction of the region Z, and corresponds to a difference between the in-plane birefringence on the surface of the region Z on the isotropic layer B side and the in-plane birefringence at a position of the region Z farthest from the isotropic layer B.

In a case where Requirement 3 is satisfied, an absolute value (|n_{e1B}−n_{B}|) of a difference between a refractive index n_{e1B} in an in-plane slow axis direction on a surface of the first optically anisotropic layer on the isotropic layer B side and the in-plane refractive index np of the isotropic layer B is 0.04 or less. The |n_{e1B}−n_{B}| is preferably 0.03 or less and more preferably 0.02 or less, from the viewpoint that the effect of the present invention is more excellent. The lower limit of |n_{e1B}−n_{B}| is 0.00.

In addition, in a case where Requirement 3 is satisfied, an absolute value (|n_{o1B}−n_{B}|) of a difference between a refractive index n_{o1B} in an in-plane fast axis direction on a surface of the first optically anisotropic layer on the isotropic layer B side and the in-plane refractive index np of the isotropic layer B is preferably 0.04 or less, preferably 0.03 or less, and more preferably 0.02 or less. The lower limit of |n_{o1B}−n_{B}| is 0.00.

The region Z may correspond to a partial region of the first optically anisotropic layer in the thickness direction or may correspond to the entire first optically anisotropic layer.

In a case where the region Z corresponds to a partial region of the first optically anisotropic layer in the thickness direction, the first optically anisotropic layer has a region different from the region Z. For example, the first optically anisotropic layer may further have the above-described region X. In addition, the first optically anisotropic layer may have a homogeneous region 1 located adjacent to the region Z. Further, as described above, the first optically anisotropic layer may have the region Z, the homogeneous region 1 located adjacent to the region Z, and the region X located adjacent to the homogeneous region 1.

From the viewpoint that the effect of the present invention is more excellent, the thickness of the specific region is preferably 10 nm or more, more preferably 60 nm or more, more preferably 300 nm or more, and still more preferably 400 nm or more. In addition, the thickness of the specific region is often 1,000 nm or less, preferably 750 nm or less, and more preferably 500 nm or less.

In each of the layers and the regions, the in-plane birefringence, the in-plane refractive index, and the thickness are values calculated by the following method.

For the first optically anisotropic layer, the second optically anisotropic layer, and the isotropic layer A and the isotropic layer B (in a case where the isotropic layer A and the isotropic layer B are present), transmission and reflection ellipsometry are performed in a wavelength range of 500 to 1,500 nm using an ellipsometer. As the ellipsometer, for example, RC-2 manufactured by Woollam Company and SE-2000 manufactured by Semilab can be used. In the above-described measurement, for one azimuthal angle, in the reflection ellipsometry, the measurement is performed with a difference of 15° or more between the maximum angle and the minimum angle of the incidence angle, and in the transmission ellipsometry, the measurement is performed at three or more angles with a difference of 30° or more between the maximum angle and the minimum angle including the vertical incidence. The above-described measurement is performed on the sample at two angles (a vertical direction and a horizontal direction) orthogonal to each other. In the above-described reflection ellipsometry, it is preferable to perform a process of reducing the back surface reflection intensity. Examples of the process of reducing the back surface reflection intensity include a process of sanding the back surface.

For the results obtained by the above-described measurement, an optical model is constructed on the assumption that the region X, the region Y, and the region Z are present, and the refractive index and the film thickness of each layer are calculated by performing fitting using a least square method. A specific fitting procedure is shown below.

First, it is assumed that the first optically anisotropic layer and the second optically anisotropic layer have the region X, the region Y, the region Z, the homogeneous region 1, and the homogeneous region 2. For each layer, the refractive index is set to n(λ)=Aₙ+Bₙ/λ₂ (Aₙ and Bₙ are variables, λ is a wavelength, and n(λ) represents a refractive index at the wavelength λ) according to a Cauchy model. In the specific region, it is assumed that Aₙ and Bₙ change linearly in a film thickness direction from an interface side. In addition, in the first optically anisotropic layer, it is assumed that Aₙ and Bₙ match at an interface between the region X and the homogeneous region 1 and at an interface between the region Z and the homogeneous region 1, and in the second optically anisotropic layer, it is assumed that Aₙ and Bₙ match at an interface between the region Y and the homogeneous region 2. In the homogeneous region 1 and the homogeneous region 2, it is assumed that there is no change in the refractive index in the film thickness direction.

By constructing an optical model according to the above-described conditions and performing fitting on the results obtained using the above-described ellipsometer, the film thickness of each region and the Cauchy model ne (2)=Aₙₑ+Bₙₑ/λ₂ of the refractive index in the in-plane slow axis direction and the Cauchy model no (2)=Aₙₒ+Bₙₒ/λ₂ of the refractive index in the in-plane fast axis direction of each region are calculated. From the obtained nₑ(λ) and nₒ(λ), the average values of the in-plane birefringence and the in-plane refractive index can also be calculated. For the refractive index in each direction, the in-plane birefringence, and the in-plane refractive index in each layer and each region, a value at a wavelength of 550 nm is adopted.

In a case where the film thickness of a certain specific region calculated by the above-described method is 0 nm, the specific region is considered not to be present. The same applies to the homogeneous region 1 and the homogeneous region 2.

The in-plane birefringence and the in-plane refractive index on the surface of the layer are obtained as an average value in a region from the interface to 20 nm, which is obtained by the above-described method.

As described above, in a case where the polarizing plate according to the embodiment of the present invention includes the isotropic layer A, Requirement 1 or 2 is satisfied, and in a case where the polarizing plate includes the isotropic layer B, Requirement 3 is satisfied. From the viewpoint that the effect of the present invention is more excellent, in a case where the polarizing plate includes the isotropic layer A, it is preferable that Requirement 1 and Requirement 2 are satisfied.

Hereinafter, the layers which can be included in the polarizing plate according to the embodiment of the present invention will be described.

### [Polarizer]

The polarizer included in the polarizing plate according to the embodiment of the present invention may be a member having a function of converting natural light into specific linearly polarized light, and examples thereof include an absorption type polarizer.

The type of the polarizer is not particularly limited, and a commonly used polarizer can be used. Examples thereof include an iodine-based polarizer, a dye-based polarizer using a dichroic dye, and a polyene-based polarizer. The iodine-based polarizer and the dye-based polarizer are generally produced by adsorbing iodine or a dichroic dye onto a polyvinyl alcohol, followed by stretching.

A protective film may be disposed on one side or both sides of the polarizer.

In addition, as described in WO2019/131943A and JP2017-083843A, a coating type polarizer produced by using and applying a liquid crystal compound and a dichroic organic coloring agent (for example, a dichroic azo coloring agent used for a light-absorbing anisotropic film described in WO2017/195833A), without using a polyvinyl alcohol as a binder, may be used as the polarizer. That is, the polarizer may be a polarizer formed of a composition containing a polymerizable liquid crystal compound.

The coating type polarizer is a technique which utilizes the alignment of the liquid crystal compound to align the dichroic organic coloring agent. As described in JP2012-083734A, in a case where the polymerizable liquid crystal compound exhibits smectic properties, it is preferable from the viewpoint of increasing the alignment degree. Alternatively, as described in WO2018/186503A, it is also preferable to crystallize a coloring agent from the viewpoint of increasing the alignment degree. WO2019/131943A describes a structure of a polymer liquid crystal which is preferred for increasing the alignment degree.

The polarizing plate may include a polarizer protective film. Examples of the polarizer protective layer include a layer containing a polymer and a layer obtained by polymerizing and curing a polyfunctional monomer. Examples of the polymer include a (meth)acrylic polymer and a cycloolefin polymer. Examples of the polymerizable monomer include radically polymerizable compounds and cationically polymerizable compounds.

### [First Optically Anisotropic Layer]

The first optically anisotropic layer included in the polarizing plate according to the embodiment of the present invention is preferably a layer formed of a composition containing a liquid crystal compound, and more preferably a layer obtained by fixing an aligned liquid crystal compound.

In the present specification, a state in which the liquid crystal compound is “fixed” is a state where the alignment of the liquid crystal compound is maintained. Specifically, the “fixed” state is more preferably a state in which, in a temperature range of usually 0 °C to 50 °C or in a temperature range of −30 °C to 70 °C under more severe conditions, the layer has no fluidity and a fixed alignment morphology can be stably maintained without causing a change in the alignment morphology due to an external field or an external force. The layer obtained by fixing the aligned liquid crystal compound may be fixed in a state in which the liquid crystal compound is aligned, and the alignment degree of the liquid crystal compound may be different in a part of the region of the first optically anisotropic layer (for example, the region X and the region Z).

The liquid crystal compound may be any of a disk-like liquid crystal compound or a rod-like liquid crystal compound.

As the disk-like liquid crystal compound, a known compound can be used, and examples thereof include compounds described in paragraphs to of JP2007-108732A and paragraphs to of JP2010-244038A.

As the rod-like liquid crystal compound, a known compound can be used, and examples thereof include the compounds described in claim 1 of JP1999-513019A (JP-H11-513019A) and paragraphs [0026] to [0098] of JP2005-289980A.

The liquid crystal compound may have a polymerizable group, and from the viewpoint that the alignment can be fixed, the liquid crystal compound is preferably a liquid crystal compound having a polymerizable group (polymerizable liquid crystal compound).

In the present specification, the type of the polymerizable group is not particularly limited, but is preferably a functional group capable of an addition polymerization reaction, more preferably a polymerizable ethylenically unsaturated group or a ring-polymerizable group, and still more preferably a (meth)acryloyl group, a vinyl group, a styryl group, or an allyl group.

As the liquid crystal compound, a photoisomerizable liquid crystal compound having a photoisomerization-reactive moiety may be used.

In the photoisomerizable liquid crystal compound, the birefringence index of the compound is changed by photoisomerization. Therefore, by irradiating a layer consisting of a composition containing a photoisomerizable liquid crystal compound with predetermined light to photoisomerize the photoisomerizable liquid crystal compound, the alignment state of the liquid crystal compound in the optically anisotropic layer can be changed, and the optical properties of the optically anisotropic layer can be controlled.

Examples of the photoisomerizable liquid crystal compound include photoisomerizable liquid crystal compounds that can be used in Method 1 described below.

The type of the first optically anisotropic layer is not particularly limited, but from the viewpoint that the effect of the present invention is more excellent, an A-Plate is preferable.

The A-Plate is a plate that satisfies any of Expression (A1) or Expression (A2) in a case where a refractive index in an in-plane slow axis direction is defined as nx, a refractive index in a direction orthogonal to the in-plane slow axis in the plane is defined as ny, and a refractive index in a thickness direction is defined as nz. In a case where Expression (A1) is satisfied, the A-Plate is a so-called positive A-Plate; and in a case where Expression (A2) is satisfied, the A-Plate is a so-called negative A-Plate.

nx>ny≈nz Expression (A1)

ny<nx≈nz Expression (A2)

The symbol “≈” encompasses not only a case where both sides are completely the same as each other but also a case where both sides are substantially the same as each other. The expression “substantially the same” means that, for example, a case where (ny−nz)×d is −10 to 10 nm and preferably −5 to 5 nm is also included in “ny≈nz”; and a case where (nx−nz)×d is −10 to 10 nm and preferably −5 to 5 nm is also included in “nx≈nz”. In (ny−nz)×d, d represents a thickness of the layer.

From the viewpoint that the effect of the present invention is more excellent, the first optically anisotropic layer preferably contains a disk-like liquid crystal compound, and is more preferably a layer formed by fixing vertically aligned disk-like liquid crystal compounds. The layer formed by fixing vertically aligned disk-like liquid crystal compounds usually corresponds to a negative A-Plate.

The first optically anisotropic layer may contain a rod-like liquid crystal compound, and in this case, a layer formed by fixing horizontally aligned rod-like liquid crystal compounds is preferable. The layer formed by fixing horizontally aligned rod-like liquid crystal compounds usually corresponds to a positive A-Plate.

In the layer formed by fixing vertically aligned disk-like liquid crystal compounds and the layer formed by fixing horizontally aligned rod-like liquid crystal compounds, it is sufficient that a region where the liquid crystal compound is fixed in the above-described alignment state is present, and the liquid crystal compound may be fixed in a state where the alignment angle is changed from vertical or horizontal in a part of the region (for example, the region X and the region Z) of the first optically anisotropic layer.

The first optically anisotropic layer may be composed of one optically anisotropic layer or two or more optically anisotropic layers. From the viewpoint that the optical film can be thinned, the first optically anisotropic layer is preferably composed of one optically anisotropic layer.

The in-plane retardation of the first optically anisotropic layer at a wavelength of 550 nm is preferably 150 nm or more, more preferably 155 nm or more, and still more preferably 160 nm or more. In addition, the in-plane retardation of the first optically anisotropic layer at a wavelength of 550 nm is preferably 240 nm or less, more preferably 220 nm or less, and still more preferably 200 nm or less.

In a case where the polarizing plate includes the isotropic layer A, the first optically anisotropic layer preferably includes the region X. In addition, in a case where the polarizing plate includes the isotropic layer B, the first optically anisotropic layer preferably includes the region Z. The region X and the region Z are as described above.

The first optically anisotropic layer preferably includes the homogeneous region 1. In a case where the first optically anisotropic layer does not include the region X and the region Z, the entire first optically anisotropic layer corresponds to the homogeneous region 1.

From the viewpoint that the effect of the present invention is more excellent, a refractive index nₑ₁ in the in-plane slow axis direction in the homogeneous region 1 of the first optically anisotropic layer is preferably 1.50 to 1.75 and more preferably 1.55 to 1.65.

From the viewpoint that the effect of the present invention is more excellent, in-plane birefringence Δn₁ in the homogeneous region 1 of the first optically anisotropic layer is preferably 0.30 or less and more preferably 0.20 or less. Δn₁ is often 0.05 or more and more often 0.10 or more.

From the viewpoint that the effect of the present invention is more excellent, the refractive index n_{e1A} in the in-plane slow axis direction on the surface of the first optically anisotropic layer on the second optically anisotropic layer side (isotropic layer A side) is preferably 1.45 to 1.70 and more preferably 1.50 to 1.65.

From the viewpoint that the effect of the present invention is more excellent, the in-plane birefringence Δn_{1A} on the surface of the first optically anisotropic layer on the second optically anisotropic layer side (isotropic layer A side) is preferably 0.04 or less and more preferably 0.03 or less. The lower limit of Δn_{1A} is 0.00.

From the viewpoint that the effect of the present invention is more excellent, the refractive index n_{e1B} in the in-plane slow axis direction on the surface of the first optically anisotropic layer on the polarizer side (isotropic layer B side) is preferably 1.45 to 1.70 and more preferably 1.50 to 1.65.

From the viewpoint that the effect of the present invention is more excellent, the in-plane birefringence Δn_{1B} on the surface of the first optically anisotropic layer on the polarizer side (isotropic layer B side) is preferably 1.45 to 1.70 and more preferably 1.50 to 1.65.

A thickness of the first optically anisotropic layer is preferably 0.5 μm or more, more preferably 1.0 μm or more, and still more preferably 1.3 μm or more. In addition, the thickness of the first optically anisotropic layer is preferably 5.0 μm or less, more preferably 3.0 μm or less, and still more preferably 2.5 μm or less.

The above-described thickness can be determined, for example, by the above-described method or a method of measuring thicknesses of any five or more points of the first optically anisotropic layer using a scanning electron microscope (SEM) for the cross section and arithmetically averaging the measured values.

An angle between an in-plane slow axis of the first optically anisotropic layer and an absorption axis of a polarizer is preferably 40° to 85°, more preferably 50° to 85°, and still more preferably 65° to 85°.

### [Second Optically Anisotropic Layer]

The second optically anisotropic layer included in the polarizing plate according to the embodiment of the present invention is preferably a layer formed of a composition containing an aligned liquid crystal compound, and more preferably a layer formed by fixing the aligned liquid crystal compound.

The layer obtained by fixing the aligned liquid crystal compound may be fixed in a state in which the liquid crystal compound is aligned, and the alignment degree of the liquid crystal compound may be different in a part of the region of the second optically anisotropic layer (for example, the region Y).

Examples of the above-described liquid crystal compound include the same liquid crystal compounds as those in the first optically anisotropic layer described above.

The second optically anisotropic layer may be composed of one optically anisotropic layer or two or more optically anisotropic layers. In a case where the second optically anisotropic layer is composed of two or more layers, the region Y is present on a surface side of the optically anisotropic layer present closest to the first optically anisotropic layer side (isotropic layer A side), on the isotropic layer A.

The second optically anisotropic layer is preferably selected from a laminate (hereinafter, also referred to as “optically anisotropic layer (AB)”) of an optically anisotropic layer formed by fixing a twistedly aligned rod-like liquid crystal compound with a thickness direction as a helical axis (hereinafter, also referred to as “optically anisotropic layer (A)”) and an optically anisotropic layer formed by fixing a vertically aligned rod-like liquid crystal compound (hereinafter, also referred to as “optically anisotropic layer (B)”), and an optically anisotropic layer formed by fixing a vertically aligned disk-like liquid crystal compound (hereinafter, also referred to as “optically anisotropic layer (C)”), and is more preferably an optically anisotropic layer (AB).

In the optically anisotropic layer formed by fixing the twistedly aligned rod-like liquid crystal compound with the thickness direction as the helical axis, the optically anisotropic layer formed by fixing the vertically aligned rod-like liquid crystal compound, and the optically anisotropic layer formed by fixing the vertically aligned disk-like liquid crystal compound, it is sufficient that a region where the liquid crystal compound is fixed in each of the above-described alignment states is present, and the liquid crystal compound may be fixed in a state where the alignment is released or in a state where the alignment angle is changed in a partial region (for example, the above-described region Y).

### <Optically Anisotropic Layer (AB)>

The optically anisotropic layer (AB) is an optically anisotropic layer formed by laminating the optically anisotropic layer (A) and the optically anisotropic layer (B), and it is preferable that the optically anisotropic layer (A) and the optically anisotropic layer (B) are laminated in this order from the adhesion layer side.

### (Optically Anisotropic Layer (A))

As described above, the optically anisotropic layer (A) is an optically anisotropic layer formed by fixing a twistedly aligned rod-like liquid crystal compound with a thickness direction as a helical axis, and it is preferably a layer (chiral nematic layer) formed by fixing a chiral nematic phase having a so-called helical structure.

The optically anisotropic layer (A) is preferably formed of a composition including a rod-like liquid crystal compound indicating a nematic liquid crystal layer and a chiral agent described below.

The rod-like liquid crystal compound is not particularly limited, and examples thereof include a rod-like liquid crystal compound that can be included in the first optically anisotropic layer described above.

A twisted angle of the rod-like liquid crystal compound (twisted angle of liquid crystal compound in an alignment axis direction) is not particularly limited, and is often more than 0° and 360° or less. From the viewpoint that the effect of the present invention is more excellent, the twisted angle is preferably 50° to 110°, more preferably 60° to 100°, and still more preferably 70° to 90°.

The twisted angle is measured using an AxoScan (polarimeter) device manufactured by Axometrics, Inc. and using device analysis software of Axometrics, Inc.

In addition, the “twist-aligned liquid crystal compound” is intended to that the liquid crystal compound from one main surface to the other main surface of the optically anisotropic layer (A) is twisted around the thickness direction of the optically anisotropic layer (A) as an axis. Along with this, the alignment axis direction (in-plane slow axis direction) of the liquid crystal compound varies depending on the position of the optically anisotropic layer (A) in the thickness direction.

An angle between the in-plane slow axis of the first optically anisotropic layer and the in-plane slow axis on the surface of the optically anisotropic layer (A) on the first optically anisotropic layer side is preferably 0° to 20° and more preferably 0° to 15°.

Re(550) of the optically anisotropic layer (A) is preferably 140 nm or more, more preferably 150 nm or more, and still more preferably 160 nm or more. In addition, Re(550) of the optically anisotropic layer (A) is preferably 220 nm or less, more preferably 210 nm or less, and still more preferably 200 nm or less.

A thickness of the optically anisotropic layer (A) is not particularly limited, and is preferably 0.5 μm or more, more preferably 1.0 μm or more, and still more preferably 1.3 μm or more. In addition, the thickness of the optically anisotropic layer (A) is preferably 5.0 μm or less, more preferably 2.5 μm or less, and still more preferably 2.2 μm or less.

### (Optically Anisotropic Layer (B))

As described above, the optically anisotropic layer (B) is a layer formed by fixing a vertically aligned rod-like liquid crystal compound.

The optically anisotropic layer (B) is preferably formed of a composition including a rod-like liquid crystal compound and a photo-alignment polymer described below.

The rod-like liquid crystal compound is not particularly limited, and examples thereof include liquid crystal compounds that can be included in the first optically anisotropic layer described above.

Re(550) of the optically anisotropic layer (B) is preferably 0 to 10 nm and more preferably 0 to 5 nm.

Rth(550) of the optically anisotropic layer (B) is preferably −120 nm or more, more preferably −110 nm or more, and still more preferably −100 nm or more. In addition, Rth(550) of the optically anisotropic layer (B) is preferably −20 nm or less, more preferably −30 nm or less, and still more preferably −40 nm or less.

A thickness of the optically anisotropic layer (B) is not particularly limited, and is preferably 10.0 μm or less, more preferably 5.0 μm or less, and still more preferably 2.0 μm or less. In addition, the thickness of the optically anisotropic layer (B) is preferably 0.1 μm or more and more preferably 0.3 μm or more.

### <Optically Anisotropic Layer (C)>

As described above, the optically anisotropic layer (C) is a layer formed by fixing a vertically aligned disk-like liquid crystal compound.

The disk-like liquid crystal compound is not particularly limited, and examples thereof include a disk-like liquid crystal compound that can be included in the first optically anisotropic layer described above.

An angle between the absorption axis of the polarizer and the in-plane slow axis of the optically anisotropic layer (C) is preferably 0° to 30°, more preferably 5° to 25°, and still more preferably 10° to 20°.

An angle between the in-plane slow axis of the first optically anisotropic layer and the in-plane slow axis of the optically anisotropic layer (C) is preferably 30° to 90°, more preferably 40° to 80°, and still more preferably 50° to 70°.

Re(550) of the optically anisotropic layer (C) is preferably 100 nm or more and more preferably 105 nm or more. In addition, Re(550) of the optically anisotropic layer (C) is preferably 150 nm or less and more preferably 145 nm or less.

A thickness of the optically anisotropic layer (C) is not particularly limited, and is preferably 10.0 μm or less, more preferably 5.0 μm or less, and still more preferably 2.0 μm or less. In addition, the thickness of the optically anisotropic layer (C) is preferably 0.1 μm or more and more preferably 0.3 μm or more.

In a case where the polarizing plate includes the isotropic layer A, it is preferable that the second optically anisotropic layer includes a region Y. The region Y is as described above.

It is also preferable that the second optically anisotropic layer includes a homogeneous region 2. In a case where the second optically anisotropic layer does not include the region Y, the entire second optically anisotropic layer corresponds to the homogeneous region 2.

From the viewpoint that the effect of the present invention is more excellent, a refractive index nₑ₂ in the in-plane slow axis direction in the homogeneous region 2 of the second optically anisotropic layer is preferably 1.50 to 1.75 and more preferably 1.55 to 1.70.

From the viewpoint that the effect of the present invention is more excellent, in-plane birefringence Δn₂ in the homogeneous region 2 of the second optically anisotropic layer is preferably 0.30 or less and more preferably 0.20 or less. Δn₂ is often 0.05 or more and more often 0.10 or more.

From the viewpoint that the effect of the present invention is more excellent, the refractive index n_{e2A} in the in-plane slow axis direction on the surface of the second optically anisotropic layer on the first optically anisotropic layer side (isotropic layer A side) is preferably 1.45 to 1.70 and more preferably 1.50 to 1.65.

From the viewpoint that the effect of the present invention is more excellent, the in-plane birefringence Δn_{2A} on the surface of the second optically anisotropic layer on the first optically anisotropic layer side (isotropic layer A side) is preferably 0.05 or less and more preferably 0.04 or less. The lower limit of Δn_{2A} is 0.00, and Δn_{2A} is often 0.02 or more.

A thickness of the second optically anisotropic layer is preferably 0.5 μm or more, more preferably 1.0 μm or more, and still more preferably 1.3 μm or more. In addition, the thickness of the second optically anisotropic layer is preferably 5.0 μm or less, more preferably 3.0 μm or less, and still more preferably 2.5 μm or less.

The thickness of the second optically anisotropic layer can be measured using the same method as that of the first optically anisotropic layer.

### [Isotropic Layer A]

The isotropic layer A may be an optically isotropic layer and is preferably an adhesion layer.

The adhesion layer is a layer that exhibits a function of causing adjacent layers (for example, the first optically anisotropic layer and the second optically anisotropic layer) to adhere to each other, and examples thereof include an adhesive layer and a pressure-sensitive adhesive layer.

The above-described adhesive layer is a layer formed of an adhesive. Examples of the adhesive include an active energy ray-curable adhesive, an aqueous adhesive, a solvent-based adhesive, an emulsion-based adhesive, a solvent-free adhesive, and a heat-curable adhesive, and an active energy ray-curable adhesive is preferable.

Examples of the active energy ray-curable adhesive include an electron beam-curable adhesive, an ultraviolet curable adhesive, and a visible light-curable adhesive; and among these, an ultraviolet curable adhesive is preferable.

As the active energy ray-curable adhesive, for example, a known adhesive can be used, and an adhesive selected from a (meth)acrylate-based adhesive or an epoxy-based adhesive is preferable.

Examples of a curable component in the (meth)acrylate-based adhesive include a compound having a (meth)acryloyl group and a compound having a vinyl group. Examples of the curable component in the epoxy-based adhesive include a compound having a glycidyl group.

A method of forming the adhesive layer is not particularly limited, and examples thereof include a method of applying an adhesive to at least one layer selected from the first optically anisotropic layer and the second optically anisotropic layer, bonding the first optically anisotropic layer and the second optically anisotropic layer, and curing the adhesive.

As the application method, a roll coating method such as reverse coating or gravure coating, a spin coating method, a screen coating method, a fountain coating method, a dipping method, and a spraying method can be employed.

The pressure-sensitive adhesive layer is a layer containing a pressure sensitive adhesive, and a known pressure-sensitive adhesive layer can be used.

Examples of the pressure sensitive adhesive contained in the pressure-sensitive adhesive layer include an acrylic pressure sensitive adhesive, an epoxy-based pressure sensitive adhesive, a rubber-based pressure sensitive adhesive, a silicone-based pressure sensitive adhesive, a urethane-based pressure sensitive adhesive, a vinyl alkyl ether-based pressure sensitive adhesive, a polyvinyl alcohol-based pressure sensitive adhesive, a polyvinylpyrrolidone-based pressure sensitive adhesive, a polyacrylamide-based pressure sensitive adhesive, and a cellulose-based pressure sensitive adhesive.

Among these, from the viewpoint of excellent transparency, weather fastness, heat resistance, and the like, an acrylic pressure sensitive adhesive (pressure-sensitive adhesive) is preferable.

The acrylic pressure sensitive adhesive is preferably a copolymer of a (meth)acrylate in which the alkyl group of the ester moiety is an alkyl group having 20 or less carbon atoms such as a methyl group, an ethyl group, or a butyl group with a (meth)acrylic monomer having a functional group such as (meth)acrylic acid or hydroxyethyl (meth)acrylate.

With regard to the pressure sensitive adhesive, reference can be made to the contents described in [0071] to [0084] of JP2018-60014A, the contents of which are incorporated herein by reference.

A method of forming the pressure-sensitive adhesive layer is not particularly limited, and examples thereof include a method of applying a solution of a pressure sensitive adhesive onto a release sheet, drying the solution, and transferring the solution to at least one layer selected from the first optically anisotropic layer and the second optically anisotropic layer, and a method of applying a solution obtained by dissolving or dispersing a pressure sensitive adhesive in a solvent (for example, toluene or ethyl acetate) onto a surface of at least one layer selected from the first optically anisotropic layer and the second optically anisotropic layer, and drying the solution.

As the above-described coating method, the method described as the method of applying an adhesive can be used.

Examples of the constituent material of the release sheet include appropriate thin paper bodies, for example, synthetic polymer films such as polyethylene, polypropylene, and polyethylene terephthalate, rubber sheets, paper, cloth, nonwoven fabrics, nets, foam sheets, and metal foils.

Among these, the isotropic layer A is preferably a pressure-sensitive adhesive layer or an ultraviolet curable adhesive layer, and more preferably an ultraviolet curable adhesive layer.

Thickness unevenness σ (unit: nm) of the isotropic layer A is often 100 nm or less, and from the viewpoint that the effect of the present invention is more excellent, the thickness unevenness σ is preferably 50 nm or less, more preferably 35 nm or less, and still more preferably 20 nm or less. In addition, from the viewpoint that air bubbles are less likely to enter during the bonding of the first optically anisotropic layer and the second optically anisotropic layer, the thickness unevenness σ of the isotropic layer A is preferably 5 nm or more. That is, the thickness unevenness σ of the isotropic layer A is preferably 5 to 35 nm, and more preferably 5 to 20 nm.

The thickness unevenness σ of the isotropic layer A is a value calculated as a standard deviation of the thicknesses of the adhesion layer at 31 points obtained in the measurement of the thickness of the isotropic layer A described above.

A method of adjusting the thickness unevenness of the isotropic layer A is not particularly limited, and examples thereof include a method of adjusting the composition, the viscosity, and the application method of the composition forming the isotropic layer A, and the conditions in a case of laminating the first optically anisotropic layer and the second optically anisotropic layer through the isotropic layer A.

From the viewpoint that the effect of the present invention is more excellent, an in-plane refractive index n of the isotropic layer A is preferably 1.48 or more, more preferably 1.51 or more, still more preferably 1.53 or more, and particularly preferably 1.56 or more. In addition, from the viewpoint that the effect of the present invention is more excellent, the in-plane refractive index n_{A} of the isotropic layer A is preferably 1.67 or less, more preferably 1.59 or less, and still more preferably 1.58 or less.

### [Isotropic Layer B]

The isotropic layer B may be an optically isotropic layer, and is preferably an adhesion layer.

Examples of the adhesion layer include the same adhesion layer as the isotropic layer A.

Among these, the isotropic layer B is preferably a pressure-sensitive adhesive layer or an ultraviolet curable adhesive layer.

From the viewpoint that the effect of the present invention is more excellent, a thickness of the isotropic layer B is preferably 0.5 μm or more, more preferably 1 μm or more, and still more preferably 2 μm or more. In addition, the thickness of the isotropic layer B is often 50 μm or less, preferably 20 μm or less, and more preferably 15 μm or less.

The thickness of the isotropic layer B can be calculated by the same method as that for the isotropic layer A described above.

Thickness unevenness σ (unit: nm) of the isotropic layer B is often 100 nm or less, and from the viewpoint that the effect of the present invention is more excellent, the thickness unevenness σ is preferably 50 nm or less, more preferably 35 nm or less, and still more preferably 20 nm or less. In addition, from the viewpoint that air bubbles are less likely to enter during the bonding of the first optically anisotropic layer and the polarizer, the thickness unevenness σ of the isotropic layer B is preferably 5 nm or more. That is, the thickness unevenness σ of the isotropic layer B is preferably 5 to 35 nm, and more preferably 5 to 20 nm.

The thickness unevenness σ of the isotropic layer B is a value calculated as a standard deviation of the thicknesses of the adhesion layer at 31 points obtained in the measurement of the thickness of the isotropic layer B described above.

A method of adjusting the thickness unevenness of the isotropic layer B is not particularly limited, and examples thereof include a method of adjusting the composition, the viscosity, and the application method of the composition forming the isotropic layer B, and the conditions in a case of laminating the first optically anisotropic layer and the polarizer through the isotropic layer B.

From the viewpoint that the effect of the present invention is more excellent, an in-plane refractive index n_{B} of the isotropic layer B is preferably 1.48 or more, more preferably 1.51 or more, still more preferably 1.53 or more, and particularly preferably 1.56 or more. In addition, from the viewpoint that the effect of the present invention is more excellent, the in-plane refractive index np of the isotropic layer B is preferably 1.67 or less, more preferably 1.59 or less, and still more preferably 1.58 or less.

### [Other Layers]

The polarizer may include a member other than those described above as long as the function of the present invention is not impaired.

Examples of the other layers include an alignment film, a substrate, and an optically anisotropic layer different from the first optically anisotropic layer and the second optically anisotropic layer.

### <Alignment Film>

The polarizing plate may include an alignment film. The alignment film may be disposed on a substrate described later or may be disposed between the optically anisotropic layers.

The alignment film can be formed by rubbing treatment of an organic compound (preferably a polymer), oblique vapor deposition of an inorganic compound, formation of a layer having microgrooves, accumulation of an organic compound (for example, ω-tricosanoic acid, dioctadecylmethylammonium chloride, or methyl stearate) by the Langmuir-Blodgett method (LB film), or the like.

In addition to the above, the alignment film may be an alignment film in which an alignment function is generated upon application of an electric field, upon application of a magnetic field, or upon irradiation with light (preferably polarized light).

Examples of the alignment film also include a photo-alignment film.

A thickness of the alignment film is not particularly limited as long as it can exhibit an alignment function, but is preferably 0.01 to 5.0 μm, more preferably 0.05 to 3.0 μm, and still more preferably 0.5 to 1.0 μm.

In a case where the alignment film is disposed on the substrate, the alignment film may be peelable from the optically anisotropic layer together with the substrate.

### <Substrate>

The polarizing plate may include a substrate.

The substrate is preferably a transparent substrate. The transparent substrate is intended to be a substrate having a transmittance of visible light (average transmittance in a visible ray region) 60% or more, and the transmittance is preferably 80% or more and more preferably 90% or more. The upper limit thereof is not particularly limited; however, it is preferably 99.9% or less.

A thickness of the substrate is not particularly limited, but is preferably 10 to 200 μm, more preferably 10 to 100 μm, and still more preferably 20 to 90 μm.

The substrate may contain various additives (for example, an optical anisotropy adjuster, a wavelength dispersion adjuster, fine particles, a plasticizer, an ultraviolet inhibitor, a deterioration inhibitor, a release agent, and the like).

A thickness of the substrate is not particularly limited, but is preferably 10 to 200 μm, more preferably 10 to 100 μm, and still more preferably 20 to 90 μm.

The substrate may consist of a plurality of layers laminated.

In addition, the substrate may be subjected to a surface treatment (for example, a glow discharge treatment, a corona discharge treatment, an ultraviolet (UV) treatment, or a flame treatment) on the surface of the substrate in order to improve adhesion with a layer provided thereon.

In addition, an adhesive layer (undercoat layer) may be provided on the substrate.

In addition, in order to impart slipperiness in a transport step and prevent a back surface and a front surface from sticking to each other after winding, a polymer layer in which inorganic particles having an average particle diameter of approximately 10 to 100 nm are mixed in a solid content mass ratio of 5% to 40% by mass may be disposed on one side of the substrate.

The substrate may be a so-called temporary support. That is, after the polarizing plate according to the embodiment of the present invention is manufactured on the substrate, the substrate may be peeled off from the optically anisotropic layer as necessary.

In a case where the above-described alignment film is formed on the surface of the substrate, a rubbing treatment may be directly performed on the surface of the substrate. That is, a substrate which has been subjected to the rubbing treatment may be used. A direction of the rubbing treatment is not particularly limited, and an optimum direction is appropriately selected according to the direction in which the liquid crystal compound is desired to be aligned.

A treatment method widely adopted as a liquid crystal alignment treatment step of a liquid crystal display (LCD) can be applied for the rubbing treatment. That is, a method of obtaining alignment by rubbing the surface of the substrate in a certain direction with paper, gauze, felt, rubber, nylon fiber, polyester fiber, or the like can be used.

In the polarizing plate according to the embodiment of the present invention, a combination of the first optically anisotropic layer and the second optically anisotropic layer may be appropriately selected, but a polarizing plate according to the following Aspect 1 or a polarizing plate according to the following Aspect 2 is preferable, and a polarizing plate according to Aspect 1 is more preferable from the viewpoint that the tint in a case of black display can be further suppressed.

(Aspect 1) The first optically anisotropic layer is a layer formed by fixing vertically aligned disk-like liquid crystal compounds, and the second optically anisotropic layer is the optically anisotropic layer (AB).

(Aspect 2) The first optically anisotropic layer is a layer formed by fixing vertically aligned disk-like liquid crystal compounds or a layer formed by fixing horizontally aligned rod-like liquid crystal compounds, and the second optically anisotropic layer is the optically anisotropic layer (C).

The definition and suitable aspects of the layer formed by fixing vertically aligned disk-like liquid crystal compounds, the optically anisotropic layer (AB), the layer formed by fixing horizontally aligned rod-like liquid crystal compounds, and the optically anisotropic layer (C) in each aspect are as described above.

The polarizing plate according to the above-described Aspect 1 will be described with reference to FIGS. 2 to 4.

FIG. 2 is a schematic cross-sectional view of a polarizing plate 100A according to Aspect 1.

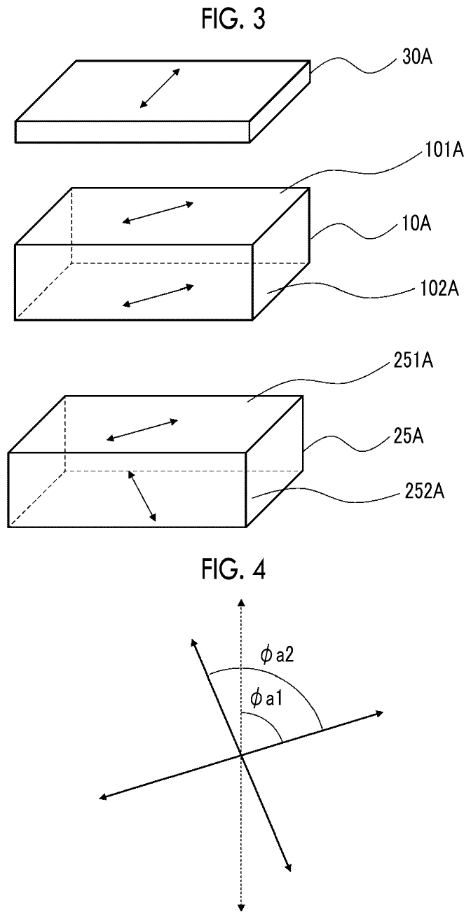

FIG. 3 is a view showing a relationship between an absorption axis of a polarizer 30A and in-plane slow axes of the first optically anisotropic layer 10A and the optically anisotropic layer (A) 25A in the polarizing plate 100A of Aspect 1 shown in FIG. 2. In FIG. 3, the arrow in the polarizer 30A indicates an absorption axis, and the arrow in the first optically anisotropic layer 10A and the optically anisotropic layer (A) 25A indicates an in-plane slow axis in each layer.

FIG. 4 is a view showing a relationship between the absorption axis (broken line) of the polarizer 30A and the in-plane slow axis (solid line) of each of the first optically anisotropic layer 10A and the optically anisotropic layer (A) 25A, upon observation from the white arrow side in FIG. 2. A rotation angle of the in-plane slow axes is represented by a positive angle value in a counterclockwise direction and a negative angle value in a clockwise direction, with respect to the absorption axis of the polarizer 30A (0°), upon observation from the white arrow side in FIG. 2. In addition, whether the twisted direction of the liquid crystal compound is a right-handed twist (clockwise) or a left-handed twist (counterclockwise) is determined with reference to the in-plane slow axis on the surface of the polarizer 30A side in the optically anisotropic layer (A) 25A, upon observation from the white arrow side in FIG. 2.

As shown in FIG. 2, the polarizing plate 100A according to Aspect 1 includes the polarizer 30A, the first optically anisotropic layer 10A, an isotropic layer A 40A, the optically anisotropic layer (A) 25A, and an optically anisotropic layer (B) 26A in this order. A laminate of the optically anisotropic layer (A) 25A and the optically anisotropic layer (B) 26A constitutes a second optically anisotropic layer. The polarizing plate 100A may include an isotropic layer B (not shown) between the polarizer 30A and the first optically anisotropic layer 10A.

In the polarizing plate 100A according to Aspect 1, as shown in FIGS. 3 and 4, an angle φa1 between the absorption axis of the polarizer 30A and the first optically anisotropic layer 10A is 76°. More specifically, the in-plane slow axis of the first optically anisotropic layer 10A is rotated by −76° (clockwise) 76° with respect to the absorption axis of the polarizer 30A. In FIGS. 3 and 4, an aspect in which φa1 is 76° is shown, but the present invention is not limited to this aspect, and φa1 is preferably 40° to 85°, more preferably 50° to 85°, and still more preferably 65° to 85°.

In addition, as shown in FIG. 3, in the first optically anisotropic layer 10A, the in-plane slow axis on a surface 101A of the first optically anisotropic layer 10A on the polarizer 30A side is parallel to the in-plane slow axis on a surface 102A of the first optically anisotropic layer 10A on the optically anisotropic layer (A) 25A side.

As shown in FIGS. 3 and 4, the in-plane slow axis on the surface 251A of the optically anisotropic layer (A) 25A on the first optically anisotropic layer 10A side is parallel to the in-plane slow axis of the first optically anisotropic layer 10A.

As described above, the optically anisotropic layer (A) 25A is a layer formed by fixing a twist-aligned rod-like liquid crystal compound with a thickness direction as a helical axis. Therefore, as shown in FIGS. 3 and 4, the in-plane slow axis on the surface 251A of the optically anisotropic layer (A) 25A on the first optically anisotropic layer 10A side and the in-plane slow axis on a surface 252A on the optically anisotropic layer (B) 26A side form the above-mentioned twisted angle (81° in FIG. 3). That is, an angle φa2 formed by the in-plane slow axis on the surface 251A of the optically anisotropic layer (A) 25A on the first optically anisotropic layer 10A side and the in-plane slow axis on the surface 252A on the optically anisotropic layer (B) 26A side is 81°. More specifically, a twisted direction of the rod-like liquid crystal compound in the optically anisotropic layer (A) 25A is a left-handed twist (counterclockwise), and a twisted angle thereof is 81°.

Although FIG. 3 and FIG. 4 show an aspect in which the twisted angle of the rod-like liquid crystal compound in the optically anisotropic layer (A) 25A is 81°, the present invention is not limited to this aspect. The twisted angle of the rod-like liquid crystal compound is preferably 50° to 110°, more preferably 60° to 100°, and still more preferably 70° to 90°.

In FIG. 3 and FIG. 4, the aspect in which the twisted direction of the rod-like liquid crystal compound is counterclockwise has been described in detail, but an aspect in which the twisted direction of the rod-like liquid crystal compound is clockwise may be configured as long as the relationship of the predetermined angle is satisfied. More specifically, it may be an aspect in which the in-plane slow axis of the first optically anisotropic layer 10A is rotated counterclockwise by 76°, and the twisted direction of the rod-like liquid crystal compound in the optically anisotropic layer (A) 25A is clockwise (right-handed twist), with reference to the absorption axis of the polarizer 30A, upon observation of the polarizing plate 100A from the polarizer 30A side.

That is, in the polarizing plate 100A, in a case where the in-plane slow axis of the first optically anisotropic layer is rotated clockwise within a range of 40° to 85° (preferably 50° to 85° and more preferably 65° to) 85° with reference to the absorption axis of the polarizer 30A, it is preferable that the twisted direction of the rod-like liquid crystal compound in the optically anisotropic layer (A) is counterclockwise with reference to the in-plane slow axis on the surface of the optically anisotropic layer (A) on the first optically anisotropic layer side.

In addition, in the polarizing plate 100A, in a case where the in-plane slow axis of the first optically anisotropic layer is rotated counterclockwise within a range of 40° to 85° (preferably 50° to 85° and more preferably 65° to) 85° with reference to the absorption axis of the polarizer 30A, it is preferable that the twisted direction of the rod-like liquid crystal compound in the optically anisotropic layer (A) is clockwise with reference to the in-plane slow axis on the surface of the optically anisotropic layer (A) on the first optically anisotropic layer side.

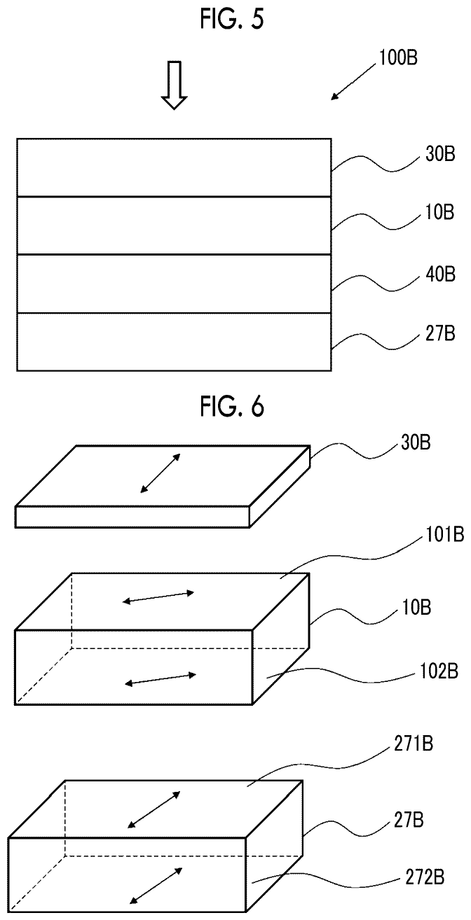

The polarizing plate according to the above-described Aspect 2 will be described with reference to FIGS. 5 to 7.

FIG. 5 is a schematic cross-sectional view of a polarizing plate 100B according to Aspect 2.

FIG. 6 is a view showing a relationship between an absorption axis of a polarizer 30B and in-plane slow axes of the first optically anisotropic layer 10B and the optically anisotropic layer (C) 27B in the polarizing plate 100B of Aspect 2 shown in FIG. 5. In FIG. 6, the arrow in the polarizer 30B indicates an absorption axis, and the arrow in the first optically anisotropic layer 10B and the optically anisotropic layer (C) 27B indicates an in-plane slow axis in each layer.

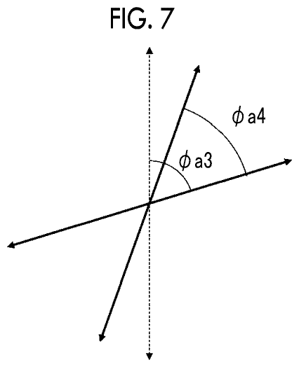

FIG. 7 is a view showing a relationship between the absorption axis (broken line) of the polarizer 30B and the in-plane slow axis (solid line) of each of the first optically anisotropic layer 10B and the optically anisotropic layer (C) 27B, upon observation from the white arrow side in FIG. 5. A rotation angle of the in-plane slow axes is represented by a positive angle value in a counterclockwise direction and a negative angle value in a clockwise direction, with respect to the absorption axis of the polarizer 30B (0°), upon observation from the white arrow side in FIG. 5.

As shown in FIG. 5, the polarizing plate 100B according to Aspect 2 includes the polarizer 30B, the first optically anisotropic layer 10B, an isotropic layer A40B, and the optically anisotropic layer (C) 27B in this order. The polarizing plate 100B may include an isotropic layer B (not shown) between the polarizer 30B and the first optically anisotropic layer 10B.

In the polarizing plate 100B according to Aspect 2, as shown in FIGS. 6 and 7, an angle φa3 between the absorption axis of the polarizer 30B and the first optically anisotropic layer 10B is 73°. More specifically, the in-plane slow axis of the first optically anisotropic layer 10B is rotated by −73° (clockwise) 73° with respect to the absorption axis of the polarizer 30B. In FIGS. 6 and 7, an aspect in which φa3 is 73° is shown, but the present invention is not limited to this aspect, and φa3 is preferably 40° to 85°, more preferably 50° to 85°, and still more preferably 65° to 85°.

In addition, as shown in FIG. 6, in the first optically anisotropic layer 10B, the in-plane slow axis on a surface 101B of the first optically anisotropic layer 10B on the polarizer 30B side is parallel to the in-plane slow axis on a surface 102B of the first optically anisotropic layer 10B on the optically anisotropic layer (C) 27B side.

As shown in FIGS. 6 and 7, an angle φa4 between the in-plane slow axis of the first optically anisotropic layer 10B and the in-plane slow axis of the optically anisotropic layer (C) 27B is 58°. More specifically, the in-plane slow axis of the optically anisotropic layer (C) 27B is rotated by 58° (58° counterclockwise) with respect to the in-plane slow axis of the first optically anisotropic layer 10B. FIGS. 6 and 7 show an aspect in which φa4 is 58°, but the present invention is not limited to this aspect, and φa4 is preferably 30° to 120°, more preferably 40° to 80°, and still more preferably 50° to 70°.

In addition, as shown in FIG. 5, in the optically anisotropic layer (C) 27B, the in-plane slow axis on a surface 271B of the optically anisotropic layer (C) 27B on the first optically anisotropic layer 10B side and the in-plane slow axis on a surface 272B of the optically anisotropic layer (C) 27B on the side opposite to the first optically anisotropic layer 10B are parallel to each other.

In FIGS. 5 to 7, an aspect in which the in-plane slow axis of the first optically anisotropic layer 10B is rotated clockwise with respect to the absorption axis of the polarizer 30B has been described in a case where the polarizing plate 100B is observed from the polarizer 30B side, but an aspect in which the in-plane slow axis of the first optically anisotropic layer 10B is rotated counterclockwise within a range of 40° to 85° (preferably 50° to 85° and more preferably 65° to) 85° may be adopted. For example, in a case where the polarizing plate 100B is observed from the polarizer 30B side, in a case where the in-plane slow axis of the first optically anisotropic layer 10B is rotated counterclockwise within a range of 40° to 85° with respect to the absorption axis of the polarizer 30B, it is preferable that the in-plane slow axis of the optically anisotropic layer (C) 27B is rotated clockwise within a range of 60°+30° with respect to the in-plane slow axis of the first optically anisotropic layer 10B.

### [Manufacturing Method of Polarizing Plate]

A manufacturing method of the polarizing plate is not particularly limited.

For example, the polarizing plate can be manufactured by producing a polarizer, a first optically anisotropic layer, and a second optically anisotropic layer, and laminating the polarizer, the first optically anisotropic layer, and the second optically anisotropic layer in a predetermined direction through an isotropic layer.

The method of producing the above-described polarizer is as described above.

Examples of the above-described laminating method include a method of bonding adjacent layers using an adhesion layer as an isotropic layer. The adhesion layer is not particularly limited, and examples thereof include the adhesion layers described as the isotropic layer A and the isotropic layer B.

In a case where the adhesion layer is an adhesive layer, it is preferable to perform a curing treatment of the adhesive layer after bonding. A method of the curing treatment can be appropriately selected depending on the type of the adhesive layer, and examples thereof include a heating treatment and an active energy ray irradiation treatment.

In order to improve adhesiveness before forming and bonding the adhesion layer, a surface treatment (for example, a glow discharge treatment, a corona discharge treatment, an ultraviolet (UV) treatment, or a flame treatment) may be performed on each optically anisotropic layer (for example, the first optically anisotropic layer and the second optically anisotropic layer).

The first optically anisotropic layer and the second optically anisotropic layer can be produced using, for example, a composition for forming an optically anisotropic layer, which contains a liquid crystal compound.

Hereinafter, a method of forming an optically anisotropic layer using a composition for forming an optically anisotropic layer will be described in detail.

### [Method of Forming Optically Anisotropic Layer]

The optically anisotropic layer can be formed using a composition for forming an optically anisotropic layer.

### <Composition for Forming Optically Anisotropic Layer>

The liquid crystal compound contained in the composition for forming an optically anisotropic layer is the same as the liquid crystal compound contained in each of the above-described optically anisotropic layers. As described above, a rod-like liquid crystal compound and a disk-like liquid crystal compound are appropriately selected according to the characteristics of an optically anisotropic layer to be formed.

As described above, the liquid crystal compound is preferably a polymerizable liquid crystal compound having a polymerizable group. The polymerizable group is as described above.

The content of the liquid crystal compound in the composition for forming an optically anisotropic layer is preferably 60% to 99% by mass, and more preferably 70% to 98% by mass with respect to the total solid content of the composition for forming an optically anisotropic layer. The solid content means a component capable of forming an optically anisotropic layer, excluding a solvent, and even in a case where a component itself is in a liquid state, such a component is regarded as the solid content.

The composition for forming an optically anisotropic layer may contain a compound other than the liquid crystal compound. Examples of the other compound include a chiral agent, a photo-alignable compound (photo-alignment polymer), a polymerization initiator, a polyfunctional monomer, an alignment control agent (a vertical alignment agent or a horizontal alignment agent), a leveling agent, a surfactant, an adhesion improver, a plasticizer, and a solvent.

For example, a composition for forming an optically anisotropic layer, which is for forming the optically anisotropic layer (A), preferably contains a chiral agent in order to twist-align the liquid crystal compound. It is not necessary to add the chiral agent in a case where the liquid crystal compound is a compound exhibiting an optical activity such as having an asymmetric carbon in a molecule. In addition, it is not necessary to add the chiral agent depending on the manufacturing method and the twisted angle.

The chiral agent is not particularly limited as long as it is compatible with the liquid crystal compound used in combination, and a known chiral agent can be used and may be appropriately selected depending on the sense and pitch of the desired helix.

As the chiral agent, for example, the compounds described in “Liquid Crystal Device Handbook, Chapter 3, Section 4-3, chiral agents for TN and STN, p. 199, edited by the 142nd Committee of the Japan Society for the Promotion of Science, 1989”, and JP2003-287623A, JP2002-302487A, JP2002-080478A, JP2002-080851A, JP2010-181852A, JP2014-034581A, and the like can be used.

Among these, a compound selected from the group consisting of an isosorbide derivative, an isomannide derivative, and a binaphthyl derivative is preferable as the chiral agent. As the isosorbide derivative, a commercially available product such as LC-756 (manufactured by BASF SE) may be used.

The chiral agent may also have a polymerizable group. Examples of the polymerizable group that the chiral agent may have include the polymerizable group that the above-described liquid crystal compound may have, and a suitable aspect thereof is also the same.

The content of chiral agent is preferably 0.01% to 200 mol % and more preferably 1% to 30 mol % with respect to the content of the liquid crystal compound.

The photo-alignable compound is a compound having a photo-aligned group, and the photo-aligned group can be aligned in a predetermined direction by irradiation with light.

As the photo-alignable compound, a photo-alignment polymer is preferable. The photo-alignment polymer is not particularly limited as long as the photo-alignment polymer is compatible with the liquid crystal compound used in combination, and a known photo-alignment polymer can be used.

The composition for forming an optically anisotropic layer may contain a polymerization initiator. The polymerization initiator to be used is selected depending on the type of the polymerization reaction, and examples thereof include a thermal polymerization initiator and a photopolymerization initiator.

The content of the polymerization initiator in the composition for forming an optically anisotropic layer is preferably 0.01% to 20% by mass, and more preferably 0.5% to 10% by mass with respect to the total solid content of the composition for forming an optically anisotropic layer.

### <Procedure for Forming Optically Anisotropic Layer>

A procedure for forming an optically anisotropic layer is not particularly limited, and examples thereof include a method including, in the following order, a coating step of coating a substrate with the above-described composition for forming an optically anisotropic layer, an alignment step of subjecting the formed coating film to an alignment treatment to align the liquid crystal compound, and an alignment fixing step of subjecting the liquid crystal compound to a curing treatment to fix the liquid crystal compound.

Examples of the above-described substrate include the substrate which may be included in the above-described polarizing plate.

The optically anisotropic layer may be directly formed on the optically anisotropic layer using the composition for forming an optically anisotropic layer. By coating the produced optically anisotropic layer with the composition for forming an optically anisotropic layer and subjecting the composition to a predetermined treatment to form an optically anisotropic layer, a laminate in which two or more optically anisotropic layers are directly laminated without an adhesion layer can be produced. In a case where the optically anisotropic layer is directly formed on the optically anisotropic layer using the composition for forming an optically anisotropic layer, a treatment of forming an alignment film may be performed on the surface of the optically anisotropic layer before coating with the composition for forming an optically anisotropic layer.

A coating method in the coating step is not particularly limited, and examples thereof include an extrusion coating method, a curtain coating method, a dip coating method, a spin coating method, a printing coating method, a spray coating method, a slot coating method, a roll coating method, a slide coating method, a blade coating method, a gravure coating method, a die-coating method, and a wire bar method.

After the application of the composition for forming an optically anisotropic layer, a treatment of drying the coating film applied to the substrate may be performed as necessary. The solvent can be removed from the coating film by the drying treatment.

The thickness of the coating film is not particularly limited, but is preferably 0.1 to 20 μm, more preferably 0.2 to 15 μm, and still more preferably 0.5 to 10 μm.

The alignment treatment in the alignment step can be performed by drying the coating film at room temperature or by heating the coating film. In a case of a thermotropic liquid crystal compound, a liquid crystal phase formed by the alignment treatment can generally be transferred by a change in temperature or pressure. In a case of a lyotropic liquid crystal compound, the liquid crystal phase can also be transferred according to a compositional ratio such as the amount of a solvent.

Note that the conditions in a case of heating the coating film are not particularly limited, and the heating temperature is preferably 50 °C to 250 °C and more preferably 50 °C to 150 °C, and the heating time is preferably 10 seconds to 10 minutes.

In addition, after the coating film is heated, the coating film may be cooled, as necessary, before a curing treatment (light irradiation treatment) which will be described later. The cooling temperature is preferably 20 °C to 200 °C and more preferably 30 °C to 150 °C.

In a case where the composition for forming an optically anisotropic layer contains a photo-alignment polymer, it is preferable to perform a photo-alignment treatment from the viewpoint of imparting the alignment control ability.

Examples of the photo-alignment treatment include a method of irradiating a coating film (including a cured film subjected to a curing treatment) of a polymerizable liquid crystal composition with polarized light or irradiating the surface of the coating film with unpolarized light from an oblique direction.

A wavelength of the polarized light or the unpolarized light is not particularly limited as long as the light is light to which the photo-aligned group is photosensitive. Examples thereof include ultraviolet rays, near-ultraviolet rays, and visible rays, and near-ultraviolet rays of 250 to 450 nm are preferable.

In addition, examples of the light source for applying polarized light or unpolarized light include a xenon lamp, a high-pressure mercury lamp, an ultra-high pressure mercury lamp, and a metal halide lamp. By using a dichroic filter, a color filter, or the like with respect to ultraviolet rays or visible rays obtained from the light source, the wavelength range of the irradiation can be restricted. In addition, linearly polarized light can be obtained by using a polarization filter or a polarization prism with respect to the light from the light source.

An integrated quantity of the polarized light or the unpolarized light is not particularly limited, and is preferably 1 to 300 mJ/cm² and more preferably 5 to 100 mJ/cm².

An illuminance of the polarized light or the unpolarized light is not particularly limited, and is preferably 0.1 to 300 mW/cm² and more preferably 1 to 100 mW/cm².

The method for the curing treatment in the alignment fixing step is not particularly limited, and examples thereof include a light irradiation treatment and a heating treatment. Among these, from the viewpoint of manufacturing suitability, a light irradiation treatment is preferable, and an ultraviolet irradiation treatment is more preferable.

Irradiation conditions of the light irradiation treatment are not particularly limited, and an irradiation amount of 50 to 1,000 mJ/cm² is preferable.

The atmosphere during the light irradiation treatment is not particularly limited, but is preferably a nitrogen atmosphere.

### <Method of Forming Optically Anisotropic Layer Having Specific Region>

The above-described method of forming the optically anisotropic layer having a specific region is not particularly limited, and examples thereof include the following Method 1 and Method 2.

### (Method 1)

Method 1 is a method using a photoisomerizable liquid crystal compound having a photoisomerization moiety. More specifically, Method 1 is a method including the above-described coating film forming step, alignment step, and alignment fixing step in this order, in which a composition containing a photoisomerizable liquid crystal compound is used as the composition for forming an optically anisotropic layer, and the method further includes an isomerization step of isomerizing the photoisomerizable liquid crystal compound between the alignment step and the alignment fixing step.

The above-described photoisomerizable liquid crystal compound is photoisomerized in the coating film of the composition for forming an optically anisotropic layer, so that a three-dimensional structure is changed and optical properties (for example, a birefringence index) are changed. In a case where the surface is irradiated with light, in a case where a phenomenon in which an intensity of light is attenuated in the thickness direction is used, a proportion of the liquid crystal compound to be photoisomerized can be reduced from the surface side along the thickness direction. Therefore, a specific region where the in-plane birefringence gradually increases along the thickness direction can be formed by a method including forming a coating film using a composition for forming an optically anisotropic layer including a photoisomerizable liquid crystal compound, aligning the liquid crystal compound, and irradiating at least one surface with light to photoisomerize the photoisomerizable liquid crystal compound.

In a case where the optically anisotropic layer is any layer selected from an A-Plate, a C-Plate, and a chiral nematic phase, the optically anisotropic layer having a specific region can be suitably formed by Method 1.

The C-Plate is a plate that satisfies any of Expression (C1) or Expression (C2) in a case where a refractive index in an in-plane slow axis direction is defined as nx, a refractive index in a direction orthogonal to the in-plane slow axis in the plane is defined as ny, and a refractive index in a thickness direction is defined as nz. In a case where Expression (C1) is satisfied, the C-Plate is a so-called positive C-Plate; and in a case where Expression (C2) is satisfied, the C-Plate is a so-called negative C-Plate. The positive C-Plate has an Rth showing a negative value and the negative C-Plate has an Rth showing a positive value.

nz>nx≈ny Expression (C1)

nz<nx≈ny Expression (C2)

The symbol “≈” encompasses not only a case where both sides are completely the same as each other but also a case where both sides are substantially the same as each other. The expression “substantially the same” means that, for example, a case where (nx−ny)×d (in which d is a thickness of a film) is 0 to 10 nm and preferably 0 to 5 nm is also included in “nx≈ny”.

### —Photoisomerizable Liquid Crystal Compound—

As described above, the photoisomerizable liquid crystal compound is a compound having a photoisomerization moiety whose three-dimensional structure is changed by being isomerized by light. Representative examples of the photoisomerization include cis-trans photoisomerization of a carbon-carbon double bond. Specific examples of the photoisomerization moiety include cinnamoyl, chalcone, and stilbene.

The photoisomerizable liquid crystal compound is preferably a compound in which a birefringence index is reduced by photoisomerization.

A photoisomerization wavelength of the photoisomerizable liquid crystal compound is preferably different from a wavelength of light used in the above-described alignment fixing step.

The photoisomerizable liquid crystal compound may be either a rod-like liquid crystal compound or a disk-like liquid crystal compound.

The photoisomerizable liquid crystal compound is preferably a compound having a cinnamoyl moiety represented by Formula (W-1) below as a photoisomerization moiety or a compound having a stilbene moiety represented by Formula (W-2) below. A benzene ring in Formula (W-1) and Formula (W-2) may have a substituent. In Formula (W-1) and Formula (W-2), * represents a bonding position.

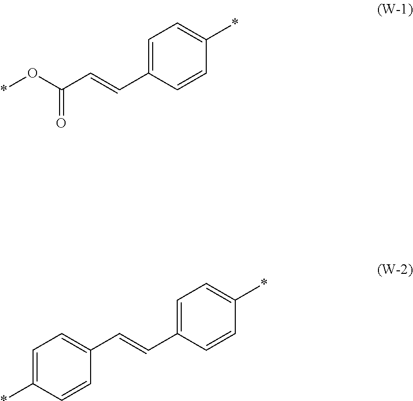 [SMILES: *OC(=O)/C=C/c1ccc(*)cc1 ; *c1ccc(/C=C/c2ccc(*)cc2)cc1]

The rod-like liquid crystal compound capable of photoisomerization preferably has a photoisomerization moiety in a mesogen.

Examples of the photoisomerizable rod-like liquid crystal compound include a compound represented by Formula (A1).

P¹-SP¹-(Cy¹-L¹)ₙ₁-W-(L²-Cy²)ₙ₂-SP²-P¹ Formula (A1)

In Formula (A1), P¹ and P² each independently represent a polymerizable group. The polymerizable group is preferably a functional group capable of an addition polymerization reaction, more preferably a polymerizable ethylenically unsaturated group or a ring-polymerizable group, and still more preferably a (meth)acryloyl group, a (meth)acryloyloxy group, a (meth)acrylamide group, a vinyl group, a styryl group, or an allyl group.

In Formula (A1), SP¹ and SP² each independently represent a spacer group,

The spacer group is not particularly limited as long as it is a divalent linking group not including a ring structure, and examples thereof include a divalent chain-like aliphatic hydrocarbon group having 1 to 20 carbon atoms.

As the divalent chain-like aliphatic hydrocarbon group having 1 to 20 carbon atoms, an alkylene group having 1 to 15 carbon atoms is preferable, and an alkylene group having 1 to 8 carbon atoms is more preferable.

One or more of —CH₂-'s constituting the divalent chain-like aliphatic hydrocarbon group may be each independently substituted with a group selected from —O—, —S—, —CO—, and —N(Q)-. Two or more —CH₂-'s may be substituted as long as the same groups are not adjacent to each other. Q represents a hydrogen atom or a substituent. As the substituent represented by Q, an alkyl group is preferable, a linear alkyl group having 1 to 4 carbon atoms is more preferable, and a methyl group or an ethyl group is still more preferable.

Among these, as the spacer group, *—(CH₂—CH₂—O)ₙₛ₁—*, *—(CH₂)ₙₛ₂—O—*, or *—(CH₂)ₙₛ₂—O—CO—* is preferable, * represents a bonding position, ns1 represents an integer of 1 to 4, and ns2's each independently represent an integer of 1 to 6 and are preferably an integer of 2 to 4.

In Formula (A1), Cy¹ and Cy² each independently represent a divalent ring group which may have a substituent.

The divalent ring group may be any of a monocyclic ring or a polycyclic ring, and is preferably a monocyclic ring.

The number of ring members in the divalent ring group is preferably 5 to 18, more preferably 5 to 10, and still more preferably 5 or 6.

Examples of the divalent ring group include a divalent aromatic ring group and a divalent alicyclic group.

Examples of the divalent aromatic ring group include a divalent aromatic hydrocarbon ring group in which two hydrogen atoms have been removed from an aromatic hydrocarbon ring and a divalent aromatic heterocyclic group in which two hydrogen atoms have been removed from an aromatic heterocyclic ring. Examples of the aromatic hydrocarbon ring include a benzene ring, a naphthalene ring, an anthracene ring, and a phenanthroline ring. Examples of the aromatic heterocyclic ring include a pyridine ring, a pyridazine ring, an imidazole ring, a thiophene ring, a quinoline ring, an isoquinoline ring, an oxazole ring, a thiazole ring, an oxadiazole ring, a benzothiazole ring, a benzothiadiazole ring, a phthalimide ring, a thienothiazole ring, a thiazolothiazole ring, a thienothiophene ring, and a thienooxazole ring. Among these, a group in which two hydrogen atoms have been removed from a benzene ring (for example, a 1,4-phenylene group) is preferable.

Examples of the divalent alicyclic group include a divalent aliphatic hydrocarbon ring group in which two hydrogen atoms have been removed from an aliphatic hydrocarbon ring (for example, a cycloalkane or a cycloalkene) and a divalent aliphatic heterocyclic group in which two hydrogen atoms have been removed from an aliphatic heterocyclic ring. Examples of the aliphatic hydrocarbon ring include a cyclopentane ring, a cyclohexane ring, a cycloheptane ring, a cyclooctane ring, a cyclononane ring, a cyclododecane ring, and a cyclodocosane ring. Examples of the aliphatic heterocyclic group include a pyrrolidine ring, an oxolane ring, a thiolane ring, a piperidine ring, a tetrahydropyran ring, a thiane ring, a piperazine ring, and a morpholine ring. Among these, a group in which two hydrogen atoms have been removed from a cyclohexane ring (for example, a 1,4-cyclohexylene group) is preferable.

The divalent ring group is preferably a divalent aromatic ring group or a divalent aliphatic hydrocarbon ring group, and more preferably a divalent aromatic ring group.

Examples of the substituent which may be included in the divalent ring group include an alkyl ester group, an alkyl group which may have a halogen atom, an acyl group, an alkoxy group, an alkylthio group, an alkyloxycarbonyl group, a carbamoyl group, an acylamino group, a halogen atom, a cyano group, and a nitro group, and an alkyl ester group, an alkyl group, or an acyl group is preferable, a methyl ester group, a linear alkyl group having 1 to 4 carbon atoms, or an acetyl group is more preferable, and a methyl ester group, a methyl group, or an ethyl group is still more preferable.

In Formula (A1), L¹ and L² each independently represent a single bond or a divalent linking group.

Examples of the divalent linking group include —CO—, —O—, —S—, —C(═S)—, —CR^{L1}R^{L2}—, —CR^{L3}═CR^{L4}—, and —NR^{L5}—, and a combination of two or more of these groups. R^{L1} to R^{L5} each independently represent a hydrogen atom or a substituent. As the substituent represented by R^{L1} to R^{L5}, a halogen atom, an alkyl group having 1 to 12 carbon atoms, or an alkoxy group having 1 to 12 carbon atoms is preferable.

L¹¹ is preferably —CO—, —O—, —CR^{L1}R^{L2}—, —NR^{L5}—, or a combination of two of these groups.

In Formula (A1), n1 and n2 each independently represent an integer of 0 or more.

The sum of n1 and n2 is preferably an integer of 1 to 10, more preferably an integer of 1 to 3, and still more preferably 1.

In Formula (A1), W represents the group represented by Formula (W-1) or the group represented by Formula (W-2), and the group represented by Formula (W-1) is preferable.

Specific examples of the rod-like liquid crystal compound capable of photoisomerization include the following compounds.

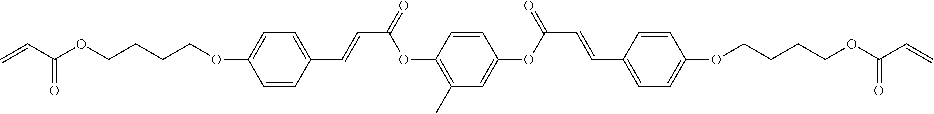 [SMILES: C=CC(=O)OCCCCOc1ccc(/C=C/C(=O)Oc2ccc(OC(=O)/C=C/c3ccc(OCCCCOC(=O)C=C)cc3)c(C)c2)cc1]

The photoisomerizable disk-like liquid crystal compound preferably has a photoisomerization moiety at a site adjacent to a mesogen moiety of the disk-like liquid crystal compound.

Examples of the photoisomerizable disk-like liquid crystal compound include a compound represented by Formula (A2).

M¹-(L³-W-L⁴-P³)m Formula (A2)

In Formula (A2), M¹ represents an m-valent disk-like mesogen group. Examples of the m-valent disk-like mesogen group include known disk-like mesogen groups, and examples thereof include mesogen groups included in the disk-like liquid crystal compounds described in JP2007-108732A and JP2010-244038A.

In Formula (A2), L³ and L⁴ each independently represent a single bond or a divalent linking group. Examples of the divalent linking group represented by L³ and L⁴ include the groups exemplified as the divalent linking group represented by L¹ and L² in Formula (A1) described above.

L³ is preferably a single bond.
L⁴ is preferably —CO—, —O—, —CR^{L1}R^{L2}—, —NR^{L5}—, or a combination of these groups.

In Formula (A2), P³'s each independently represent a polymerizable group. The definition and suitable aspect of the polymerizable group represented by P³ are the same as those of the polymerizable group represented by P¹ and P² in Formula (A1).

In Formula (A2), m represents an integer of 3 or more. m is preferably an integer of 3 to 10 and more preferably an integer of 4 to 8.

In Formula (A2), W represents the group represented by Formula (W-1) or the group represented by Formula (W-2), and the group represented by Formula (W-1) is preferable.

Specific examples of the photoisomerizable disk-like liquid crystal compound include compounds shown below.

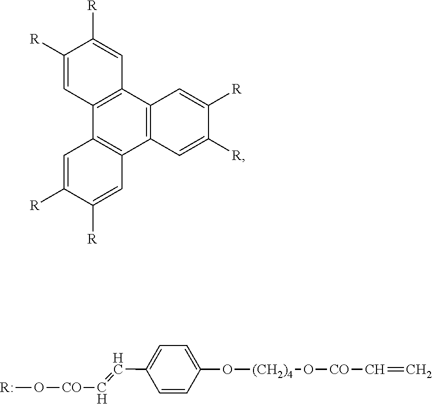

The photoisomerizable liquid crystal compound may be used alone or in combination of two or more kinds thereof.

In a case where the optically anisotropic layer having a specific region is formed using Method 1, a liquid crystal compound having no photoisomerization moiety and the photoisomerizable liquid crystal compound may be used in combination.

A content of the photoisomerizable liquid crystal compound can be appropriately adjusted according to the thickness of the desired specific region.

The content of the photoisomerizable liquid crystal compound is preferably 10% to 100% by mass and more preferably 30% to 100% by mass with respect to the total amount of the liquid crystal compound.

The content of the photoisomerizable liquid crystal compound is preferably 30% to 98% by mass and more preferably 60% to 95% by mass with respect to the total solid content of the composition for forming an optically anisotropic layer.

The light for isomerizing the photoisomerizable liquid crystal compound is not particularly limited, but is preferably different from the light used in the alignment step and the alignment fixing step.

Examples of the wavelength of the light for isomerizing the photoisomerizable liquid crystal compound include ultraviolet rays, near-ultraviolet rays, and visible rays, and light having a wavelength of 300 to 330 nm is preferable.

The irradiation conditions of the light are not particularly limited and can be adjusted according to the kind and concentration of the photoisomerizable liquid crystal compound to be used and the thickness of the desired specific region. The irradiation amount of the light and the thickness of the specific region can be determined using, for example, the Beer-Lambert Law.

The irradiation amount of the light irradiation treatment is, for example, 10 to 500 mJ/cm² in many cases and 30 to 200 mJ/cm² in more cases.

In a case where the specific region is formed on one surface side of the optically anisotropic layer, the optically anisotropic layer having the specific region on one surface can be formed by irradiating one surface side (preferably, a surface opposite to the substrate side) of the coating film of the composition for forming an optically anisotropic layer with light to perform photoisomerization.

In a case where the specific region is formed on both surfaces of the optically anisotropic layer, the optically anisotropic layer having the specific region on both surfaces can be formed by irradiating both surfaces of the coating film of the composition for forming an optically anisotropic layer, that is, the surface on the substrate side and the surface opposite to the substrate side, with light.

### (Method 2)

Method 2 is a method using a composition for forming an optically anisotropic layer, containing a surfactant having a mesogen group. In other words, Method 2 is a method including the above-described coating film forming step, alignment step, and alignment fixing step in this order, in which a composition for forming an optically anisotropic layer, containing a surfactant having a mesogen group, is used as the composition for forming an optically anisotropic layer.

In a case where the surfactant unevenly distributed on the surface side of the coating film of the composition for forming an optically anisotropic layer has a predetermined mesogen group, the alignment of the liquid crystal compound changes from the surface side of the coating film along the thickness direction, and a specific region where the in-plane birefringence gradually increases along the thickness direction can be formed.

In a case where the optically anisotropic layer is a chiral nematic phase, an optically anisotropic layer having a specific region on one surface can be suitably formed by Method 2.

For example, in a case where the composition for forming an optically anisotropic layer forming a chiral nematic phase contains a surfactant having a vertically aligned mesogen group, the rod-like liquid crystal compound that is horizontally aligned with respect to the main surface while being twisted with the thickness direction as a helical axis takes twisted alignment such that the rod-like liquid crystal compound is vertically aligned toward the surface side, and thus the in-plane birefringence gradually decreases from the region where the rod-like liquid crystal compound is horizontally aligned toward the surface side.

Examples of the surfactant having a mesogen group include a polymer having a repeating unit having an uneven distribution group and a repeating unit having a mesogen group.

### —Repeating Unit Including Uneven Distribution Group—

The uneven distribution group means a group that is unevenly distributed on the air interface side of the coating film in a case where a coating film is formed using a composition containing a compound having an uneven distribution group. Examples of the uneven distribution group include a group having a fluorine atom and a group having a silicon atom.

Examples of the group having a fluorine atom include an alkyl group in which at least one hydrogen atom is substituted with a fluorine atom (fluoroalkyl group) and an alkenyl group in which at least one hydrogen atom is substituted with a fluorine atom (fluoroalkenyl group), and a fluoroalkyl group is preferable.

The number of carbon atoms in the fluoroalkyl group is preferably 1 to 20 and more preferably 1 to 10.

The number of carbon atoms in the fluoroalkenyl group is preferably 2 to 20 and more preferably 2 to 10.

The number of fluorine atoms in the fluoroalkyl group and the fluoroalkenyl group is preferably 1 to 25, more preferably 3 to 21, and still more preferably 5 to 21.

The group containing a fluorine atom is preferably a group represented by Formula (F1).

*—(CH₂)ₘₐ(CF₂)_{mb}CF₂X Formula (F1)

In Formula (F1), * represents a bonding position.

ma and mb each independently represent an integer of 0 or more.

ma is preferably an integer of 0 to 10, more preferably an integer of 0 to 6, and still more preferably an integer of 1 to 3.

mb is preferably an integer of 0 to 12, more preferably an integer of 0 to 8, still more preferably an integer of 0 to 5, and particularly preferably an integer of 3 to 5.

X represents a hydrogen atom or a fluorine atom, and a fluorine atom is preferable.

The group containing a silicon atom is preferably a group represented by Formula (S1).

*-L^{s1}-(SiR¹¹R¹²R¹³)ₘₛ Formula (S1)

In Formula (S1), * represents a bonding position,

In Formula (S1), L^{s1} represents an (ms+1)-valent linking group.

Suitable examples of the (ms+1)-valent linking group include an (ms+1)-valent hydrocarbon group having 1 to 10 carbon atoms, which may have a substituent, in which a part of carbon atoms constituting the hydrocarbon group may be substituted with a heteroatom.

As the substituent which may be included in the above-described hydrocarbon group, an alkyl group is preferable, a linear alkyl group having 1 to 4 carbon atoms is more preferable, and a methyl group or an ethyl group is still more preferable.

Examples of the heteroatom which may replace a part of the above-described carbon atoms include a silicon atom, an oxygen atom, and a nitrogen atom.

Examples of L^{s1} include a group represented by Structural Formula K-1-L, a group represented by Structural Formula K-2-L, and a group represented by Structural Formula K-3-L. In the following structural formulae, * represents * in Formula (S1), and ** represents a bonding position to the group represented by —SiR¹¹R¹²R¹³ in Formula (S1).

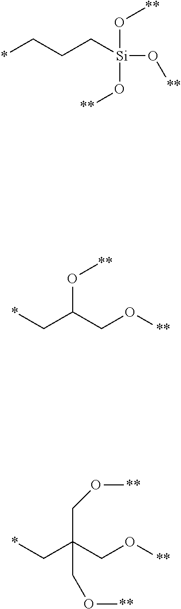

In Formula (S1), R¹¹, R¹², and R¹³ each independently represent an alkyl group, an alkenyl group, an aryl group, or an alkylene aryl group, which may have a substituent. As the substituent, a halogen atom, an alkyl group, an alkylcarbonyl group, an alkyloxycarbonyl group, an alkylcarbonyloxy group, or an alkoxy group is preferable.

Examples of the above-described alkyl group include a linear alkyl group having 1 to 18 carbon atoms and a branched or cyclic alkyl group having 3 to 18 carbon atoms.

Examples of the alkenyl group include an alkenyl group having 2 to 12 carbon atoms.

Examples of the aryl group include an aryl group having 6 to 12 carbon atoms.

Examples of the alkylene aryl group include an alkylene aryl group having 7 to 30 carbon atoms.

It is preferable that R¹¹, R¹², and R¹³ are all alkyl groups.

The repeating unit having an uneven distribution group is preferably a repeating unit represented by Formula (B1).

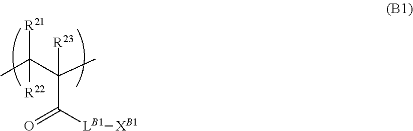

In Formula (B1), R²¹ and R²² each independently represent a hydrogen atom or an alkyl group.

Examples of the above-described alkyl group include a linear alkyl group having 1 to 18 carbon atoms and a branched or cyclic alkyl group having 3 to 18 carbon atoms.

It is preferable that R²¹ and R²² are each a hydrogen atom.

In Formula (B1), R²³ represents a hydrogen atom or a substituent.

Examples of the substituent include an alkyl group, an alkenyl group, an aryl group, a group represented by Formula (F1), and a group represented by Formula (S1).

R²³ is preferably a hydrogen atom or an alkyl group, more preferably a hydrogen atom or a linear alkyl group having 1 to 4 carbon atoms, still more preferably a hydrogen atom, a methyl group, or an ethyl group, and particularly preferably a hydrogen atom or a methyl group.

In Formula (B1), L^{B1} represents a single bond, —O—, or —NR^{Z}—. R^{Z} represents a hydrogen atom or a substituent.

Examples of the substituent represented by R^{Z} include the groups exemplified as the substituent represented by R²³, and an alkyl group is preferable, a linear alkyl group having 1 to 4 carbon atoms is more preferable, and a methyl group or an ethyl group is still more preferable.

L^{B1} is preferably —O— or —NH—, and more preferably —O—.

In Formula (B1), X^{B1} represents an uneven distribution group.

The definition of the uneven distribution group is as described above, and a group containing a fluorine atom or a group containing a silicon atom is preferable, and a group represented by Formula (F1) or a group represented by Formula (S1) is more preferable.

The repeating unit having an uneven distribution group may be used alone or in combination of two or more kinds thereof.

A content of the repeating unit having an uneven distribution group is preferably 10% to 90% by mass, more preferably 15% to 80% by mass, and still more preferably 20% to 70% by mass with respect to all repeating units (100% by mass) constituting the main chain of the surfactant.

### —Repeating Unit Containing Mesogen Group—

The mesogen group in the repeating unit having a mesogen group is not particularly limited, and a known mesogen group can be used, and for example, “Flussige Kristalle in Tabellen II” (VEB Deutsche Verlag fur Grundstoff Industrie, Leipzig, 1984), particularly the description on pages 7 to 16, and “Liquid Crystal Handbook” (Maruzen, 2000), particularly the description in Chapter 3, edited by the Liquid Crystal Handbook Editing Committee, can be referred to.

As the mesogen group, for example, a group having at least one cyclic structure selected from the group consisting of an aromatic hydrocarbon group, a heterocyclic group, and an alicyclic group is preferable.

From the reason that the alignment degree of the liquid crystal compound is improved, the mesogen group is preferably a group having an aromatic hydrocarbon group or a group having an alicyclic group, which may have a substituent, more preferably a group having 2 to 4 aromatic hydrocarbon groups, which may have a substituent, and still more preferably a group having 3 aromatic hydrocarbon groups, which may have a substituent. The substituent is preferably an alkyl group, an alkoxy group, an alkyl ester group, or an acetyl group, and more preferably a methyl group, a tert-butyl group, a methoxy group, or a methyl ester group. The mesogen group is preferably a group represented by Formula (M1).

*-(Cy¹¹-L¹¹)ₙₘ-Cy¹²-* (M1)

In Formula (M1), * represents a bonding position.

nm represents an integer of 1 or more, and is preferably an integer of 1 to 10, more preferably an integer of 1 to 3, and still more preferably 2.

Cy¹¹ and Cy¹² each independently represent a divalent ring group which may have a substituent. The definitions and suitable aspects of the group represented by Cy¹¹ and Cy¹² are the same those for Cy¹ and Cy² in Formula (A1) described above.

L¹¹ represents a single bond or a divalent linking group. The definition and suitable aspects of the group represented by L¹¹ are the same as those for L¹ and L² in Formula (A1) described above.

The repeating unit having a mesogen group is preferably a repeating unit represented by Formula (C1) or a repeating unit represented by Formula (C2).

The mesogen group in the repeating unit represented by Formula (C1) is vertically aligned with respect to the main surface, and the mesogen group in the repeating unit represented by Formula (C2) is horizontally aligned with respect to the main surface.

From the viewpoint of the formability of the specific region, it is preferable that the surfactant has the repeating unit represented by Formula (C1).

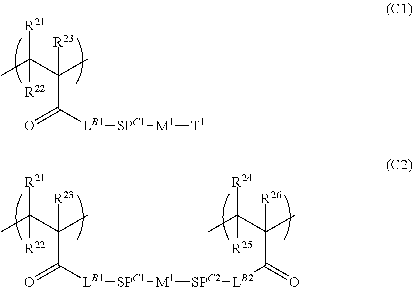

In Formulae (C1) and (C2), R²¹, R²², R²³, and L^{B1} are the same as those described in Formula (B1).

In Formula (C2), R²⁴ and R²⁵ each independently have the same definitions as R²¹ and R²² in Formula (B1), and suitable aspects thereof are also the same. R²⁶ has the same definition as R²³ in Formula (B1), and the suitable aspect is also the same. L^{B2} has the same definition as that for L^{B1} in Formula (B1), and suitable aspects thereof are also the same.

In Formulae (C1) and (C2), SP^{C1} and SP^{C2} each independently represent a spacer group. In Formulae (C1) and (C2), the definition and suitable aspect of the spacer group represented by SP^{C1} and SP^{C2} are the same as those of the group represented by SP¹ and SP² in Formula (A1).

In Formulae (C1) and (C2), M¹ represents a mesogen group. The details of the mesogen group are as described above.

In Formula (C2), T¹ represents a terminal group. The terminal group represents a hydrogen atom or a substituent.

Examples of the substituent include a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group having 1 to 10 carbon atoms (ROC(O)—: R represents an alkyl group), an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a trialkylsilyloxy group having 3 to 12 carbon atoms, a ureido group having 1 to 10 carbon atoms, and a (meth)acryloyloxy group-containing group. Examples of the (meth)acryloyloxy group-containing group include a group represented by -L^{A}-A (L^{A} represents a single bond or a divalent linking group. Examples of the divalent linking group include the same groups as those for L¹ as described above. A represents a (meth)acryloyloxy group).

In addition, examples of T¹ also include a boronic acid group (—B(OH)₂) and a boronic acid ester group (—B(R^{B1})₂).

R^{B1}'s each independently represent a hydrogen atom, an alkyl group which may have a substituent, an aryl group which may have a substituent, or a heteroaryl group which may have a substituent, and a hydrogen atom or an alkyl group which may have a substituent is preferable.

The number of carbon atoms in the alkyl group is preferably 1 to 10 and more preferably 1 to 5.

The number of carbon atoms in the aryl group is preferably 4 to 20 and more preferably 6 to 12. Examples of the aryl group include a phenyl group.

The number of carbon atoms in the heteroaryl group is preferably 3 to 10 and more preferably 3 to 5. Examples of the heteroatom of the heteroaryl group include an oxygen atom, a nitrogen atom, and a sulfur atom.

R^{B1}'s may be bonded to each other to form a ring. The number of ring members of the ring formed by bonding R^{B1}'s to each other is preferably 4 to 8 and more preferably 5 or 6.

The repeating unit having a mesogen group may be used alone or in combination of two or more kinds thereof.

A content of the repeating unit having a mesogen group is preferably 5% to 80% by mass, more preferably 10% to 70% by mass, and still more preferably 15% to 60% by mass with respect to all repeating units (100% by mass) constituting the main chain of the surfactant.

The surfactant having a mesogen group may have a repeating unit other than the above-described repeating units.

Examples of the other repeating units include a repeating unit having a polymerizable group and a repeating unit having an acid group.

The surfactant having a mesogen group may be used alone or in combination of two or more kinds thereof. In a case where the optically anisotropic layer having a specific region is formed using Method 2, a surfactant having no mesogen group and a surfactant having a mesogen group may be used in combination.

From the viewpoint of aligning properties of the optically anisotropic layer, it is also preferable to use, as the surfactant having a mesogen group, a surfactant having a vertically aligned mesogen group (for example, a surfactant having a repeating unit represented by Formula (C1)) and a surfactant having a horizontally aligned mesogen group (for example, a surfactant having a repeating unit represented by Formula (C2)) in combination.

### [Use]

The polarizing plate according to the embodiment of the present invention can be suitably applied to a display device.

The display device according to the embodiment of the present invention includes a display element and the polarizing plate according to the embodiment of the present invention.

Usually, the polarizing plate is provided on a viewing side of the display device. In this case, in the polarizing plate, the polarizer is disposed on the viewing side.

The display element is not particularly limited, and examples thereof include an organic electroluminescence display element (organic EL display element) and a liquid crystal display element.

The organic electroluminescence display element is a member in which a light emitting layer or a plurality of organic compound thin films including a light emitting layer are formed between a pair of electrodes of an anode and a cathode, and may have a hole injection layer, a hole transport layer, an electron injection layer, an electron transport layer, and/or a protective layer, and the like in which each of these layers may have other functions, in addition to the light emitting layer. Various materials can be used to form the respective layers.

### EXAMPLES

Hereinbelow, the present invention will be described in more detail with reference to Examples.

The material, the amount used, the proportion, the process contents, the process procedure, and the like shown in the following examples can be appropriately changed, within a range not departing from the gist of the present invention. Therefore, the scope of the present invention should not be construed as being limited to Examples shown below.

### Example 1

### [Production of Cellulose Acylate Film (Substrate)]

The following composition (cellulose acylate dope) was put into a mixing tank, stirred, and further heated at 90 °C for 10 minutes. Thereafter, the obtained composition was filtered through a filter paper having an average hole diameter of 34 μm and a sintered metal filter having an average hole diameter of 10 μm to prepare a dope. The concentration of solid contents of the dope was 23.5% by mass, the amount of the plasticizer added was a proportion to cellulose acylate, and the solvent of the dope was methylene chloride/methanol/butanol=81/18/1 (mass ratio).

Cellulose acylate dope

| | |
|---|---|
| Cellulose acylate (acetyl substitution | 100 parts by mass |
| degree: 2.86, viscosity average degree of | |
| polymerization: 310) | |
| Compound 1 (represented by Formula (S4)) | 8.0 parts by mass |
| Compound 2 (represented by Formula (S5)) | 2.0 parts by mass |
| Compound 3 (represented by Formula (S6)) | 0.2 parts by mass |
| Compound 4 (represented by Formula (S7)) | 0.02 parts by mass |
| Silica particle dispersion (AEROSIL R972, | 0.1 parts by mass |
| manufactured by Nippon Aerosil Co., Ltd) | |
| Solvent (methylene chloride/ | |
| methanol/butanol) | |

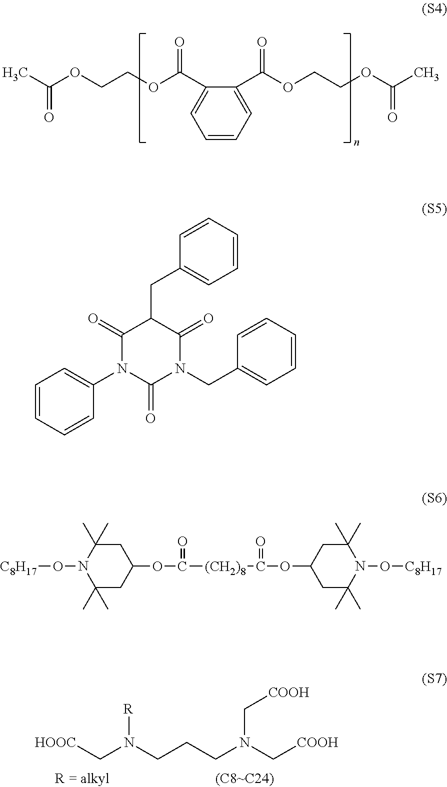

The produced dope above was cast using a band casting machine. The dope was cast from a die such that the dope was in contact with a metal support, and then the obtained web (film) was stripped. The drum was made of SUS.

The web (film) obtained by casting was peeled off from the drum and dried in a tentering machine for 20 minutes using a tentering machine such that both ends of the web were clipped with clips and transported at 30 °C to 40 °C during film transport. Subsequently, the web was post-dried by zone heating while being rolled and transported. The obtained web was knurled and then wound up.

In the obtained cellulose acylate film, a film thickness was 40 μm, an in-plane retardation at a wavelength of 550 nm was 1 nm, and a thickness direction retardation at a wavelength of 550 nm was 26 nm.

### <Alkali Saponification Treatment>

After passing the obtained cellulose acylate film through a dielectric heating roll at a temperature of 60 °C to raise the film surface temperature to 40 °C, an alkaline solution having the formulation shown below was applied onto a band surface of the film using a bar coater at a coating amount of 14 ml/m², followed by heating to 110 °C, and transportation of the film under a steam type far-infrared heater manufactured by Noritake Company Limited for 10 seconds. Subsequently, pure water was applied at 3 ml/m² using the same bar coater. Then, after washing with water using a fountain coater and draining using an air knife were repeated three times, the film was transported to a drying zone at 70 °C for 10 seconds and dried to produce a cellulose acylate film which had been subjected to an alkali saponification treatment.

Alkaline solution

| | |
|---|---|
| Potassium hydroxide | 4.7 parts by mass |
| Water | 15.8 parts by mass |
| Isopropanol | 63.7 parts by mass |
| Surfactant: C₁₄H₂₉O(CH₂CH₂O)₂₀H | 1.0 part by mass |
| Propylene glycol | 14.8 parts by mass |

### [Formation of Alignment Film]

An alignment film coating liquid having the following formulation was continuously applied onto the surface of the cellulose acylate film which had been subjected to the alkali saponification treatment with a #14 wire bar. The film was dried with hot air at 60 °C for 60 seconds, and further dried with hot air at 100 °C for 120 seconds.

Alignment film coating liquid

| | |
|---|---|
| Polyvinyl alcohol shown below | 10 parts by mass |
| Water | 371 parts by mass |
| Methanol | 119 parts by mass |
| Glutaraldehyde (crosslinking agent) | 0.5 parts by mass |
| Citric acid ester (manufactured by Sankyo | 0.175 parts by mass |
| Chemical Co., Ltd.) | |

Polyvinyl alcohol: degree of polymerization of 300 (numerical value in each repeating unit represents a content (% by mass) with respect to all repeating units)

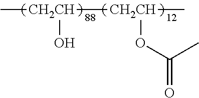

### [Formation of First Optically Anisotropic Layer]

The above produced alignment film was continuously subjected to a rubbing treatment. In this case, the longitudinal direction and the transport direction of the elongated film were parallel to each other, and an angle between the longitudinal direction (transport direction) of the film and the rotation axis of the rubbing roller was 76°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was −14°. That is, the position of the rotation axis of the rubbing roller is a position rotated by 76° counterclockwise with respect to the longitudinal direction of the film as a reference.

A composition (1a) for forming an optically anisotropic layer, containing a disk-like liquid crystal compound with the following formulation, was applied onto the rubbing-treated alignment film using a Geeser coating machine to form a composition layer. Next, the obtained composition layer was heated with hot air at 110 °C for 2 minutes for drying of the solvent and alignment aging of the disk-like liquid crystal compound to be homogeneously aligned. Subsequently, the obtained composition layer was irradiated with 320 nm LED-UV (50 mJ/cm²) from the air interface side at 60 °C to cause an isomerization reaction. Thereafter, UV irradiation (100 mJ/cm²) was performed at 70 °C to fix the alignment of the liquid crystal compound to form an optically anisotropic layer (1a).

A thickness of the optically anisotropic layer (1a) was 1.7 μm, and a retardation at 550 nm was 168 nm. In addition, a value obtained by dividing the in-plane retardation at a wavelength of 550 nm by the thickness of the first optically anisotropic layer was 0.099. In addition, in a case of viewing from the optically anisotropic layer (1a) side, assuming that the in-plane slow axis angle of the optically anisotropic layer (1a) was parallel to the rotation axis of the rubbing roller, and the width direction of the film was 0° (the counterclockwise direction was 90° and the clockwise direction was −90° in the longitudinal direction), the in-plane slow axis was −14°.

The optically anisotropic layer (1a) corresponds to the first optically anisotropic layer.

Composition (1a) for forming optically anisotropic layer

| | |
|---|---|
| Disk-like liquid crystal compound 1 | 100 parts by mass |
| shown below | |
| Alignment film interface alignment | 0.15 parts by mass |
| agent 1 given below | |
| Fluorine-containing compound A | 0.1 parts by mass |
| given below | |
| Fluorine-containing compound B | 0.05 parts by mass |
| given below | |
| Fluorine-containing compound C | 0.21 parts by mass |
| shown below | |
| Ethylene oxide-modified | 8.0 parts by mass |
| trimethylolpropane triacrylate | |
| (V#360, manufactured by Osaka | |
| Organic Chemical Industry Ltd.) | |
| Photopolymerization initiator | 6.0 parts by mass |
| (APi-307, manufactured by | |
| Shenzhen UV ChemTech Ltd.) | |
| Methyl ethyl ketone | 200 parts by mass |

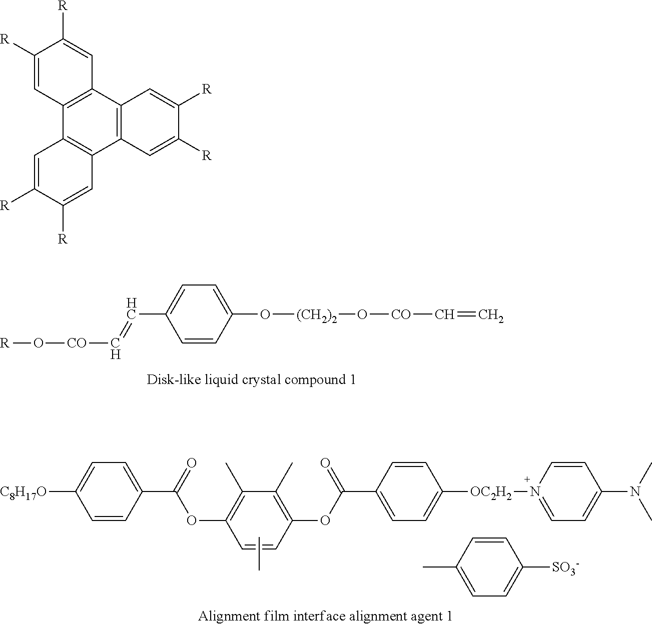

Fluorine-containing compound A (in the following formula, a and b represent the content (% by mass) of each repeating unit with respect to all the repeating units, a represents 90% by mass, and b represents 10% by mass. The weight-average molecular weight thereof was 15,000.)

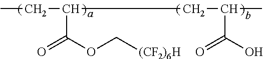

Fluorine-containing compound B (The numerical value in each repeating unit represents the content (% by mass) with respect to all the repeating units. The weight-average molecular weight thereof was 12,500.)

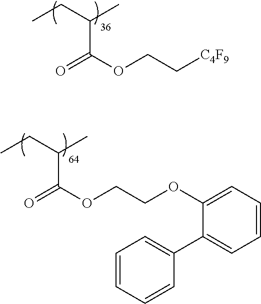

Fluorine-containing compound C (The numerical value in each repeating unit represents the content (% by mass) with respect to all the repeating units. The weight-average molecular weight thereof was 12,500.)

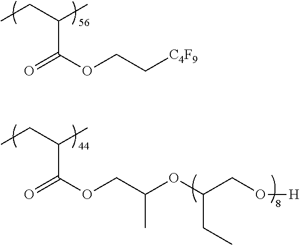

Photopolymerization initiator (APi-307, manufactured by Shenzhen UV ChemTech Ltd.)

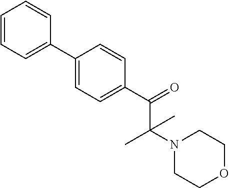 [SMILES: CC(C)(C(=O)c1ccc(-c2ccccc2)cc1)N1CCOCC1]

### [Formation of Second Optically Anisotropic Layer]

### <Formation of Optically Anisotropic Layer (B)>

A composition (1c) for forming an optically anisotropic layer containing a rod-like liquid crystal compound having the following composition was applied onto the above produced cellulose acylate film using a Geeser coating machine to form a composition layer. Thereafter, both ends of the film were held, a cooling plate (9 °C) was provided on the side of the surface on which the coating film of the film was formed such that the distance from the film reached 5 mm, a heater (75 °C) was provided on a side opposite to the surface on which the coating film of the film was formed such that the distance from the film reached 5 mm, and the film was dried for 2 minutes.

Next, the film was heated with hot air at 60 °C for 1 minute, and irradiated with ultraviolet rays at an irradiation amount of 100 mJ/cm² using a 365 nm UV-LED while purging with nitrogen so as to have an atmosphere having an oxygen concentration of 100 ppm or less. This was followed by annealing with hot air at 120 °C for 1 minute to form a precursor layer.

The obtained precursor layer was irradiated with UV light (ultra-high pressure mercury lamp; UL750, manufactured by HOYA Corporation) passing through a wire grid polarizer at room temperature at an irradiation amount of 7.9 mJ/cm² (wavelength: 313 nm) to form a composition layer having an alignment control ability on the surface thereof.

The formed composition layer had a film thickness of 0.6 μm. The in-plane retardation at a wavelength of 550 nm was 0 nm, and the retardation at a wavelength of 550 nm in the thickness direction was-80 nm. It was confirmed that an average tilt angle of a major axis direction of the rod-like liquid crystal compound with respect to the film surface was 90° and the rod-like liquid crystal compound was aligned perpendicular to the film surface.

The optically anisotropic layer (1c) corresponds to the optically anisotropic layer (B). Ltd.)

Composition (1c) for forming optically anisotropic layer

| | |
|---|---|
| Rod-like liquid crystal compound (A) given below | 100 parts by mass |
| Polymerizable monomer (A-400, manufactured | 4.0 parts by mass |
| by Shin-Nakamura Chemical | |
| Polymerization initiator S-1 (oxime type) given below | 5.0 parts by mass |
| Photoacid generator D-1 given below | 3.0 parts by mass |
| Polymer M-1 given below | 2.0 parts by mass |
| Vertical alignment agent S01 given below | 2.0 parts by mass |
| Photo-alignment polymer A-1 given below | 2.0 parts by mass |
| Methyl ethyl ketone | 42.3 parts by mass |
| Methyl isobutyl ketone | 627.5 parts by mass |

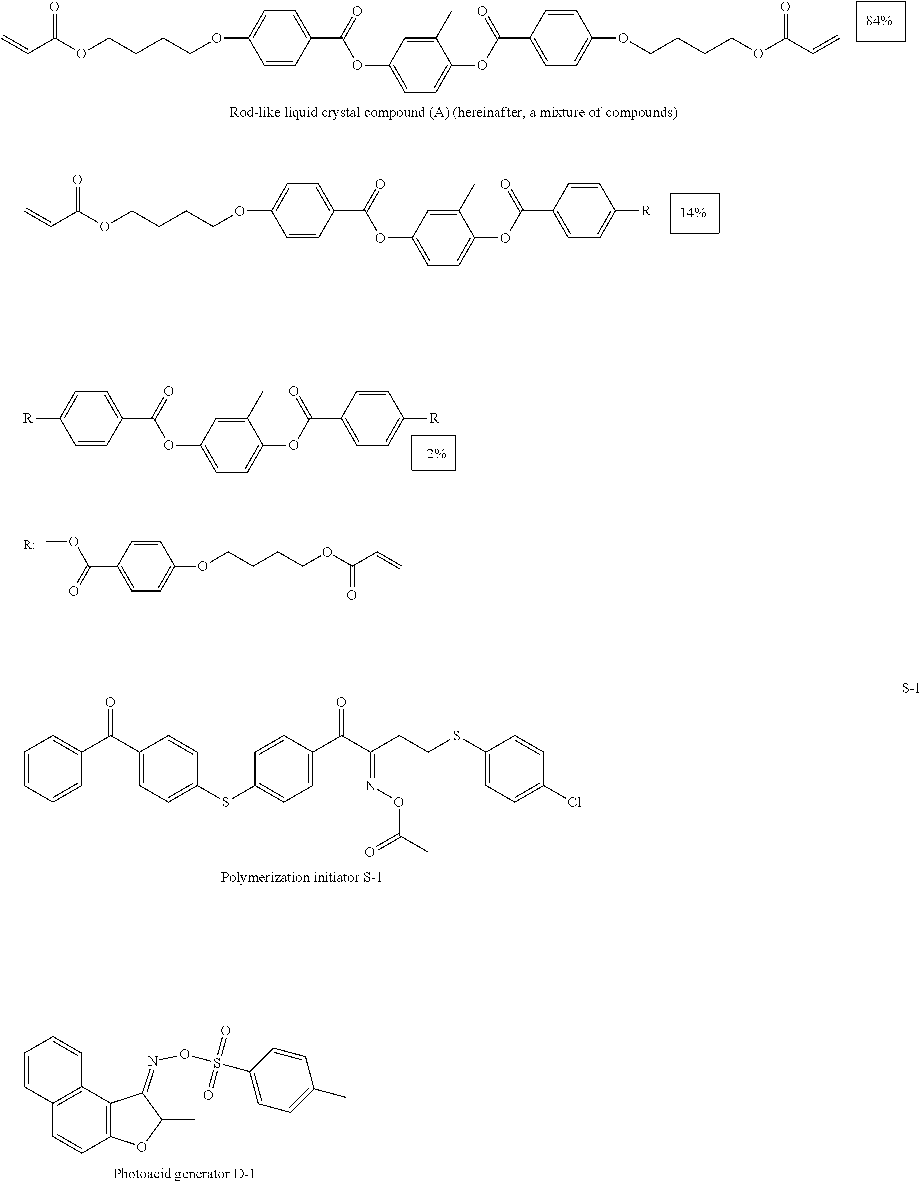

Polymer M-1 (The numerical value in each repeating unit represents the content (% by mass) with respect to all the repeating units. The weight-average molecular weight thereof was 58,000.)

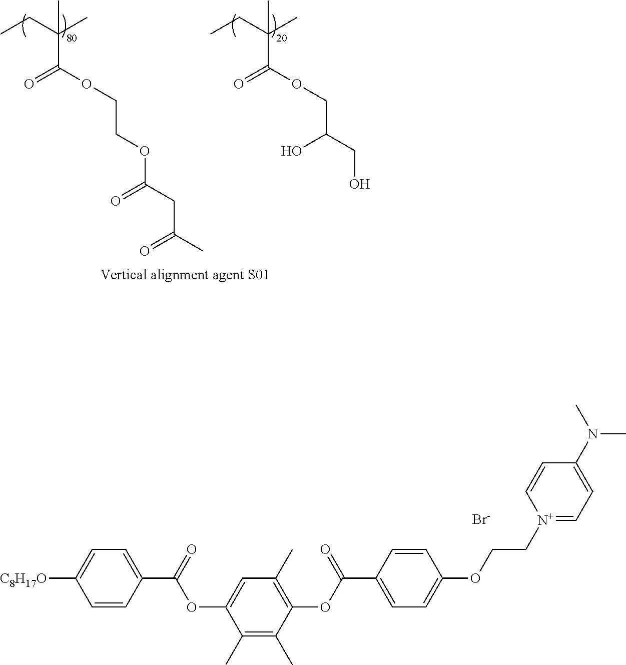

Photo-alignment polymer A-1 (in the following formula, a, b, and c represent the content (% by mass) of each repeating unit with respect to all repeating units, and a was 40% by mass, b was 25% by mass, and c was 35% by mass. The weight-average molecular weight thereof was 69,300.)

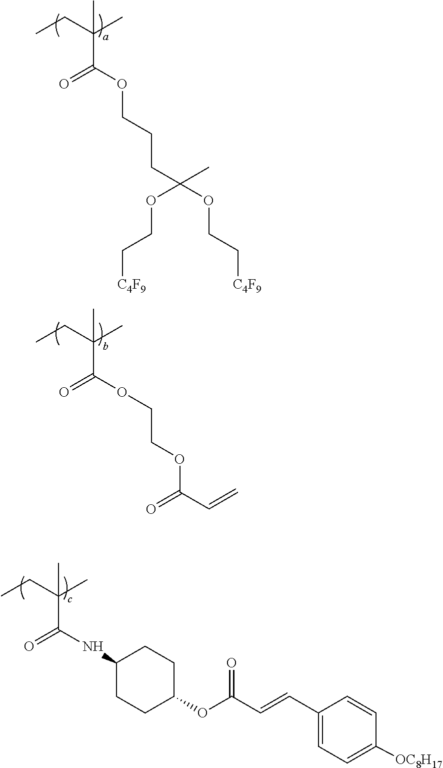

### <Formation of Optically Anisotropic Layer (A)>

Next, a composition (1b) for forming an optically anisotropic layer containing a rod-like liquid crystal compound having the following composition was applied onto the above produced optically anisotropic layer (1c) by using a Geeser coating machine, and heated with hot air at 60 °C for 60 seconds. Subsequently, the obtained composition layer was irradiated with UV (300 mJ/cm²) at 80 °C to fix the alignment of the liquid crystal compound to form an optically anisotropic layer (1b).

In the optically anisotropic layer (1b), a thickness was 1.5 μm, a product And of a birefringence index and the thickness at a wavelength of 550 nm was 164 nm, and a twisted angle of the liquid crystal compound was 81°. Assuming that the width direction of the film is defined as 0° (the longitudinal direction of the film is defined as) 90°, the alignment axial angle of the liquid crystal compound was 14° on the air side and 95° on the side in contact with the optically anisotropic layer (1c), in a case of being viewed from the optically anisotropic layer (1b) side.

The alignment axial angle of the liquid crystal compound contained in the optically anisotropic layer is expressed as negative in a case where it is clockwise (right-handed turning) and positive in a case where it is counterclockwise (left-handed turning) with the width direction of the substrate as a reference of 0°, upon observing the substrate from the surface side of the optically anisotropic layer.

In addition, the twisted angle of the liquid crystal compound is expressed as negative in a case where the alignment axis direction of the liquid crystal compound on the substrate side (back side) is clockwise (right-handed turning) and positive in a case where it is counterclockwise (left-handed turning) with reference to the alignment axis direction of the liquid crystal compound on the surface side (front side), upon observing the substrate from the surface side of the optically anisotropic layer.

The optically anisotropic layer (1b) corresponds to the optically anisotropic layer (A).

Composition (1b) for forming optically anisotropic layer

| | |
|---|---|
| Rod-like liquid crystal compound (A) given above | 70 parts by mass |
| Rod-like liquid crystal compound (B) given below | 30 parts by mass |
| Ethylene oxide-modified trimethylolpropane triacrylate | 4 parts by mass |
| (V# 360, manufactured by Osaka Organic | |
| Chemical Industry Ltd.) | |
| Photopolymerization initiator (Irgacure 819, | 3 parts by mass |
| manufactured by BASF SE) | |
| Left-handed twisting chiral agent (L1) shown below | 0.50 parts by mass |
| Fluorine-containing compound D shown below | 0.20 parts by mass |
| Methyl isobutyl ketone | 126 parts by mass |
| Ethyl propionate | 126 parts by mass |

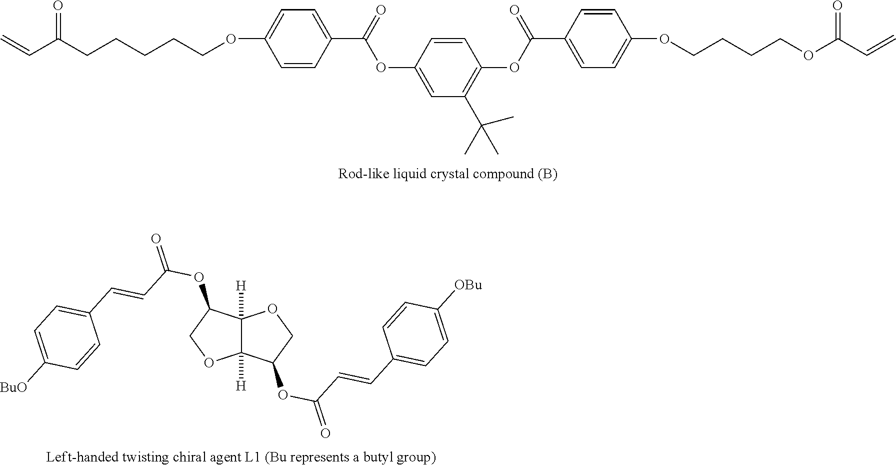

Fluorine-containing compound D (the content of the repeating unit on the left side was 76% by mass and the content of the repeating unit on the right side was 24% by mass; a weight-average molecular weight was 27,500)

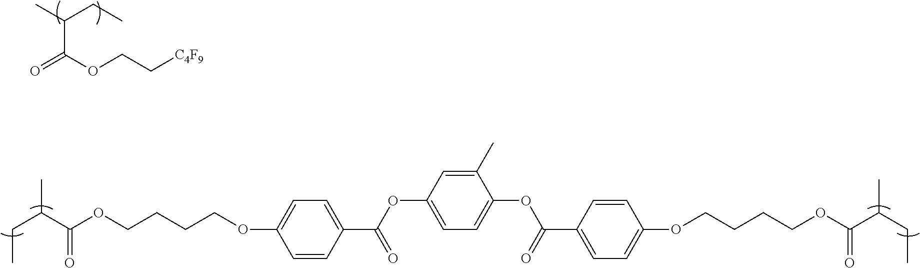

According to the above-described procedure, an optically anisotropic layer (1b-1c) in which the optically anisotropic layer (1c) and the optically anisotropic layer (1b) were directly laminated on the elongated cellulose acylate film was produced. It was confirmed that the photo-alignment polymer was present in a case where the surface of the optically anisotropic layer (1c) on the side in contact with the optically anisotropic layer (1b) was examined.

The above-described optically anisotropic layer (1b-1c) corresponds to the optically anisotropic layer (AB).

### [Production of Polarizing Plate]

### <Production of Linear Polarizer>

A surface of a support of a cellulose triacetate film TJ25 (manufactured by Fujifilm Corporation; thickness: 25 μm) was subjected to an alkali saponification treatment. Specifically, the support was immersed in a 1.5 N sodium hydroxide aqueous solution at 55 °C for 2 minutes, washed in a water washing bath at room temperature, and further neutralized with 0.1 N sulfuric acid at 30 °C. After the neutralization, the support was washed in a water washing bath at room temperature and further dried with hot air at 100 °C to obtain a polarizer protective film.

A roll-like polyvinyl alcohol (PVA) film having a thickness of 60 μm was continuously stretched in an iodine aqueous solution in a longitudinal direction, and dried to obtain a linear polarizer having a thickness of 13 μm. The luminosity corrected single transmittance of the polarizer was 43%. In this case, an absorption axis direction of the polarizer coincided with the longitudinal direction.

The above-described polarizer protective film was bonded to one surface of the above-described polarizer using the following PVA adhesive to produce a linear polarizer.

### <Preparation of PVA Adhesive>

100 parts by mass of a polyvinyl alcohol-based resin having an acetoacetyl group (average degree of polymerization: 1200, degree of saponification: 98.5 mol %, degree of acetoacetylation: 5 mol %) and 20 parts by mass of methylol melamine were dissolved in pure water under a temperature condition of 30 °C to prepare a PVA adhesive as an aqueous solution adjusted to a concentration of solid contents of 3.7% by mass.

### <Production of Optical Film>

A surface side of the optically anisotropic layer (1a) formed on the produced long cellulose acylate film was subjected to a corona discharge treatment. Conditions of the corona discharge treatment were set to an output intensity of 2.5 kW, a line speed of 18 m/min, an electrode length of 1.4 m, and a gap-to-gap distance of 2 mm. The following ultraviolet curable adhesive (1d) was applied onto the corona-treated surface to have a film thickness of 1.5 μm.

A surface side of the optically anisotropic layer (1b) of the optically anisotropic layer (1b-1c) formed on the produced long cellulose acylate film was also subjected to a corona discharge treatment. Conditions of the corona discharge treatment were set to an output intensity of 5.0 kW, a line speed of 18 m/min, an electrode length of 1.4 m, and a gap-to-gap distance of 2 mm. The following adhesive (1d) was applied onto the treated surface subjected to the corona treatment to have a film thickness of 1.0 μm.

The adhesive (1d) applied onto the optically anisotropic layer (1a) and the adhesive (1d) applied onto the optically anisotropic layer (1b) were bonded to each other, heated to 50 °C using an IR heater, irradiated with UV light from both surface sides of the cellulose acylate film of the bonded laminate to cure the adhesive (1d), and then thermally dried at 70 °C for 3 minutes. A film thickness of the cured adhesive layer (1d) was 2.0 μm from SEM observation of a cross section cut.

In this manner, an optical film (1a-1b-1c) having a layer configuration of the optically anisotropic layer (1a)—the adhesive layer (1d)—the optically anisotropic layer (1b-1c) was obtained. In the optical film (1a-1b-1c), in the above-described optically anisotropic layer (1b-1c), the optically anisotropic layer (1b) was disposed on the adhesive layer (1d) side.

An in-plane retardation of the above-described optical film (1a-1b-1c) at a wavelength of 550 nm was 141 nm.

Adhesive (1d)

| | |
|---|---|
| Acryloylmorpholine (manufactured by | 15 parts by mass |
| Kohjin Co., Ltd.) | |
| N-hydroxyacrylamide (manufactured | 15 parts by mass |
| by Kohjin Co., Ltd.) | |
| Tripropylene glycol diacrylate | |
| (ARONIX M-220, manufactured by | 10 parts by mass |
| Toagosei Co., Ltd.) | |
| OGSOL EA-F5710 (manufactured by | 60 parts by mass |
| Osaka Gas Chemicals Co., Ltd.) | |
| Photopolymerization initiator | 1.5 parts by mass |
| (KAYACURE DETX-S, manufactured | |
| by Nippon Kayaku Co., Ltd.) | |

### <Production of Polarizing Plate>

The exposed surface of the optical film (1a-1b-1c) in which the surface of the optically anisotropic layer (1a) in contact with the cellulose acylate film was exposed was subjected to a corona discharge treatment. Conditions of the corona discharge treatment were set to an output intensity of 2.5 kW, a line speed of 18 m/min, an electrode length of 1.4 m, and a gap-to-gap distance of 2 mm. The following ultraviolet curable adhesive (2d) was applied onto the corona-treated surface to have a film thickness of 1.5 μm.

The surface of the long linear polarizer produced above on the opposite side of the polarizer protective film and the surface of the optical film (1a-1b-1c) on which the adhesive (2d) was applied were bonded to each other to obtain a laminate of linear polarizer-adhesive layer (2d)—optically anisotropic layer (1a)—adhesive layer (1d)—optically anisotropic layer (1b-1c).

Subsequently, the cellulose acylate film on the optically anisotropic layer (1b-1c) side was peeled off to expose the surface of the optically anisotropic layer (1b-1c) that had been in contact with the cellulose acylate film. In this manner, a polarizing plate (P1) including the optical film (1a-1b-1c) and the linear polarizer was produced. In the polarizing plate (P1), the polarizer protective film, the polarizer, the adhesive layer (2d), the optically anisotropic layer (1a), the adhesive layer (1d), the optically anisotropic layer (1b), and the optically anisotropic layer (1c) were laminated in this order, and the polarizing plate (P1) corresponded to the polarizing plate according to Aspect 1.

The angle formed by the absorption axis of the polarizer and the in-plane slow axis of the optically anisotropic layer (1a) was −76°. In addition, the alignment axial angle of the liquid crystal compound on the optically anisotropic layer (1a) side of the optically anisotropic layer (1b) was −14° with the width direction as a reference of 0°, which coincided with the in-plane slow axis direction of the optically anisotropic layer (1a).

Adhesive (2d)

| | |
|---|---|
| Acryloylmorpholine (manufactured | 20 parts by mass |
| by Kohjin Co., Ltd.) | |
| N-hydroxyacrylamide (manufactured | 20 parts by mass |
| by Kohjin Co., Ltd.) | |
| Tripropylene glycol diacrylate | 20 parts by mass |
| (ARONIX M-220, manufactured | |
| by Toagosei Co., Ltd.) | |
| OGSOL EA-F5710 (manufactured by | 40 parts by mass |
| Osaka Gas Chemicals Co., Ltd.) | |
| Photopolymerization initiator | 1.5 parts by mass |
| (KAYACURE DETX-S, manufactured | |
| by Nippon Kayaku Co., Ltd.) | |

### Example 2

A polarizing plate P2 was produced by the same method as in Example 1, except that the procedures of [Formation of first optically anisotropic layer] and <Formation of optically anisotropic layer (A)> described above were changed as follows, and the procedure of <Production of optical film> described above was changed as follows.

### [Formation of First Optically Anisotropic Layer]

A composition (2a) for forming an optically anisotropic layer, containing a disk-like liquid crystal compound with the following formulation, was applied onto the rubbing-treated alignment film using a Geeser coating machine to form a composition layer. Next, the obtained composition layer was heated with hot air at 110 °C for 2 minutes for drying of the solvent and alignment aging of the disk-like liquid crystal compound to be homogeneously aligned. Subsequently, the obtained composition layer was irradiated with UV (100 mJ/cm²) at 70 °C to fix the alignment of the liquid crystal compound to form an optically anisotropic layer (2a).

A thickness of the optically anisotropic layer (2a) was 1.5 μm, and a retardation at 550 nm was 168 nm. In addition, a value obtained by dividing the in-plane retardation at a wavelength of 550 nm by the thickness of the first optically anisotropic layer was 0.110. In addition, in a case of viewing from the optically anisotropic layer (2a) side, assuming that the in-plane slow axis angle of the optically anisotropic layer (2a) was parallel to the rotation axis of the rubbing roller, and the width direction of the film was 0° (the counterclockwise direction was 90° and the clockwise direction was −90° in the longitudinal direction), the in-plane slow axis was −14°.

The optically anisotropic layer (2a) corresponds to the first optically anisotropic layer.

Composition (2a) for forming optically anisotropic layer

| | |
|---|---|
| Disk-like liquid crystal compound 2 given below | 80 parts by mass |
| Disk-like liquid crystal compound 3 given below | 20 parts by mass |
| Alignment film interface alignment | 0.12 parts by mass |
| agent 1 shown above | |
| Fluorine-containing compound A shown above | 0.1 parts by mass |
| Fluorine-containing compound B given above | 0.05 parts by mass |
| Fluorine-containing compound C shown above | 0.21 parts by mass |
| Ethylene oxide-modified | 6.0 parts by mass |
| trimethylolpropane triacrylate | |
| (V#360, manufactured by Osaka | |
| Organic Chemical Industry Ltd.) | |
| Photopolymerization initiator (APi-307, | 6.0 parts by mass |
| manufactured by Shenzhen UV ChemTech | |
| Methyl ethyl ketone | 200 parts by mass |

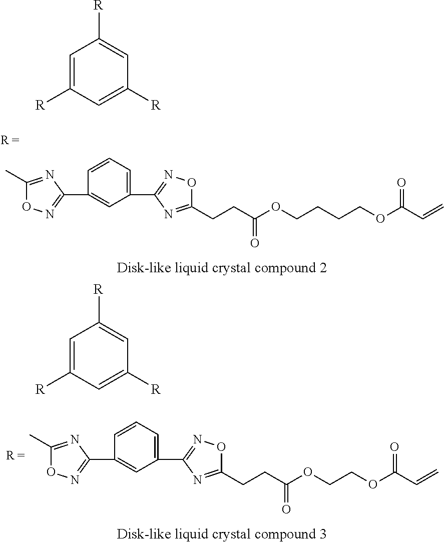

### <Formation of Optically Anisotropic Layer (A)>

A composition (2b) for forming an optically anisotropic layer containing a rod-like liquid crystal compound having the following composition was applied onto the above produced optically anisotropic layer (1c) by using a Geeser coating machine, and heated with hot air at 60 °C for 60 seconds. The obtained composition layer was irradiated with 320 nm LED-UV from the air interface side at 60 °C (40 mJ/cm²) to induce an isomerization reaction. Thereafter, the obtained composition layer was irradiated with UV (300 mJ/cm²) at 80 °C to fix the alignment of the liquid crystal compound to form an optically anisotropic layer (2b).

In the optically anisotropic layer (2b), a thickness was 1.6 μm, And at a wavelength of 550 nm was 164 nm, and a twisted angle of the liquid crystal compound was 81°. Assuming that a width direction of the film is defined as 0° (a longitudinal direction of the film is defined as) 90°, the alignment axial angle of the liquid crystal compound was 14° on the air side and 95° on the side in contact with the optically anisotropic layer (1c), in a case of being viewed from the optically anisotropic layer (2b) side.

The alignment axial angle of the liquid crystal compound contained in the optically anisotropic layer is expressed as negative in a case where it is clockwise (right-handed turning) and positive in a case where it is counterclockwise (left-handed turning) with the width direction of the substrate as a reference of 0°, upon observing the substrate from the surface side of the optically anisotropic layer.

In addition, the twisted angle of the liquid crystal compound is expressed as negative in a case where the alignment axis direction of the liquid crystal compound on the substrate side (back side) is clockwise (right-handed turning) and positive in a case where it is counterclockwise (left-handed turning) with reference to the alignment axis direction of the liquid crystal compound on the surface side (front side), upon observing the substrate from the surface side of the optically anisotropic layer.

Composition (2b) for forming optically anisotropic layer

| | |
|---|---|
| Rod-like liquid crystal compound | 60 parts by mass |
| (A) given above | |
| Rod-like liquid crystal compound | 40 parts by mass |
| (C) given below | |
| Ethylene oxide-modified | 5 parts by mass |
| trimethylolpropane triacrylate | |
| (V#360, manufactured by | |
| Osaka Organic Chemical Industry Ltd.) | |
| Photopolymerization initiator (Irgacure 819, | 3 parts by mass |
| manufactured by BASF SE) | |
| Left-handed twisting chiral agent (L1) given above | 0.70 parts by mass |
| Fluorine-containing compound D given above | 0.18 parts by mass |
| Methyl isobutyl ketone | 126 parts by mass |
| Ethyl propionate | 126 parts by mass |

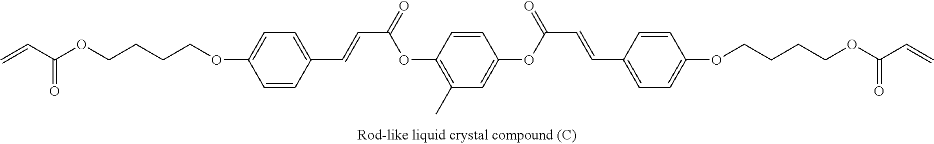 [SMILES: C=CC(=O)OCCCCOc1ccc(/C=C/C(=O)Oc2ccc(OC(=O)/C=C/c3ccc(OCCCCOC(=O)C=C)cc3)c(C)c2)cc1]

### <Production of Optical Film>

A surface side of the optically anisotropic layer (2a) formed on the produced long cellulose acylate film was subjected to a corona discharge treatment. Conditions of the corona discharge treatment were set to an output intensity of 2.5 kW, a line speed of 18 m/min, an electrode length of 1.4 m, and a gap-to-gap distance of 2 mm. The adhesive (1d) was applied onto the surface subjected to the corona treatment such that a film thickness was 1.5 μm.

A surface side of the optically anisotropic layer (2b) of the optically anisotropic layer (1c-2b) formed on the produced long cellulose acylate film was also subjected to a corona discharge treatment. Conditions of the corona discharge treatment were set to an output intensity of 5.0 kW, a line speed of 18 m/min, an electrode length of 1.4 m, and a gap-to-gap distance of 2 mm. The adhesive (1d) was applied onto the surface subjected to the corona treatment such that a film thickness was 1.0 μm.

The adhesive (1d) applied onto the optically anisotropic layer (2a) and the adhesive (1d) applied onto the optically anisotropic layer (2b) were bonded to each other, heated to 50 °C using an IR heater, irradiated with UV light from both surface sides of the cellulose acylate film of the bonded laminate to cure the adhesive (1d), and then thermally dried at 70 °C for 3 minutes. A film thickness of the cured adhesive layer (1d) was 2.0 μm from SEM observation of a cross section cut.

In this manner, an optical film (2a-2b-1c) having a layer configuration of the optically anisotropic layer (2a)—the adhesive layer (1d)—the optically anisotropic layer (2b-1c) was obtained. In the optical film (2a-2b-1c), the optically anisotropic layer (2b) was disposed on the adhesive layer (1d) side in the optically anisotropic layer (2b-1c).

An in-plane retardation of the optical film (2a-2b-1c) at a wavelength of 550 nm was 141 nm.

### Example 3

A polarizing plate P3 was produced by the same method as in Example 2, except that the procedure of <Formation of optically anisotropic layer (A)> described above was changed as follows.

### [Formation of Optically Anisotropic Layer (A)]

Next, a composition (3b) for forming an optically anisotropic layer containing a rod-like liquid crystal compound having the following composition was applied onto the above produced optically anisotropic layer (1c) by using a Geeser coating machine, and heated with hot air at 60 °C for 60 seconds. Subsequently, the obtained composition layer was irradiated with UV (300 mJ/cm²) at 70 °C to fix the alignment of the liquid crystal compound to form an optically anisotropic layer (3b).

In the optically anisotropic layer (3b), a thickness was 1.6 μm, And at a wavelength of 550 nm was 164 nm, and a twisted angle of the liquid crystal compound was 81°. Assuming that a width direction of the film is defined as 0° (a longitudinal direction of the film is defined as) 90°, the alignment axial angle of the liquid crystal compound was 14° on the air side and 95° on the side in contact with the optically anisotropic layer (1c), in a case of being viewed from the optically anisotropic layer (3b) side.

The alignment axial angle of the liquid crystal compound contained in the optically anisotropic layer is expressed as negative in a case where it is clockwise (right-handed turning) and positive in a case where it is counterclockwise (left-handed turning) with the width direction of the substrate as a reference of 0°, upon observing the substrate from the surface side of the optically anisotropic layer.

In addition, the twisted angle of the liquid crystal compound is expressed as negative in a case where the alignment axis direction of the liquid crystal compound on the substrate side (back side) is clockwise (right-handed turning) and positive in a case where it is counterclockwise (left-handed turning) with reference to the alignment axis direction of the liquid crystal compound on the surface side (front side), upon observing the substrate from the surface side of the optically anisotropic layer.

Composition (3b) for forming optically anisotropic layer

| | |
|---|---|
| Rod-like liquid crystal compound | 70 parts by mass |
| (A) given above | |
| Rod-like liquid crystal compound | 30 parts by mass |
| (B) given above | |
| Ethylene oxide-modified | 5 parts by mass |
| trimethylolpropane triacrylate | |
| (V#360, manufactured by Osaka | |
| Organic Chemical Industry Ltd.) | |
| Photopolymerization initiator (Irgacure | 3 parts by mass |
| 819, manufactured by BASF SE) | |
| Left-handed twisting chiral agent (L1) given above | 0.60 parts by mass |
| Fluorine-containing compound D given above | 0.18 parts by mass |
| Fluorine-containing compound E given below | 0.02 parts by mass |
| Methyl isobutyl ketone | 126 parts by mass |
| Ethyl propionate | 126 parts by mass |

Fluorine-containing compound E (the content of the repeating unit on the left side was 50% by mass and the content of the repeating unit on the right side was 50% by mass; a weight-average molecular weight was 24,700)

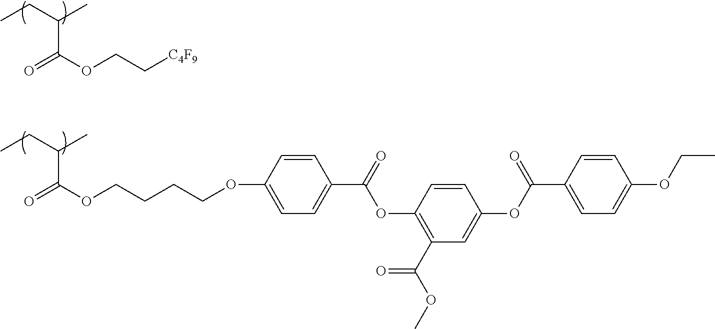

### Example 4

A polarizing plate P4 was produced in the same manner as in Example 1, except that, in <Production of optical film> described above, the optically anisotropic layer (1b) was changed to the optically anisotropic layer (2b).

### Example 5

A polarizing plate P5 was produced by the same method as in Example 1, except that the procedure of [Formation of first optically anisotropic layer] described above was changed as follows, and the procedure of <Production of optical film> and <Production of polarizing plate> described above was changed as follows.

### [Formation of First Optically Anisotropic Layer]

A composition (2a) for forming an optically anisotropic layer, containing a disk-like liquid crystal compound with the above-described formulation, was applied onto the rubbing-treated alignment film using a Geeser coating machine to form a composition layer. Next, the obtained composition layer was heated with hot air at 110 °C for 2 minutes for drying of the solvent and alignment aging of the disk-like liquid crystal compound to be homogeneously aligned. The obtained composition layer was irradiated with 320 nm LED-UV from the air interface side at 60 °C (50 mJ/cm²) to induce an isomerization reaction. Subsequently, the obtained composition layer was irradiated with UV (100 mJ/cm²) at 70 °C to fix the alignment of the liquid crystal compound to form an optically anisotropic layer (3a).

The optically anisotropic layer (3a) had a thickness of 1.5 μm and a retardation of 168 nm at 550 nm. In addition, a value obtained by dividing the in-plane retardation at a wavelength of 550 nm by the thickness of the first optically anisotropic layer was 0.110. In addition, in a case of viewing from the optically anisotropic layer (3a) side, assuming that the in-plane slow axis angle of the optically anisotropic layer (3a) was parallel to the rotation axis of the rubbing roller, and the width direction of the film was 0° (the counterclockwise direction was 90° and the clockwise direction was −90° in the longitudinal direction), the in-plane slow axis was +14°.

The optically anisotropic layer (3a) corresponds to the first optically anisotropic layer.

### <Production of Optical Film and Production of Polarizing Plate>

A surface side of the optically anisotropic layer (3a) formed on the produced long cellulose acylate film was subjected to a corona discharge treatment. Conditions of the corona discharge treatment were set to an output intensity of 2.5 kW, a line speed of 18 m/min, an electrode length of 1.4 m, and a gap-to-gap distance of 2 mm. The adhesive (2d) was applied onto the corona-treated surface to have a film thickness of 1.5 μm.

The surface of the long linear polarizer produced above on the opposite side of the polarizer protective film and the surface of the optically anisotropic layer (3a) on which the adhesive (2d) was applied were bonded to each other to obtain a laminate of linear polarizer-adhesive layer (2d)—optically anisotropic layer (3a).

Subsequently, a surface side of the optically anisotropic layer (1b-1c) formed on the produced long cellulose acylate film on the 1b side was subjected to a corona discharge treatment. Conditions of the corona discharge treatment were set to an output intensity of 2.8 kW, a line speed of 18 m/min, an electrode length of 1.4 m, and a gap-to-gap distance of 2 mm. The adhesive (1d) was applied onto the surface subjected to the corona treatment such that a film thickness was 1.5 μm.

The cellulose acylate film on the 3a side of the laminate of linear polarizer-adhesive layer (2d)—optically anisotropic layer (3a) was peeled off, and the surface that had been in contact with the cellulose acylate film was subjected to a corona discharge treatment. Conditions of the corona discharge treatment were set to an output intensity of 2.0 kW, a line speed of 18 m/min, an electrode length of 1.4 m, and a gap-to-gap distance of 2 mm.

The surface of the laminate of linear polarizer-adhesive layer (2d)—optically anisotropic layer (3a) that had been in contact with the cellulose acylate film subjected to the corona discharge treatment and the adhesive (1d) applied onto the 1b side of the optically anisotropic layer (1b-1c) formed on the cellulose acylate film were bonded to each other. In this manner, a polarizing plate P5 including the optical film (3a-1b-1c) and a linear polarizer was produced. In the polarizing plate P5, the polarizer protective film, the polarizer, the adhesive layer (2d), the optically anisotropic layer (3a), the adhesive layer (1d), the optically anisotropic layer (1b), and the optically anisotropic layer (1c) were laminated in this order, and the polarizing plate P5 corresponded to the polarizing plate according to Aspect 1.

The angle formed by the absorption axis of the polarizer and the in-plane slow axis of the optically anisotropic layer (3a) was −76°. In addition, the alignment axial angle of the liquid crystal compound on the optically anisotropic layer (3a) side of the optically anisotropic layer (1b) was −14° with the width direction as a reference of 0°, which coincided with the in-plane slow axis direction of the optically anisotropic layer (3a).

### Example 6

A polarizing plate P6 was produced by the same method as in Example 1, except that the procedure of [Formation of first optically anisotropic layer] described above was changed as follows.

### [Formation of First Optically Anisotropic Layer]

A composition (4a) for forming an optically anisotropic layer, containing a disk-like liquid crystal compound with the following formulation, was applied onto the rubbing-treated alignment film using a Geeser coating machine to form a composition layer. Next, the obtained composition layer was heated with hot air at 100 °C for 2 minutes for drying of the solvent and alignment aging of the disk-like liquid crystal compound to be homogeneously aligned. Subsequently, the obtained composition layer was irradiated with 320 nm LED-UV (30 mJ/cm²) from the air interface side at 60 °C to cause an isomerization reaction. Thereafter, UV irradiation (100 mJ/cm²) was performed at 70 °C to fix the alignment of the liquid crystal compound to form an optically anisotropic layer (4a).

The optically anisotropic layer (4a) had a thickness of 1.5 μm and a retardation of 168 nm at 550 nm. In addition, a value obtained by dividing the in-plane retardation at a wavelength of 550 nm by the thickness of the first optically anisotropic layer was 0.113. In a case of viewing from the optically anisotropic layer (4a) side, assuming that the in-plane slow axis angle of the optically anisotropic layer (4a) was parallel to the rotation axis of the rubbing roller, and the width direction of the film was 0° (the counterclockwise direction was 90° and the clockwise direction was −90° in the longitudinal direction), the in-plane slow axis was −14°.

The optically anisotropic layer (4a) corresponds to the first optically anisotropic layer.

Composition (4a) for forming optically anisotropic layer

| | |
|---|---|
| Disk-like liquid crystal compound 1 | 20 parts by mass |
| given above | |
| Disk-like liquid crystal compound 2 | 60 parts by mass |
| given above | |
| Disk-like liquid crystal compound 3 | 20 parts by mass |
| given above | |
| Alignment film interface alignment | 0.15 parts by mass |
| agent 1 shown above | |
| Fluorine-containing compound A | 0.1 parts by mass |
| shown above | |
| Fluorine-containing compound B | 0.05 parts by mass |
| given above | |
| Fluorine-containing compound C | 0.21 parts by mass |
| shown above | |
| Ethylene oxide-modified | 4.0 parts by mass |
| trimethylolpropane triacrylate | |
| (V#360, manufactured by Osaka | |
| Organic Chemical Industry Ltd.) | |
| Photopolymerization initiator | 6.0 parts by mass |
| (APi-307, manufactured by | |
| Shenzhen UV ChemTech Ltd.) | |
| Methyl ethyl ketone | 200 parts by mass |

### Example 7

A polarizing plate P7 was produced by the same method as in Example 1, except that the procedure of [Formation of first optically anisotropic layer] described above was changed as follows.

### [Formation of First Optically Anisotropic Layer]

A composition (5a) for forming an optically anisotropic layer, containing a disk-like liquid crystal compound with the following formulation, was applied onto the rubbing-treated alignment film using a Geeser coating machine to form a composition layer. Next, the obtained composition layer was heated with hot air at 90 °C for 2 minutes for drying of the solvent and alignment aging of the disk-like liquid crystal compound to be homogeneously aligned. Subsequently, the obtained composition layer was irradiated with 320 nm LED-UV (70 mJ/cm²) from the air interface side at 60 °C to cause an isomerization reaction. Thereafter, UV irradiation (100 mJ/cm²) was performed at 60 °C to fix the alignment of the liquid crystal compound to form an optically anisotropic layer (5a).

A thickness of the optically anisotropic layer (5a) was 1.5 μm, and a retardation at 550 nm was 168 nm. In addition, a value obtained by dividing the in-plane retardation at a wavelength of 550 nm by the thickness of the first optically anisotropic layer was 0.109. In a case of viewing from the optically anisotropic layer (5a) side, assuming that the in-plane slow axis angle of the optically anisotropic layer (5a) was parallel to the rotation axis of the rubbing roller, and the width direction of the film was 0° (the counterclockwise direction was 90° and the clockwise direction was −90° in the longitudinal direction), the in-plane slow axis was −14°.

The optically anisotropic layer (5a) corresponds to the first optically anisotropic layer.

Composition (5a) for forming optically anisotropic layer

| | |
|---|---|
| Disk-like liquid crystal compound 1 given above | 40 parts by mass |
| Disk-like liquid crystal compound 2 given above | 40 parts by mass |
| Disk-like liquid crystal compound 3 given above | 20 parts by mass |
| Alignment film interface alignment | 0.15 parts by mass |
| agent 1 shown above | |
| Fluorine-containing compound A shown above | 0.1 parts by mass |
| Fluorine-containing compound B given above | 0.05 parts by mass |
| Fluorine-containing compound C shown above | 0.21 parts by mass |
| Ethylene oxide-modified | 3.0 parts by mass |
| trimethylolpropane triacrylate | |
| (V#360, manufactured by Osaka | |
| Organic Chemical Industry Ltd.) | |
| Photopolymerization initiator (APi-307, | 6.0 parts by mass |
| manufactured by Shenzhen UV ChemTech Ltd.) | |
| Methyl ethyl ketone | 200 parts by mass |

### Example 8

A polarizing plate P8 was produced by the same method as in Example 1, except that the procedure of [Formation of first optically anisotropic layer] described above was changed as follows.

### [Formation of First Optically Anisotropic Layer]

A composition (6a) for forming an optically anisotropic layer, containing a disk-like liquid crystal compound with the following formulation, was applied onto the rubbing-treated alignment film using a Geeser coating machine to form a composition layer. Next, the obtained composition layer was heated with hot air at 110 °C for 2 minutes for drying of the solvent and alignment aging of the disk-like liquid crystal compound to be homogeneously aligned. Subsequently, the obtained composition layer was irradiated with 320 nm LED-UV (70 mJ/cm²) from the air interface side at 60 °C to cause an isomerization reaction. Thereafter, UV irradiation (100 mJ/cm²) was performed at 70 °C to fix the alignment of the liquid crystal compound to form an optically anisotropic layer (6a).

A thickness of the optically anisotropic layer (6a) was 1.6 μm, and a retardation at 550 nm was 168 nm. In addition, a value obtained by dividing the in-plane retardation at a wavelength of 550 nm by the thickness of the first optically anisotropic layer was 0.106. In a case of viewing from the optically anisotropic layer (6a) side, assuming that the in-plane slow axis angle of the optically anisotropic layer (6a) was parallel to the rotation axis of the rubbing roller, and the width direction of the film was 0° (the counterclockwise direction was 90° and the clockwise direction was −90° in the longitudinal direction), the in-plane slow axis was −14°.

The optically anisotropic layer (6a) corresponds to the first optically anisotropic layer.

Composition (6a) for forming optically anisotropic layer

| | |
|---|---|
| Disk-like liquid crystal compound 1 | 80 parts by mass |
| given above | |
| Disk-like liquid crystal compound 2 | 20 parts by mass |
| given above | |
| Alignment film interface alignment | 0.15 parts by mass |
| agent 1 shown above | |
| Fluorine-containing compound A | 0.1 parts by mass |
| shown above | |
| Fluorine-containing compound B | 0.05 parts by mass |
| given above | |
| Fluorine-containing compound C | 0.21 parts by mass |
| shown above | |
| Ethylene oxide-modified | 5.0 parts by mass |
| trimethylolpropane triacrylate | |
| (V#360, manufactured by Osaka | |
| Organic Chemical Industry Ltd.) | |
| Photopolymerization initiator | 6.0 parts by mass |
| (APi-307, manufactured | |
| by Shenzhen UV ChemTech Ltd.) | |
| Methyl ethyl ketone | 200 parts by mass |

### Example 9

A polarizing plate P9 was produced by the same method as in Example 2, except that the procedure of <Method of forming optically anisotropic layer (A)> described above was changed as follows.

### <Method of Forming Optically Anisotropic Layer (A)>

A composition (4b) for forming an optically anisotropic layer containing a rod-like liquid crystal compound having the following composition was applied onto the above produced optically anisotropic layer (1c) by using a Geeser coating machine, and heated with hot air at 60 °C for 60 seconds. The obtained composition layer was irradiated with 320 nm LED-UV from the air interface side at 60 °C (50 mJ/cm²) to induce an isomerization reaction. Thereafter, the obtained composition layer was irradiated with UV (300 mJ/cm²) at 80 °C to fix the alignment of the liquid crystal compound to form an optically anisotropic layer (4b).

In the optically anisotropic layer (4b), a thickness was 1.5 μm, And at a wavelength of 550 nm was 164 nm, and a twisted angle of the liquid crystal compound was 81°. Assuming that a width direction of the film is defined as 0° (a longitudinal direction of the film is defined as) 90°, the alignment axial angle of the liquid crystal compound was 14° on the air side and 95° on the side in contact with the optically anisotropic layer (1c), in a case of being viewed from the optically anisotropic layer (4b) side.

The alignment axial angle of the liquid crystal compound contained in the optically anisotropic layer is expressed as negative in a case where it is clockwise (right-handed turning) and positive in a case where it is counterclockwise (left-handed turning) with the width direction of the substrate as a reference of 0°, upon observing the substrate from the surface side of the optically anisotropic layer.

In addition, the twisted angle of the liquid crystal compound is expressed as negative in a case where the alignment axis direction of the liquid crystal compound on the substrate side (back side) is clockwise (right-handed turning) and positive in a case where it is counterclockwise (left-handed turning) with reference to the alignment axis direction of the liquid crystal compound on the surface side (front side), upon observing the substrate from the surface side of the optically anisotropic layer.

Composition (4b) for forming optically anisotropic layer

| | |
|---|---|
| Rod-like liquid crystal compound (A) given above | 90 parts by mass |
| Rod-like liquid crystal compound (C) given above | 10 parts by mass |
| Ethylene oxide-modified | 4 parts by mass |
| trimethylolpropane triacrylate | |
| (V# 360, manufactured by Osaka Organic | |
| Chemical Industry Ltd.) | |
| Photopolymerization initiator (Irgacure 819, | 3 parts by mass |
| manufactured by BASF SE) | |
| Left-handed twisting chiral agent (L1) given above | 0.70 parts by mass |
| Fluorine-containing compound D given above | 0.18 parts by mass |
| Methyl isobutyl ketone | 126 parts by mass |
| Ethyl propionate | 126 parts by mass |

### Example 10

A polarizing plate P10 was produced by the same method as in Example 2, except that the procedure of <Method of forming optically anisotropic layer (A)> described above was changed as follows.

### <Method of Forming Optically Anisotropic Layer (A)>

A composition (5b) for forming an optically anisotropic layer containing a rod-like liquid crystal compound having the following composition was applied onto the above produced optically anisotropic layer (1c) by using a Geeser coating machine, and heated with hot air at 60 °C for 60 seconds. The obtained composition layer was irradiated with 320 nm LED-UV from the air interface side at 60 °C (40 mJ/cm²) to induce an isomerization reaction. Thereafter, the obtained composition layer was irradiated with UV (300 mJ/cm²) at 80 °C to fix the alignment of the liquid crystal compound to form an optically anisotropic layer (5b).

In the optically anisotropic layer (5b), a thickness was 1.6 μm, And at a wavelength of 550 nm was 164 nm, and a twisted angle of the liquid crystal compound was 81°. Assuming that a width direction of the film is defined as 0° (a longitudinal direction of the film is defined as) 90°, the alignment axial angle of the liquid crystal compound was 14° on the air side and 95° on the side in contact with the optically anisotropic layer (1c), in a case of being viewed from the optically anisotropic layer (5b) side.

The alignment axial angle of the liquid crystal compound contained in the optically anisotropic layer is expressed as negative in a case where it is clockwise (right-handed turning) and positive in a case where it is counterclockwise (left-handed turning) with the width direction of the substrate as a reference of 0°, upon observing the substrate from the surface side of the optically anisotropic layer.

In addition, the twisted angle of the liquid crystal compound is expressed as negative in a case where the alignment axis direction of the liquid crystal compound on the substrate side (back side) is clockwise (right-handed turning) and positive in a case where it is counterclockwise (left-handed turning) with reference to the alignment axis direction of the liquid crystal compound on the surface side (front side), upon observing the substrate from the surface side of the optically anisotropic layer.

Composition (5b) for forming optically anisotropic layer

| | |
|---|---|
| Rod-like liquid crystal compound | 80 parts by mass |
| (A) given above | |
| Rod-like liquid crystal compound | 20 parts by mass |
| (C) given above | |
| Ethylene oxide-modified | 4 parts by mass |
| trimethylolpropane triacrylate | |
| (V# 360, manufactured by Osaka | |
| Organic Chemical Industry Ltd.) | |
| Photopolymerization initiator (Irgacure 819, | 3 parts by mass |
| manufactured by BASF SE) | |
| Left-handed twisting chiral agent (L1) given above | 0.70 parts by mass |
| Fluorine-containing compound D given above | 0.18 parts by mass |
| Methyl isobutyl ketone | 126 parts by mass |
| Ethyl propionate | 126 parts by mass |

### Example 11

A polarizing plate was produced by the same method as in Example 1, except that an acrylic pressure sensitive adhesive (3d) having an average refractive index of 1.57 was used instead of the adhesive (1d).

### Example 12

A polarizing plate was produced by the same method as in Example 1, except that an epoxy crosslinking adhesive (4d) having an average refractive index of 1.57 was used instead of the adhesive (1d).

### Example 13

A polarizing plate was produced by the same method as in Example 1, except that in <Formation of optical film> described above, the adhesive (1d) was changed to the adhesive (2d).

### Example 14

A polarizing plate was produced by the same method as in Example 1, except that in <Formation of optical film> described above, the adhesive (1d) was changed to the following ultraviolet curable adhesive (4d).

Adhesive (4d)

| | |
|---|---|
| Acryloylmorpholine (manufactured | 40 parts by mass |
| by Kohjin Co., Ltd.) | |
| N-hydroxyacrylamide (manufactured | 30 parts by mass |
| by Kohjin Co., Ltd.) | |
| Tripropylene glycol diacrylate | 20 parts by mass |
| (ARONIX M-220, manufactured | |
| by Toagosei Co., Ltd.) | |
| OGSOL EA-F5710 (manufactured by | 10 parts by mass |
| Osaka Gas Chemicals Co., Ltd.) | |
| Photopolymerization initiator | 1.5 parts by mass |
| KAYACURE DETX-S, manufactured | |
| by Nippon Kayaku Co., Ltd.) | |

### Example 15

A polarizing plate was produced by the same method as in Example 1, except that in <Formation of optical film> described above, the adhesive (1d) was changed to the following ultraviolet curable adhesive (5d).

Adhesive (5d)

| | |
|---|---|
| Acryloylmorpholine (manufactured | 10 parts by mass |
| by Kohjin Co., Ltd.) | |
| N-hydroxyacrylamide (manufactured | 5 parts by mass |
| by Kohjin Co., Ltd.) | |
| Tripropylene glycol diacrylate | 10 parts by mass |
| (ARONIX M-220, manufactured | |
| by Toagosei Co., Ltd.) | |
| OGSOL EA-F5710 (manufactured by | 75 parts by mass |
| Osaka Gas Chemicals Co., Ltd.) | |
| Photopolymerization initiator | 1.5 parts by mass |
| (KAYACURE DETX-S, manufactured by | |
| Nippon Kayaku Co., Ltd.) | |

### Example 16

A polarizing plate P16 was produced by the same method as in Example 1, except that the <Formation of optical film> step described above was changed as follows.

A surface side of the optically anisotropic layer (1a) formed on the produced long cellulose acylate film was subjected to a corona discharge treatment. Conditions of the corona discharge treatment were set to an output intensity of 2.5 kW, a line speed of 18 m/min, an electrode length of 1.4 m, and a gap-to-gap distance of 2 mm. The above-described ultraviolet curable adhesive (1d) was applied onto the corona-treated surface to have a film thickness of 5.5 μm.

A surface side of the optically anisotropic layer (1b) of the optically anisotropic layer (1c-1b) formed on the produced long cellulose acylate film was also subjected to a corona discharge treatment. Conditions of the corona discharge treatment were set to an output intensity of 5.0 kW, a line speed of 18 m/min, an electrode length of 1.4 m, and a gap-to-gap distance of 2 mm. The above-described adhesive (1d) was applied onto the treated surface subjected to the corona treatment to have a film thickness of 6.0 μm.

The adhesive (1d) applied onto the optically anisotropic layer (1a) and the adhesive (1d) applied onto the optically anisotropic layer (1b) were bonded to each other, heated to 50 °C using an IR heater, irradiated with UV light from both surface sides of the cellulose acylate film of the bonded laminate to cure the adhesive (1d), and then thermally dried at 70 °C for 3 minutes. The film thickness after curing was 11.0 μm from the SEM observation of the cross section cut.

In this manner, an optical film (1a-1b-1c) having a layer configuration of the optically anisotropic layer (1a)—the adhesive layer (1d)—the optically anisotropic layer (1b-1c) was obtained. In the optical film (1a-1b-1c), in the above-described optically anisotropic layer (1b-1c), the optically anisotropic layer (1b) was disposed on the adhesive layer (1d) side.

An in-plane retardation of the above-described optical film (1a-1b-1c) at a wavelength of 550 nm was 141 nm.

### Examples 17 to 19

A polarizing plate was produced in the same manner as in Example 1, except that, in <Production of optical film> described above, the component ratio of the adhesive (1d) and the bonding conditions were adjusted to form an adhesive layer having a thickness and a thickness unevenness σ shown in the following tables.

### Example 20

### [Formation of First Optically Anisotropic Layer]

A continuous rubbing treatment was performed on the alignment film applied onto the cellulose acylate film in the same manner as in the above-described optically anisotropic layer (1a). In this case, the longitudinal direction and the transport direction of the elongated film were parallel to each other, and an angle between the longitudinal direction (transport direction) of the film and the rotation axis of the rubbing roller was 73°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was −17°. In other words, the position of the rotation axis of the rubbing roller is a position rotated by 73° counterclockwise with reference to the longitudinal direction of the film.

A composition (7a) for forming an optically anisotropic layer, containing a disk-like liquid crystal compound with the following formulation, was applied onto the rubbing-treated alignment film using a Geeser coating machine to form a composition layer. Next, the obtained composition layer was heated with hot air at 110 °C for 2 minutes for drying of the solvent and alignment aging of the disk-like liquid crystal compound. The obtained composition layer was irradiated with 320 nm LED-UV from the air interface side at 60 °C (60 mJ/cm²) to induce an isomerization reaction. Thereafter, the obtained composition layer was irradiated with UV (70 mJ/cm²) at 80 °C to fix the alignment of the liquid crystal compound to form an optically anisotropic layer (7a).

The thickness of the optically anisotropic layer (7a) was 2.3 μm. In addition, the in-plane retardation at 550 nm was 236 nm. In a case of viewing from the optically anisotropic layer (7a) side, assuming that the in-plane slow axis angle of the optically anisotropic layer (7a) was parallel to the rotation axis of the rubbing roller, and the width direction of the film was 0° (the counterclockwise direction was 90° and the clockwise direction was −90° in the longitudinal direction), the in-plane slow axis was −17°.

The optically anisotropic layer (7a) corresponds to the first optically anisotropic layer.

Composition (7a) for forming optically anisotropic layer

| | |
|---|---|
| Disk-like liquid crystal compound 1 given above | 100 parts by mass |
| Alignment film interface alignment | 0.10 parts by mass |
| agent 1 shown above | |
| Fluorine-containing compound A shown above | 0.1 parts by mass |
| Fluorine-containing compound B given above | 0.05 parts by mass |
| Fluorine-containing compound C shown above | 0.21 parts by mass |
| Ethylene oxide-modified | 8 parts by mass |
| trimethylolpropane triacrylate | |
| (V# 360, manufactured by Osaka Organic | |
| Chemical Industry Ltd.) | |
| Photopolymerization initiator (Irgacure 907, | 5.0 parts by mass |
| manufactured by BASF SE) | |
| Methyl ethyl ketone | 200 parts by mass |

### [Formation of Second Optically Anisotropic Layer]

The alignment film produced in [Example 1] was continuously subjected to a rubbing treatment. In this case, the longitudinal direction and the transport direction of the elongated film were parallel to each other, and an angle between the longitudinal direction (transport direction) of the film and the rotation axis of the rubbing roller was 105°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was 75°. In other words, the position of the rotation axis of the rubbing roller is a position rotated by 105° counterclockwise with reference to the longitudinal direction of the film.

A composition (8a) for forming an optically anisotropic layer, containing a disk-like liquid crystal compound with the following formulation, was applied onto the rubbing-treated alignment film using a Geeser coating machine to form a composition layer. Next, the obtained composition layer was heated with hot air at 60 °C for 2 minutes for drying of the solvent and alignment aging of the disk-like liquid crystal compound. Subsequently, the obtained composition layer was irradiated with UV (70 mJ/cm²) at 60 °C to fix the alignment of the liquid crystal compound to form an optically anisotropic layer (8a).

A thickness of the optically anisotropic layer (8a) was 1.1 μm. In addition, the in-plane retardation at 550 nm was 116 nm. It was confirmed that the average tilt angle of the disc plane of the disk-like liquid crystal compound with respect to the film surface was 90°, and the disk-like liquid crystal compound was aligned vertically to the film surface. In addition, in a case of viewing from the optically anisotropic layer (8a) side, assuming that the in-plane slow axis angle of the optically anisotropic layer (8a) was parallel to the rotation axis of the rubbing roller, and the width direction of the film was 0° (the counterclockwise direction was 90° and the clockwise direction was −90° in the longitudinal direction), the in-plane slow axis was 75°.

The optically anisotropic layer (8a) corresponds to the optically anisotropic layer (C).

Composition (8a) for forming optically anisotropic layer

| | |
|---|---|
| Disk-like liquid crystal compound 2 given above | 80 parts by mass |
| Disk-like liquid crystal compound 3 given above | 20 parts by mass |
| Alignment film interface alignment | 0.30 parts by mass |
| agent 1 shown above | |
| Fluorine-containing compound A shown above | 0.1 parts by mass |
| Fluorine-containing compound B given above | 0.05 parts by mass |
| Fluorine-containing compound C shown above | 0.21 parts by mass |
| Ethylene oxide-modified | 10 parts by mass |
| trimethylolpropane triacrylate | |
| (V#360, manufactured by Osaka Organic | |
| Chemical Industry Ltd.) | |
| Photopolymerization initiator (Irgacure 907, | 3.0 parts by mass |
| manufactured by BASF SE) | |
| Methyl ethyl ketone | 200 parts by mass |

### [Production of Polarizing Plate]

Using the obtained optically anisotropic layer (7a) and optically anisotropic layer (8a), an optical film (7a-8a) in which the optically anisotropic layer (7a)—the adhesive layer (1d)—the optically anisotropic layer (8a) were laminated in this order was obtained in the same manner as in Example 1.

Next, a polarizing plate P20 including the optical film (7a-8a) and a linear polarizer was produced by the same method as in Example 1. In the polarizing plate P20, the polarizer protective film, the polarizer, the optically anisotropic layer (7a), the adhesive layer (1d), and the optically anisotropic layer (8a) are laminated in this order, and the polarizing plate P20 corresponds to the polarizing plate according to Aspect 2.

The angle formed by the absorption axis of the polarizer and the in-plane slow axis of the optically anisotropic layer (7a) was −73°. In addition, an angle formed by the in-plane slow axis of the optically anisotropic layer (7a) and the in-plane slow axis of the optically anisotropic layer (8a) was 58°.

### Example 21

### [Formation of First Optically Anisotropic Layer]

A continuous rubbing treatment was performed on the alignment film applied onto the cellulose acylate film in the same manner as in the optically anisotropic layer (1a). At this time, the longitudinal direction and the transport direction of the elongated film were parallel, and the angle between the film longitudinal direction (transport direction) and the rubbing roller rotation axis was 75°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was −15°. In other words, the position of the rotation axis of the rubbing roller is a position rotated by 75° counterclockwise with reference to the longitudinal direction of the film.

A composition (9a) for forming an optically anisotropic layer, containing a rod-like liquid crystal compound with the following formulation, was applied onto the rubbing-treated alignment film using a Geeser coating machine to form a composition layer. Next, the obtained composition layer was heated with hot air at 110 °C for 2 minutes for drying of the solvent and alignment aging of the rod-like liquid crystal compound. The obtained composition layer was irradiated with 320 nm LED-UV from the air interface side at 60 °C (70 mJ/cm²) to induce an isomerization reaction. Subsequently, the obtained composition layer was irradiated with UV (100 mJ/cm²) at 80 °C to fix the alignment of the liquid crystal compound to form an optically anisotropic layer (9a).

A thickness of the optically anisotropic layer (9a) was 2.1 μm. In addition, a retardation at 550 nm was 220 nm. In a case of viewing from the optically anisotropic layer (9a) side, assuming that the in-plane slow axis angle of the optically anisotropic layer (9a) was parallel to the rotation axis of the rubbing roller, and the width direction of the film was 0° (the counterclockwise direction was 90° and the clockwise direction was −90° in the longitudinal direction), the in-plane slow axis was −15°.

The optically anisotropic layer (9a) corresponds to the first optically anisotropic layer.

Composition (9a) for forming optically anisotropic layer

| | |
|---|---|
| Rod-like liquid crystal compound (A) given above | 70 parts by mass |
| Rod-like liquid crystal compound (C) given above | 30 parts by mass |
| Ethylene oxide-modified | 10 parts by mass |
| trimethylolpropane triacrylate | |
| (V#360, manufactured by Osaka | |
| Organic Chemical Industry Ltd.) | |
| Photopolymerization initiator (Irgacure 907, | 3 parts by mass |
| manufactured by BASF SE) | |
| Fluorine-containing compound D shown above | 0.20 parts by mass |
| Methyl ethyl ketone | 250 parts by mass |

### [Production of Polarizing Plate]

Using the obtained optically anisotropic layer (9a) and the optically anisotropic layer (8a) obtained in [Example 20], an optical film (9a-8a) in which the optically anisotropic layer (9a)—the adhesive layer (1d)—the optically anisotropic layer (8a) were laminated in this order was obtained in the same manner as in Example 1.

Next, a polarizing plate P21 including the optical film (9a-8a) and a linear polarizer was produced by the same method as in Example 1.

In the polarizing plate P21, the polarizer protective film, the polarizer, the optically anisotropic layer (9a), the adhesive layer (1d), and the optically anisotropic layer (8a) are laminated in this order, and the polarizing plate P21 corresponds to the polarizing plate according to Aspect 2.

The angle formed by the absorption axis of the polarizer and the in-plane slow axis of the optically anisotropic layer (9a) was −75°. In addition, an angle formed by the in-plane slow axis of the optically anisotropic layer (9a) and the in-plane slow axis of the optically anisotropic layer (8a) was 15°.

### Examples 22 and 23

A polarizing plate was produced by the same method as in Example 1, except that, in [Formation of first optically anisotropic layer] of Example 1, the film thickness of the optically anisotropic layer was adjusted to the value shown in the table below.

### Comparative Example 1

A polarizing plate was produced by the same method as in Example 1, except that the optically anisotropic layer (1a) of Example 1 was changed to the optically anisotropic layer (2a) of Example 2.

### [Production of Organic EL Display Device]

The SAMSUNG GALAXY S4 equipped with an organic EL panel was disassembled, a circular polarization plate was peeled off, and each of the polarizing plates produced above was bonded to the display device using a pressure-sensitive adhesive such that the polarizer protective film was arranged on the outside, thereby producing an organic EL display device.

### [Measurement of Refractive Index and Film Thickness of Each Layer]

Reflection ellipsometry was performed on the substrate (the above-described cellulose acylate film) and the laminate in which the alignment film was formed on the substrate. The reflection ellipsometry was performed using the method described in the calculation method of the in-plane birefringence, the in-plane refractive index, and the thickness in each layer and each region described above. Next, the wavelength dispersion of the refractive index was set to n(λ)=Aₙ+Bₙ/λ₂ (Aₙ and Bₙ are variables, Δ is a wavelength, and n(λ) represents a refractive index at the wavelength λ) according to a Cauchy model, and the refractive index and the film thickness of the substrate were calculated by fitting. An optical model was constructed in the same manner from the obtained measurement results of the refractive index and the film thickness of the obtained substrate and the laminate in which the alignment film was formed on the substrate, and the refractive index and the film thickness of the alignment film were calculated by fitting.

Subsequently, the in-plane birefringence, the in-plane refractive index, and the thickness were calculated for each of the optically anisotropic layers and the isotropic layers using the above-described method.

### [Evaluation]

### [In-Plane Tint Unevenness]

The produced polarizing plate was bonded to a black acrylic plate (ACRYLITE L502 Black, manufactured by Mitsubishi Chemical Corporation) using a pressure-sensitive adhesive such that the polarizer protective film was disposed on the outer side. Under a rod-like fluorescent lamp (FPL-27EX-N), the polarizing plate was set at an azimuthal angle at which the major axis direction of the rod-like fluorescent lamp and the longitudinal direction of the polarizing plate were perpendicular to each other through a diffuser, and the in-plane tint was observed from a polar angle of 30° to 40°. As a result, the in-plane tint unevenness in a case of being viewed from an oblique direction was evaluated according to the following standard. The results are shown in tables below.
A: in-plane tint unevenness was not visible at all, or the in-plane tint unevenness was visible, but only a little. (acceptable)
B: in-plane tint unevenness was slightly visible, but there was no problem in use. (acceptable)
C: in-plane tint unevenness was slightly visible, but there was no problem in use. (acceptable)
D: in-plane tint unevenness was visible, but there was no problem in use. (acceptable)
E: in-plane tint unevenness was strongly visible, which was not acceptable.

### [Air Bubbles During Bonding]

The produced organic EL display device was displayed in black, and observed from the front direction and the 20° direction under bright light, and defects caused by air bubbles were evaluated according to the following standard. The results are shown in tables below.
Absent: no defects were observed by visual inspection, and there was no problem in use. (acceptable)
Present: there was a clearly circular color loss mark, which was unacceptable.

### Results

The configuration, refractive index, film thickness, and evaluation results of the polarizing plates of each of Examples and Comparative Examples are shown in the following table.

In the table, in a case where the optically anisotropic layer consists of two layers, the optically anisotropic layer is shown as “optically anisotropic layer on the polarizer side/optically anisotropic layer on the side opposite to the polarizer side”. For example, in a case where, as in Example 1, the liquid crystal type column of the second optically anisotropic layer is “rod-like/rod-like” and the liquid crystal alignment state column is “twisted/vertical”, this means that the second optically anisotropic layer is formed by laminating, from the polarizer side, a layer formed by fixing a twistedly aligned rod-like liquid crystal compound and a layer formed by fixing a vertically aligned rod-like liquid crystal compound.

The value of ne1 shown in the table indicates the refractive index in the in-plane slow axis direction on the surface of the optically anisotropic layer on the side where the specific region is present. In a case where the specific region is not present, the value of ne1 indicates the refractive index in the in-plane slow axis direction on the surface of the optically anisotropic layer on the isotropic layer A side. The value of ne2 shown in the table indicates the refractive index in the in-plane slow axis direction in a region where the in-plane birefringence is the maximum value in the specific region of the optically anisotropic layer. In Examples 1 to 19 and 22 to 23, the region indicating ne2 was present in the layer formed by fixing the twistedly aligned rod-like liquid crystal compound, and the above-described value was the same as the refractive index in the in-plane slow axis direction of the homogeneous region 2 present in the layer formed by fixing the twistedly aligned rod-like liquid crystal compound. The definition of the refractive index in the in-plane slow axis direction in the layer formed by fixing the twistedly aligned rod-like liquid crystal compound is as described above.

In the table, the specific region column indicates a region present in the optically anisotropic layer. For example, in a case where the region X is described, the corresponding first optically anisotropic layer has the region X.

In the table, the isotropic layer A and isotropic layer B columns indicate the physical properties of the isotropic layer adjacent to the specific region present in each of Examples. For example, in Example 1, the isotropic layer A is a layer adjacent to the region X, and in Example 5, the isotropic layer B is a layer adjacent to the region Z. In Comparative Example 1, the physical properties of the isotropic layer A between the first optically anisotropic layer and the second optically anisotropic layer are shown.

TABLE 1

| | First optically anisotropic layer | | | | | | | | Isotropic layer A and isotropic layer B | | | |
|---|---|---|---|---|---|---|---|---|---|---|---|---|
| | | | | Total | | | | Thick- | | In- | | Thickness |
| | | Liquid | | film | | | | ness of | | plane | Film | un- |
| | Liquid | crystal | | thick- | | | | specific | Bonding | refrac- | thick- | evenness |
| | crystal | alignment | Re | ness | | | Specific | region | agent | tive | ness | σ |
| | type | state | (nm) | (μm) | ne1 | ne2 | region | (nm) | type | index | (μm) | (nm) |
| Example 1 | Disk-like | Vertical | 168 | 1.7 | 1.61 | 1.63 | Region X | 450 | Acrylic | 1.58 | 2 | 10 |
| Example 2 | Disk-like | Vertical | 168 | 1.4 | 1.63 | 1.63 | — | — | Acrylic | 1.58 | 2 | 10 |
| Example 3 | Disk-like | Vertical | 168 | 1.4 | 1.63 | 1.63 | — | — | Acrylic | 1.58 | 2 | 10 |
| Example 4 | Disk-like | Vertical | 168 | 1.7 | 1.61 | 1.63 | Region X | 450 | Acrylic | 1.58 | 2 | 10 |
| Example 5 | Disk-like | Vertical | 168 | 1.7 | 1.61 | 1.63 | Region Z | 450 | Acrylic | 1.58 | 2 | 10 |
| Example 6 | Disk-like | Vertical | 168 | 1.4 | 1.61 | 1.63 | Region X | 50 | Acrylic | 1.58 | 2 | 10 |
| Example 7 | Disk-like | Vertical | 168 | 1.5 | 1.61 | 1.63 | Region X | 100 | Acrylic | 1.58 | 2 | 10 |
| Example 8 | Disk-like | Vertical | 168 | 1.6 | 1.61 | 1.63 | Region X | 250 | Acrylic | 1.58 | 2 | 10 |
| Example 9 | Disk-like | Vertical | 168 | 1.4 | 1.63 | 1.63 | — | — | Acrylic | 1.58 | 2 | 10 |
| Example 10 | Disk-like | Vertical | 168 | 1.4 | 1.63 | 1.63 | — | — | Acrylic | 1.58 | 2 | 10 |
| Example 11 | Disk-like | Vertical | 168 | 1.7 | 1.61 | 1.63 | Region X | 450 | PSA | 1.57 | 5 | 7 |
| Example 12 | Disk-like | Vertical | 168 | 1.7 | 1.61 | 1.63 | Region X | 450 | Epoxy-based | 1.57 | 2.2 | 11 |
| Example 13 | Disk-like | Vertical | 168 | 1.7 | 1.61 | 1.63 | Region X | 450 | Acrylic | 1.58 | 2.2 | 10 |
| Example 14 | Disk-like | Vertical | 168 | 1.7 | 1.61 | 1.63 | Region X | 450 | Acrylic | 1.58 | 2.2 | 12 |
| Example 15 | Disk-like | Vertical | 168 | 1.7 | 1.61 | 1.63 | Region X | 450 | Acrylic | 1.58 | 2.2 | 13 |
| Example 16 | Disk-like | Vertical | 168 | 1.7 | 1.61 | 1.63 | Region X | 450 | Acrylic | 1.58 | 11 | 17 |
| Example 17 | Disk-like | Vertical | 168 | 1.7 | 1.61 | 1.63 | Region X | 450 | Acrylic | 1.58 | 2.2 | 31 |
| Example 18 | Disk-like | Vertical | 168 | 1.7 | 1.61 | 1.63 | Region X | 450 | Acrylic | 1.58 | 2.2 | 45 |
| Example 19 | Disk-like | Vertical | 168 | 1.7 | 1.61 | 1.63 | Region X | 450 | Acrylic | 1.58 | 2.2 | 3 |
| Example 20 | Disk-like | Vertical | 236 | 2.3 | 1.61 | 1.63 | Region X | 400 | Acrylic | 1.58 | 2 | 10 |
| Example 21 | Rod-like | Horizontal | 220 | 2.1 | 1.62 | 1.64 | Region X | 400 | Acrylic | 1.58 | 2 | 10 |
| Example 22 | Disk-like | Vertical | 150 | 1.5 | 1.61 | 1.63 | Region X | 400 | Acrylic | 1.58 | 2 | 10 |
| Example 23 | Disk-like | Vertical | 190 | 1.9 | 1.61 | 1.63 | Region X | 500 | Acrylic | 1.58 | 2 | 10 |
| Comparative | Disk-like | Vertical | 168 | 1.4 | 1.63 | 1.63 | — | — | Acrylic | 1.58 | 2 | 10 |
| Example 1 | | | | | | | | | | | | |

TABLE 2

| | Second optically anisotropic layer | | | | | | | Evaluation | |
|---|---|---|---|---|---|---|---|---|---|
| | Liquid | | Total film | | | | Thickness of | | Air bubbles |
| | crystal | Liquid crystal | thickness | | | Specific | specific | In-plane tint | during |
| | type | alignment state | (μm) | ne1 | ne2 | region | region (nm) | unevenness | bonding |
| Example 1 | Rod-like/ | Twisted/vertical | 2.3 | 1.64 | 1.64 | — | — | B | Absent |
| | rod-like | | | | | | | | |
| Example 2 | Rod-like/ | Twisted/vertical | 2.6 | 1.62 | 1.64 | Region Y | 400 | B | Absent |
| | rod-like | | | | | | | | |
| Example 3 | Rod-like/ | Twisted/vertical | 2.6 | 1.62 | 1.64 | Region Y | 350 | B | Absent |
| | rod-like | | | | | | | | |
| Example 4 | Rod-like/ | Twisted/vertical | 2.6 | 1.62 | 1.64 | Region Y | 400 | A | Absent |
| | rod-like | | | | | | | | |
| Example 5 | Rod-like/ | Twisted/vertical | 2.6 | 1.64 | 1.64 | — | — | B | Absent |
| | rod-like | | | | | | | | |
| Example 6 | Rod-like/ | Twisted/vertical | 2.3 | 1.64 | 1.64 | — | — | D | Absent |
| | rod-like | | | | | | | | |
| Example 7 | Rod-like/ | Twisted/vertical | 2.3 | 1.64 | 1.64 | — | — | C | Absent |
| | rod-like | | | | | | | | |
| Example 8 | Rod-like/ | Twisted/vertical | 2.3 | 1.64 | 1.64 | — | — | C | Absent |
| | rod-like | | | | | | | | |
| Example 9 | Rod-like/ | Twisted/vertical | 2.3 | 1.62 | 1.64 | Region Y | 50 | D | Absent |
| | rod-like | | | | | | | | |
| Example 10 | Rod-like/ | Twisted/vertical | 2.3 | 1.62 | 1.64 | Region Y | 100 | C | Absent |
| | rod-like | | | | | | | | |
| Example 11 | Rod-like/ | Twisted/vertical | 2.3 | 1.64 | 1.64 | — | — | C | Absent |
| | rod-like | | | | | | | | |
| Example 12 | Rod-like/ | Twisted/vertical | 2.3 | 1.64 | 1.64 | — | — | B | Absent |
| | rod-like | | | | | | | | |
| Example 13 | Rod-like/ | Twisted/vertical | 2.3 | 1.64 | 1.64 | — | — | C | Absent |
| | rod-like | | | | | | | | |
| Example 14 | Rod-like/ | Twisted/vertical | 2.3 | 1.64 | 1.64 | — | — | D | Absent |
| | rod-like | | | | | | | | |
| Example 15 | Rod-like/ | Twisted/vertical | 2.3 | 1.64 | 1.64 | — | — | C | Absent |
| | rod-like | | | | | | | | |
| Example 16 | Rod-like/ | Twisted/vertical | 2.3 | 1.64 | 1.64 | — | — | B | Absent |
| | rod-like | | | | | | | | |
| Example 17 | Rod-like/ | Twisted/vertical | 2.3 | 1.64 | 1.64 | — | — | C | Absent |
| | rod-like | | | | | | | | |
| Example 18 | Rod-like/ | Twisted/vertical | 2.3 | 1.64 | 1.64 | — | — | C | Absent |
| | rod-like | | | | | | | | |
| Example 19 | Rod-like/ | Twisted/vertical | 2.3 | 1.64 | 1.64 | — | — | B | Present |
| | rod-like | | | | | | | | |
| Example 20 | Disk-like | Vertical | 2.1 | 1.63 | 1.63 | — | — | B | Absent |
| Example 21 | Disk-like | Vertical | 2.1 | 1.64 | 1.64 | — | — | B | Absent |
| Example 22 | Rod-like/ | Twisted/vertical | 1.1 | 1.64 | 1.64 | — | — | B | Absent |
| | rod-like | | | | | | | | |
| Example 23 | Rod-like/ | Twisted/vertical | 1.1 | 1.64 | 1.64 | — | — | B | Absent |
| | rod-like | | | | | | | | |
| Comparative | Rod-like/ | Twisted/vertical | 2.3 | 1.64 | 1.64 | — | — | E | Absent |
| Example 1 | rod-like | | | | | | | | |

From the results shown in the above tables, it was confirmed that, in a case where the polarizing plate according to the embodiment of the present invention was applied to the display element to obtain the display device, and the display device was viewed from the oblique direction in the black display, the in-plane tint unevenness was less likely to occur.

From the comparison of Examples 1 and 2 and Examples 4 and 5, it was confirmed that, in a case where the polarizing plate satisfied two or more of Requirements 1 to 3, the effect of the present invention was more excellent.

From the comparison of Examples 1, 3, and 6 to 10, it was confirmed that, in a case where the thicknesses of the region X, the region Y, and the region Z were 60 nm or more, the effect of the present invention was more excellent, and in a case where the thicknesses of the region X, the region Y, and the region Z were 300 nm or more, the effect of the present invention was even more excellent.

From the comparison of Examples 1 and 11 to 15, it was confirmed that, in a case where the in-plane refractive indices of the isotropic layer A and the isotropic layer B were 1.53 or more, the effect of the present invention was more excellent, and in a case where the in-plane refractive indices of the isotropic layer A and the isotropic layer B were 1.56 to 1.58, the effect of the present invention was even more excellent.

From the comparison of Examples 1 and 17 to 19, it was confirmed that, in a case where the thickness unevenness of the isotropic layer A and the isotropic layer B was 35 nm or less, the effect of the present invention was more excellent, and in a case where the thickness unevenness of the isotropic layer A and the isotropic layer B was 5 nm or more, air bubbles during bonding could be further suppressed.

### EXPLANATION OF REFERENCES

10, 10A, 10B: first optically anisotropic layer
12: region X
14: region Z
16: homogeneous region 1
20: second optically anisotropic layer
22: region Y
24: homogeneous region 2
30, 30A, 30B: polarizer
40, 40A, 40B: isotropic layer A
50: isotropic layer B
25A: optically anisotropic layer (A)
26A: optically anisotropic layer (B)
27B: optically anisotropic layer (C)
100, 100A, 100B: polarizing plate

What is claimed is:

1. A polarizing plate comprising, in order:
a polarizer;
a first optically anisotropic layer; and
a second optically anisotropic layer,
wherein an isotropic layer A exhibiting optical isotropy is disposed between the first optically anisotropic layer and the second optically anisotropic layer, and at least one of Requirement 1 or Requirement 2 is satisfied, or
an isotropic layer B exhibiting optical isotropy is disposed between the polarizer and the first optically anisotropic layer, and Requirement 3 is satisfied,
Requirement 1: the first optically anisotropic layer has a region X in which an in-plane birefringence gradually increases along a thickness direction from a surface on a side of the isotropic layer A, and an absolute value of a difference between a refractive index in an in-plane slow axis direction on the surface of the first optically anisotropic layer on the side of the isotropic layer A and an in-plane refractive index of the isotropic layer A is 0.04 or less,
Requirement 2: the second optically anisotropic layer has a region Y in which an in-plane birefringence gradually increases along the thickness direction from a surface on the side of the isotropic layer A, and an absolute value of a difference between a refractive index in an in-plane slow axis direction on the surface of the second optically anisotropic layer on the side of the isotropic layer A and the in-plane refractive index of the isotropic layer A is 0.04 or less, and
Requirement 3: the first optically anisotropic layer has a region Z in which an in-plane birefringence gradually increases along a thickness direction from a surface on a side of the isotropic layer B, and an absolute value of a difference between a refractive index in an in-plane slow axis direction on the surface of the first optically anisotropic layer on the side of the isotropic layer B and an in-plane refractive index of the isotropic layer B is 0.04 or less.

2. The polarizing plate according to claim 1,
wherein thicknesses of the region X, the region Y, and the region Z are 60 to 500 nm.

3. The polarizing plate according to claim 1,
wherein in-plane thickness unevennesses of the isotropic layer A and the isotropic layer B are 5 to 35 nm.

4. The polarizing plate according to claim 1,
wherein the first optically anisotropic layer is an A-Plate.

5. The polarizing plate according to claim 1,
wherein an in-plane retardation of the first optically anisotropic layer at a wavelength of 550 nm is 150 to 240 nm.

6. The polarizing plate according to claim 1,
wherein the first optically anisotropic layer contains a disk-like liquid crystal compound.

7. The polarizing plate according to claim 1,
wherein the in-plane refractive indices of the isotropic layer A and the isotropic layer B are 1.51 to 1.59.

8. The polarizing plate according to claim 1,
wherein thicknesses of the isotropic layer A and the isotropic layer B are 0.5 to 20 μm.

9. The polarizing plate according to claim 1,
wherein the isotropic layer A and the isotropic layer B are each a pressure-sensitive adhesive layer or an ultraviolet curable adhesive layer.

10. A display device comprising:
a display element; and
the polarizing plate according to claim 1.
